(19) United States
(12) Patent Application Publication
(10) Pub. No.: US 2016/0033862 A1
(43) Pub. Date: Feb. 4, 2016

(54) ACTIVE LIGHT-SENSITIVE, OR RADIATION-SENSITIVE RESIN COMPOSITION, AND PATTERN-FORMING METHOD USING SAME

(71) Applicant: FUJIFILM Corporation, Tokyo (JP)

(72) Inventor: Akinori SHIBUYA, Haibara-gun (JP)

(73) Assignee: FUJIFILM CORPORATION, Tokyo (JP)

(21) Appl. No.: 14/881,478

(22) Filed: Oct. 13, 2015

Related U.S. Application Data
(63) Continuation of application No. PCT/JP2014/062137, filed on May 2, 2014.

(30) Foreign Application Priority Data
May 14, 2013 (JP) 2013-102598

(51) Int. Cl. G03F 7/039; G03F 7/32; G03F 7/20

(52) U.S. Cl. CPC G03F 7/039; G03F 7/20; G03F 7/32; G03F 7/2041

(57) ABSTRACT

Provided is an active light-sensitive or radiation-sensitive resin composition with excellent exposure latitude and pattern roughness such as line width roughness, and a pattern-forming method using the same. The active light-sensitive or radiation-sensitive resin composition of the present invention contains
(A) at least one type of a compound which is represented by General Formula (I) below and which generates an acid by irradiation with active light or radiation and
(B) at least one type of a resin which includes a repeating unit which is represented by General Formula (1) below and of which, due to being decomposed by an action of an acid, the solubility increases with respect to an alkali developer.

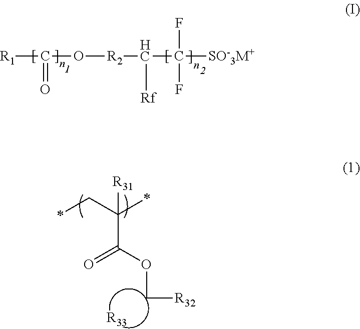

### CROSS-REFERENCE TO RELATED APPLICATIONS

This application is a Continuation of PCT International Application No. PCT/JP2014/062137, filed on May 2, 2014, which claims priority under 35 U.S.C. §119(a) to Japanese Patent Application No. 2013-102598, filed on May 14, 2013. Each of the above application(s) is hereby expressly incorporated by reference, in its entirety, into the present application.

### BACKGROUND OF THE INVENTION

1. Field of the Invention

The present invention relates to an active light-sensitive, or radiation-sensitive resin composition and an active light-sensitive or radiation-sensitive film and a pattern-forming method using the same. In more detail, the present invention relates to an active light-sensitive or radiation-sensitive resin composition, which is used in steps for manufacturing semiconductors such as IC, steps for manufacturing circuit boards of liquid crystal, thermal heads, and the like, in addition to other photofabrication processes, lithography printing plates, and acid curable compositions; an active light-sensitive or radiation-sensitive film, and a pattern-forming method using the same. In addition, the present invention also relates to a method for manufacturing an electronic device which includes the pattern-forming method and to an electronic device which is manufactured by this method.

2. Description of the Related Art

A chemical amplification resist composition is a pattern forming material which generates an acid in an exposed section by being irradiated with radiation such as far ultraviolet light, changes its solubility with respect to a developer in an irradiated section and a non-irradiated section of active radiation according to a reaction in which the acid is a catalyst, and forms a pattern on a substrate.

In a case where a KrF excimer laser is an exposure light source, since a resin with small absorption in the 248 nm region in which poly(hydroxy styrene) is the basic skeleton is primarily used for a main component, a favorable pattern with high sensitivity and high resolution is formed, and the base is favorable compared to a naphthoquinone diazide/novolak resin base in the prior art.

On the other hand, in a case of using a light source with an even shorter wavelength, for example, an ArF excimer laser (193 nm) as the exposure light source, since a compound which has an aromatic group substantially exhibits great absorption in the 193 nm region, even the chemical amplification system described above is not sufficient. For this reason, a resist for an ArF excimer laser, which contains a resin which has an alicyclic hydrocarbon structure, has been developed.

In addition, various types of compounds have also been developed with regard to a photoacid generator which is a main constituent component of the chemical amplification resist composition (for example, refer to WO2011/104127A). WO2011/104127A discloses a photoacid generator of a fluorine-containing sulfonic acid salt.

However, there is a demand for further improvement with regard to the exposure latitude and line width roughness in the resist composition described above.

### SUMMARY OF THE INVENTION

An object of the present invention is to provide an active light-sensitive or radiation-sensitive resin composition with excellent exposure latitude (also referred to below as DOF) and pattern roughness such as line width roughness (also referred to below as LWR), and a pattern-forming method using the same.

The present inventors completed the present invention exemplified below as a result of intensive research in order to solve the problems described above.

[1] An active light-sensitive or radiation-sensitive resin composition which contains (A) at least one type of a compound which is represented by General Formula (I) below and which generates an acid by irradiation with active light or radiation and

(B) at least one type of a resin which includes a repeating unit which is represented by General Formula (1) below and of which, due to being decomposed by an action of an acid, the solubility increases with respect to an alkali developer:

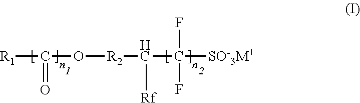

(In General Formula (I),

R₁ represents an alicyclic hydrocarbon group in which at least one of methylene groups configuring a ring skeleton is substituted with a divalent linking group having a hetero atom;

R₂ represents a divalent linking group;

Rf represents a fluorine atom or an alkyl group which is substituted with at least one fluorine atom;

n₁ and n₂ each independently represent 0 or 1; and

M⁺ represents a monovalent cation.)

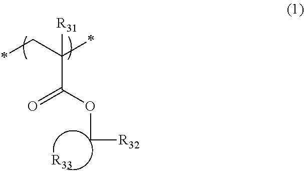

(In General Formula (1),

R₃₁ represents a hydrogen atom, a fluorine atom, an alkyl group, or a fluorinated alkyl group;

R₃₂ represents an alkyl group or a cycloalkyl group;

R₃₃ represents an atom group which is necessary for forming a monocyclic alicyclic hydrocarbon structure with a carbon atom with which R₃₂ is bonded; and in the alicyclic hydrocarbon structure, a part of carbon atoms configuring a ring may be substituted with a hetero atom or a group having a hetero atom.)

[2] The active light-sensitive or radiation-sensitive resin composition according to [1] in which, in General Formula (I), R₁ is a lactone group.

[3] The active light-sensitive or radiation-sensitive resin composition according to [1] or [2] in which, in General Formula (I), n₂ is 1 and Rf is a fluorine atom.

[4] The active light-sensitive or radiation-sensitive resin composition according to any one of [1] to [3] in which, in General Formula (I), n₁ is 1 and R₂ is a methylene group.

[5] The active light-sensitive or radiation-sensitive resin composition according to any one of [1] to [4] in which, in General Formula (I), R₁ is a lactone group having a polycyclic structure.

[6] The active light-sensitive or radiation-sensitive resin composition according to any one of [1] to [5] in which, in General Formula (I), R₁ is a lactone group represented by the structural formula below.

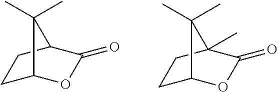

[7] The active light-sensitive or radiation-sensitive resin composition according to any one of [1] to [6] in which, in General Formula (I), M⁺ is a sulfonium cation represented by General Formula (II) or (III) below:

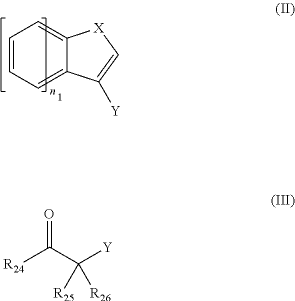

(In General Formulas (II) and (III),

Y represents a structure represented by any of General Formulas (V-1) to (V-3) below;

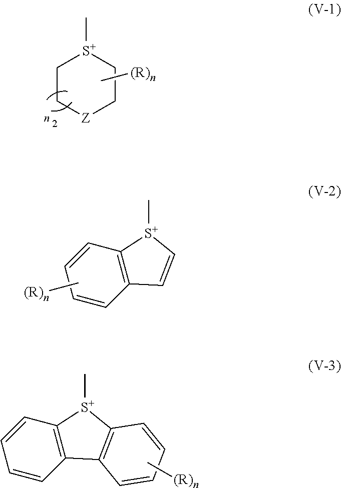

n₁ and n₂ are each independently 0 or 1;

X and Z represent any of —CH₂—, —CR₂₁═CR₂₂—, —NR₂₃—, —S—, and —O—; R₂₁, R₂₂, and R₂₃ each independently represent a hydrogen atom, a substituted or unsubstituted alkyl group, a cycloalkyl group, or an alkoxy group;

R₂₄ represents a substituted or unsubstituted aryl group;

R₂₅ and R₂₆ each independently represent a hydrogen atom, a substituted or unsubstituted alkyl group or a cycloalkyl group, and R₂₅ and R₂₆ may form a ring by linking with each other; and

(R)ₙ represents a substituent group.

[8] The active light-sensitive or radiation-sensitive resin composition according to any one of [1] to [7] in which at least one type of a photoacid generator other than compound (A) is included.

[9] The active light-sensitive or radiation-sensitive resin composition according to any one of [1] to [8] which further includes a hydrophobic resin.

[10] An active light-sensitive or radiation-sensitive film which includes the composition according to any one of [1] to [9].

[11] A pattern-forming method which includes forming a film which includes the composition according to any one of [1] to [10], irradiating the film with active light or radiation, and developing the film irradiated with active light or radiation.

[12] The pattern-forming method according to [11] in which the irradiating with active light or radiation is performed by ArF liquid immersion exposure.

[13] A method for manufacturing an electronic device which includes the pattern-forming method according to [11] or [12].

[14] An electronic device which is manufactured by the method for manufacturing an electronic device according to [13].

### Effects of the Invention

According to the present invention, it is possible to provide an active light-sensitive or radiation-sensitive resin composition with excellent exposure latitude and pattern roughness such as line width roughness, and an active light-sensitive or radiation-sensitive film and a pattern-forming method using the same.

### DESCRIPTION OF EXEMPLARY EMBODIMENTS

Detailed description will be given below of embodiments of the present invention.

In the notation of the groups (atomic groups) in the present specification, notation which does not indicate whether a group is substituted or unsubstituted encompasses groups (atomic groups) which have a substituent group as well as groups (atomic groups) which do not have a substituent group. For example, an “alkyl group” encompasses not only an alkyl group which does not have a sub stituent group (an unsubstituted alkyl group), but also an alkyl group which has a substituent group (a substituted alkyl group).

In addition, a straight-chain and branched alkyl group is included in an “alkyl group” and a “substituted alkyl group” in the present specification. In the same manner, an alkyl group which is included in an “alkoxy group” may be either straight-chain or branched and may be a cycloalkyl group.

In the present invention, the “active light” or “radiation” has the meaning of, for example, particle beams such as the bright line spectrum of a mercury lamp, far ultraviolet rays which are represented by an excimer laser, extreme ultraviolet rays (EUV light), X-rays, electron beams, and ion beams. In addition, “light” in the present invention has the meaning of active light or radiation.

In addition, unless otherwise stated, “exposure” in the present specification includes not only exposure using a mercury lamp or far ultraviolet rays which are represented by an excimer laser, X-rays, extreme ultraviolet rays (EUV light), and the like, but also drawing using particle beams such as electron beams and ion beams.

An active light-sensitive or radiation-sensitive resin composition of the present invention (also referred to below as a “resist composition”) contains (A) at least one type of a compound (also referred to below as a “compound (A)” or a “photoacid generator (A)”) which is represented by General Formula (I) below and which generates an acid by irradiation with active light or radiation and (B) at least one type of a resin (also referred to below as a resin (B)) which includes a repeating unit which is represented by General Formula (1) below and of which, due to being decomposed by an action of an acid, a solubility increases with respect to an alkali developer.

The active light-sensitive or radiation-sensitive resin composition of the present invention is a composition with improved exposure latitude and line width roughness as a result of containing the compound (A) and the resin (B).

The reason why the exposure latitude and line width roughness are improved is not certain; however, it is considered that the ratio of the acid strength of an acid which is generated from the compound (A) and the amount of activation energy for the deprotection reaction in a repeating unit which is represented by General Formula (1) is optimal. It is assumed that the deprotection reaction quickly proceeding due to the exposure and the PEB contributes to the improvement of exposure latitude and line width roughness. In addition, a cyclic structure which includes a hetero atom is present at an end of the acid which is generated from the compound (A). It is considered that the exposure latitude and line width roughness are improved since interaction between the generated acid and a binder resin is great and the diffusibility of the generated acid is small due to the cyclic structure including a hetero atom.

Description will be given below of each component of the composition of the present invention.

[1] Compound (A)

The active light-sensitive or radiation-sensitive resin composition of the present invention contains at least one type of the compound (A) which is represented by General Formula (1) below which generates an acid by irradiation with active light or radiation as described above.

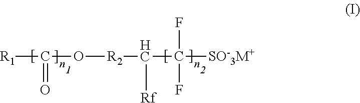

In General Formula (I),

R₁ represents an alicyclic hydrocarbon group in which at least one of methylene groups configuring a ring skeleton is substituted with a divalent linking group having a hetero atom;

R₂ represents a divalent linking group;

Rf represents a fluorine atom or an alkyl group which is substituted with at least one fluorine atom;

n₁ and n₂ each independently represent 0 or 1; and

M⁺ represents a monovalent cation.

R₁ is preferably an alicyclic hydrocarbon group with 4 or more carbon atoms. In addition, the alicyclic hydrocarbon group preferably has 20 or less carbon atoms and more preferably has 15 or less carbon atoms. The alicyclic hydrocarbon group described above may be a monocyclic alicyclic hydrocarbon group or a polycyclic alicyclic hydrocarbon group. A polycyclic alicyclic hydrocarbon group is more preferable.

The monocyclic alicyclic hydrocarbon group preferably has 4 to 12 carbon atoms and examples thereof include a cyclopentyl group, a cyclohexyl group, a cycloheptyl group, a cyclooctyl group, a cyclododecanyl group, a cyclopentenyl group, a cyclohexenyl group, a cyclooctadienyl group, a piperidine ring group, and the like, and a cyclopentyl group, a cyclohexyl group, and a cyclooctyl group are particularly preferable.

The polycyclic alicyclic hydrocarbon group preferably has 7 to 20 carbon atoms and examples thereof include a bicyclo[4.3.0] nonanyl group, a decahydronaphthalenyl group, a 1,2,3,4-tetrahydronaphthalenyl group, a tricyclo[5.2.1.0(2,6)] decanyl group, a tetracyclodecanyl group, a tetracyclododecanyl group, a bornyl group, an isobornyl group, a norbornyl group, an adamantyl group, a noradamantyl group, a 1,7,7-trimethyl tricyclo [2.2.1.0^{2,6}] heptanyl group, a 3,7,7-trimethyl bicyclo[4.1.0] heptanyl group, a decahydroisoquinoline ring group, and the like, a norbornyl group, an adamantyl group, and a noradamantyl group are preferable, and a norbornyl group is more preferable.

With regard to R₁, some of the methylene groups which configure a ring skeleton of the alicyclic hydrocarbon group are substituted with a divalent linking group which has a hetero atom. Examples of the hetero atom include an oxygen atom, a sulfur atom, and a nitrogen atom, and an oxygen atom is particularly preferable. Examples of the divalent linking group which has a hetero atom include an ester group, an ether group, a thioester group, and amide group. Among these, a group in which a methylene group which configures the ring skeleton of the alicyclic hydrocarbon group described above is substituted with an ester structure, that is, a lactone group, is preferable and a lactone group which has a polycyclic structure is more preferable. In particular, since the diffusibility of the generated acid is small, a group in which a polycyclic lactone group is substituted with an alkyl group, a cycloalkyl group, a hydroxyl group, a carboxyl group, or the like is preferable. The substituent group is preferably an alkyl group and the number of the substituent groups is preferably 1 to 5 and more preferably 2 or 3. Having 2 or 3 alkyl groups as substituent groups more remarkably improves the pattern shape since the generated acid does not easily diffuse in the binder resin (the resin (B)).

Preferred examples of R₁ will be shown below.

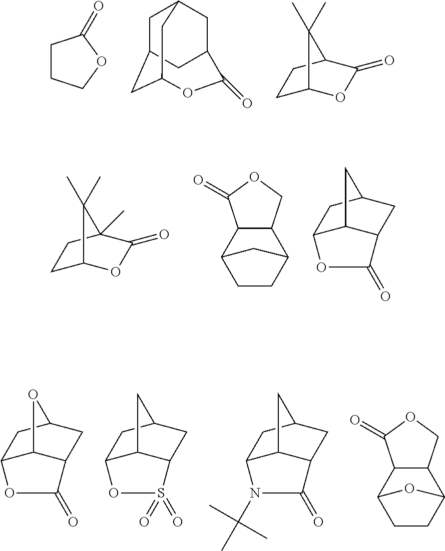

R₁ is particularly preferably a lactone group which will be shown below.

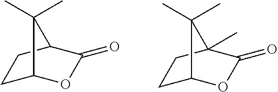

Examples of R₂ include an individual or a combination of two or more groups selected from a group consisting of an alkylene group, a phenylene group, an ether bond, a thioether bond, a carbonyl group, an ester bond, an amide bond, a urethane bond, or a ureylene bond. R₂ is preferably an alkylene group, more preferably a methylene group or an ethylene group, and particularly preferably a methylene group.

Rf is preferably a fluorine atom.

n₁ is preferably 1.

n₂ is preferably 1.

A monovalent cation as M⁺ is preferably a proton (H⁺), a metal cation such as a lithium ion, a sodium ion, and a potassium ion, or an onium ion such as an ammonium ion, a sulfonium ion, an iodonium ion, and a phosphonium ion. The monovalent cation as M⁺ is more preferably a sulfonium ion.

M⁺ is even more preferably a sulfonium cation which is represented by General Formula (II) or (III) below.

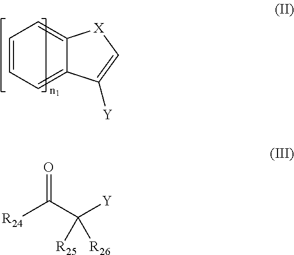

In General Formulas (II) and (III),

Y represents a structure represented by any of General Formulas (V-1) to (V-3) below.

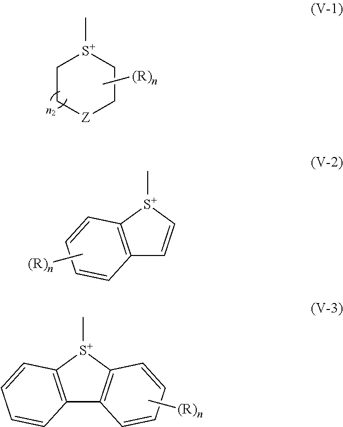

n₁ and n₂ are each independently 0 or 1.

X and Z represent any of —CH₂—, —CR₂₁═CR₂₂—, —NR₂₃—, —S—, and —O— and R₂₁, R₂₂, and R₂₃ each independently represent a hydrogen atom, a substituted or unsubstituted alkyl group, a cycloalkyl group, or an alkoxy group.

R₂₄ represents a substituted or unsubstituted aryl group.

R₂₅ and R₂₆ each independently represent a hydrogen atom, a substituted or unsubstituted alkyl group, or a cycloalkyl group, and R₂₅ and R₂₆ may form a ring by linking with each other.

(R)ₙ represents a substituent group.

Examples of an anion structure of a compound which is represented by General Formula (I) include the structures which are shown below.

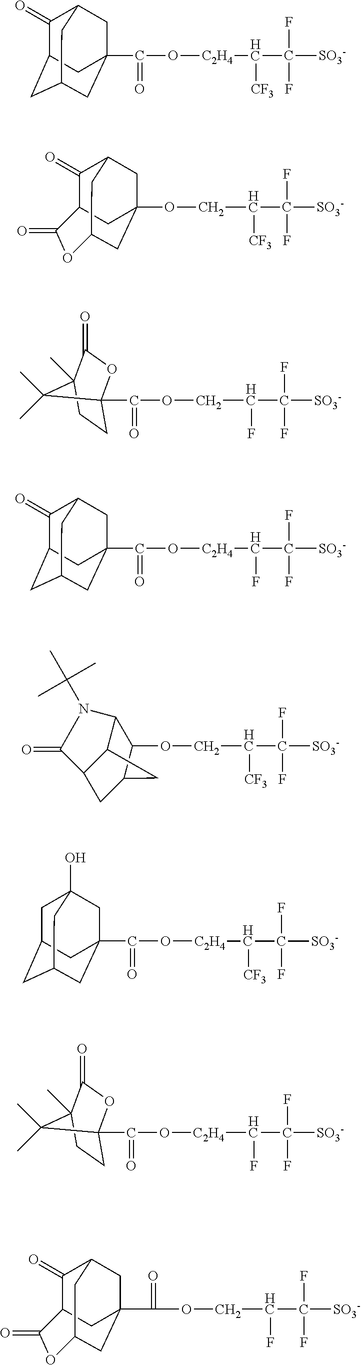

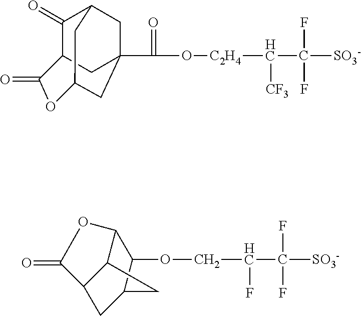

The content of the compounds (A) in the composition of the present invention is preferably 0.1 mass % to 30 mass %, more preferably 3 mass % to 25 mass %, and even more preferably 7 mass % to 20 mass %, based on the total solid content of the composition.

In addition, the composition of the present invention may include two or more types of the compounds (A) and may include a photoacid generator (also referred to below as a compound (A′)) other than the compounds (A) in addition to the compounds (A). In a case where the composition of the present invention includes two or more types of photoacid generators, the total content of the photoacid generators is preferably within the range described above.

As the compound (A′), it is possible to appropriately select and use a photo-cationic polymerization photoinitiator, a photo-radical polymerization photoinitiator, a light decolorant for dyes, a photodiscoloration agent, a known compound which generates an acid by irradiation with active light or radiation which is used for microresists and the like, or mixtures thereof

Examples thereof include diazonium salt, phosphonium salt, sulfonium salt, iodonium salt, imide sulfonate, oxime sulfonate, diazo disulfone, disulfone, and o-nitrobenzyl sulfonate.

In addition, it is possible to use the groups which generate an acid by irradiation with active light or radiation, or compounds which introduce the compounds to a main chain or a side chain of a polymer, for example, the compounds described in U.S. Pat. No. 3,849,137A, DE3914407A, JP1988-26653A (JP-S63-26653A), JP1980-164824A (JP-S55-164824A), JP1987-69263A (JP-S62-69263A), JP1988-146038A (JP-S63-146038A), JP1988-163452A (JP-S63-163452A), JP1987-153853A (JP-S62-153853A), JP1988-146029A (JP-S63-146029A), and the like.

Furthermore, it is also possible to use the compounds which generate acid using light described in U.S. Pat. No. 3,779,778A, EP126712B, and the like.

Preferred examples of compounds (A′) include compounds which are represented by General Formulas (ZI), (ZII), and (ZIII) below.

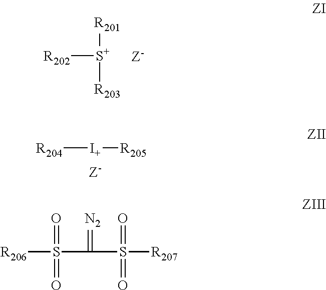

In General Formula (ZI) above,

R₂₀₁, R₂₀₂, and R₂₀₃ each independently represent an organic group.

The number of carbon atoms of the organic group as R₂₀₁, R₂₀₂, and R₂₀₃ is generally 1 to 30 and preferably 1 to 20.

In addition, two out of R₂₀₁ to R₂₀₃ may bond with each other to form a ring structure, and an oxygen atom, a sulfur atom, an ester bond, an amide bond, and a carbonyl group may be included in the ring. Examples of groups formed by two out of R₂₀₁ to R₂₀₃ bonding with each other include an alkylene group (for example, a butylene group or a pentylene group).

Z⁻ represents a non-nucleophilic anion.

Examples of the non-nucleophilic anion as Z— include a sulfonic acid anion, a carboxylic acid anion, a sulfonylimide anion, a bis(alkylsulfonyl) imide anion, a tris(alkylsulfonyl) methyl anion, and the like.

The non-nucleophilic anion is an anion in which the ability to cause a nucleophilic reaction is remarkably low and an anion which is able to suppress decomposition over time due to an intramolecular nucleophilic reaction. Therefore, the temporal stability of a resist is improved.

Examples of the sulfonic acid anion include an aliphatic sulfonic acid anion, an aromatic sulfonic acid anion, a camphor sulfonic acid anion, and the like.

Examples of the carboxylic acid anion include an aliphatic carboxylic acid anion, an aromatic carboxylic acid anion, an aralkyl carboxylic acid anion, and the like.

An aliphatic moiety in the aliphatic sulfonic acid anion may be an alkyl group or a cycloalkyl group, and is preferably an alkyl group with 1 to 30 carbon atoms and a cycloalkyl group with 3 to 30 carbon atoms and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, a bornyl group, and the like.

An aromatic group in the aromatic sulfonic acid anion is preferably an aryl group with 6 to 14 carbon atoms and examples thereof include a phenyl group, a tolyl group, a naphthyl group, and the like.

The alkyl group, cycloalkyl group, and aryl group in the aliphatic sulfonic acid anion and the aromatic sulfonic acid anion may have a sub stituent group. Examples of the sub stituent group of the alkyl group, the cycloalkyl group, and the aryl group in the aliphatic sulfonic acid anion and the aromatic sulfonic acid anion include a nitro group, a halogen atom (a fluorine atom, a chlorine atom, a bromine atom, and an iodine atom), a carboxyl group, a hydroxyl group, an amino group, a cyano group, an alkoxy group (preferably with 1 to 15 carbon atoms), a cycloalkyl group (preferably with 3 to 15 carbon atoms), an aryl group (preferably with 6 to 14 carbon atoms), an alkoxycarbonyl group (preferably with 2 to 7 carbon atoms), an acyl group (preferably with 2 to 12 carbon atoms), an alkoxycarbonyloxy group (preferably with 2 to 7 carbon atoms), an alkylthio group (preferably 1 to 15 carbon atoms), an alkyl sulfonyl group (preferably 1 to 15 carbon atoms), an alkylimino sulfonyl group (preferably with 2 to 15 carbon atoms), an aryloxy sulfonyl group (preferably with 6 to 20 carbon atoms), an alkylaryloxy sulfonyl group (preferably with 7 to 20 carbon atoms), a cycloalkylaryloxy sulfonyl group (preferably with 10 to 20 carbon atoms), an alkyloxyalkyloxy group (preferably with 5 to 20 carbon atoms), a cycloalkylalkyloxyalkyloxy group (preferably with 8 to 20 carbon atoms), and the like. For of the aryl group of each group and the ring structure, examples of the substituent group further include an alkyl group (preferably with 1 to 15 carbon atoms).

Examples of an aliphatic moiety in the aliphatic carboxylic acid anion include the same alkyl groups and cycloalkyl groups as in the aliphatic sulfonic acid anion.

Examples of an aromatic group in the aromatic carboxylic acid anion include the same aryl groups as in the aromatic sulfonic acid anion.

The aralkyl group in the aralkyl carboxylic acid anion is preferably an aralkyl group with 6 to 12 carbon atoms and examples thereof include a benzyl group, a phenethyl group, a naphthylmethyl group, a naphthylethyl group, a naphthylbutyl group, and the like.

An alkyl group, a cycloalkyl group, an aryl group, and an aralkyl group in the aliphatic carboxylic acid anion, the aromatic carboxylic acid anion, and the aralkyl carboxylic acid anion may have a substituent group. Examples of a substituent group of an alkyl group, a cycloalkyl group, an aryl group, and an aralkyl group in the aliphatic carboxylic acid anion, the aromatic carboxylic acid anion, and the aralkyl carboxylic acid anion include the same halogen atoms, alkyl groups, cycloalkyl groups, alkoxy groups, alkylthio groups, and the like as in the aromatic sulfonic acid anion.

Examples of the sulfonylimide anion include a saccharin anion.

An alkyl group in the bis(alkylsulfonyl) imide anion and a tris(alkylsulfonyl) methyl anion is preferably an alkyl group with 1 to 5 carbon atoms and examples thereof include a methyl group, an ethyl group, a propyl group, an isopropyl group, an n-butyl group, an isobutyl group, a sec-butyl group, a pentyl group, a neopentyl group, and the like. Examples of a substituent group of the alkyl groups include a halogen atom, an alkyl group which is substituted with a halogen atom, an alkoxy group, an alkylthio group, an alkyloxy sulfonyl group, an aryloxy sulfonyl group, a cycloalkylaryloxy sulfonyl group, and the like and an alkyl group which is substituted with a fluorine atom is preferable.

Examples of other non-nucleophilic anions include fluorinated phosphorus, fluorinated boron, fluorinated antimony, and the like.

Preferred examples of a non-nucleophilic anion of Z⁻ include an aliphatic sulfonic acid anion in which the α-position of sulfonic acid is substituted with a fluorine atom, an aromatic sulfonic acid anion which is substituted with a fluorine atom or a group which has a fluorine atom, a bis(alkylsulfonyl) imide anion in which an alkyl group is substituted with a fluorine atom, and a tris(alkylsulfonyl) methide anion in which an alkyl group is substituted with a fluorine atom. The non-nucleophilic anion is more preferably a perfluoro aliphatic sulfonic acid anion with 4 to 8 carbon atoms or a benzene sulfonic acid anion which has a fluorine atom, and even more preferably a nonafluoro butane sulfonic acid anion, perfluoro octane sulfonic acid anion, a pentafluoro benzene sulfonic acid anion, or a 3,5-bis (trifluoro methyl) benzene sulfonic acid anion.

Here, the compound may have a plurality of structures which are represented by General Formula (ZI). For example, the compound may have a structure in which at least one of R₂₀₁ to R₂₀₃ of compounds which are represented by General Formula (ZI) is bonded with at least one of R₂₀₁ to R₂₀₃ of another compound which is represented by General Formula (ZI).

Particularly preferable examples among acid generators which may be used with the acid generator of the present invention will be given below.

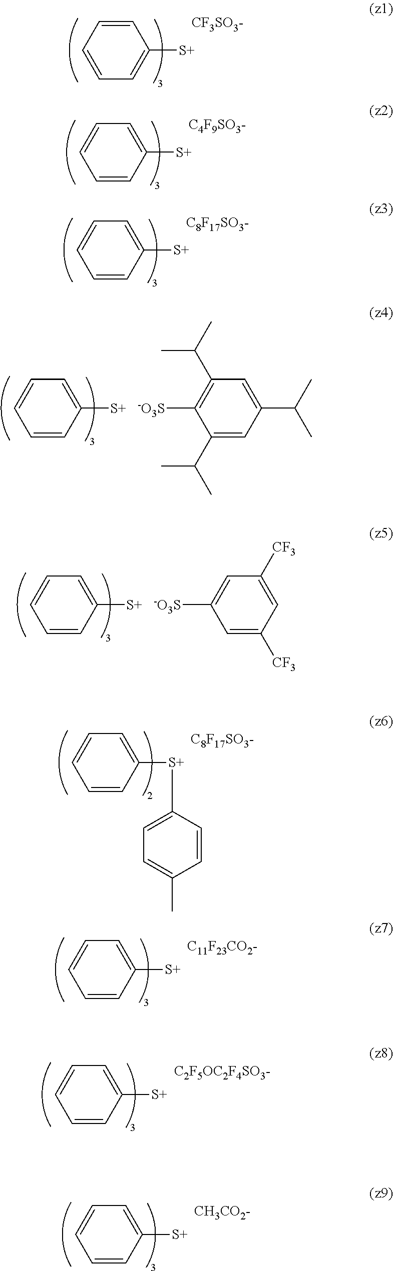

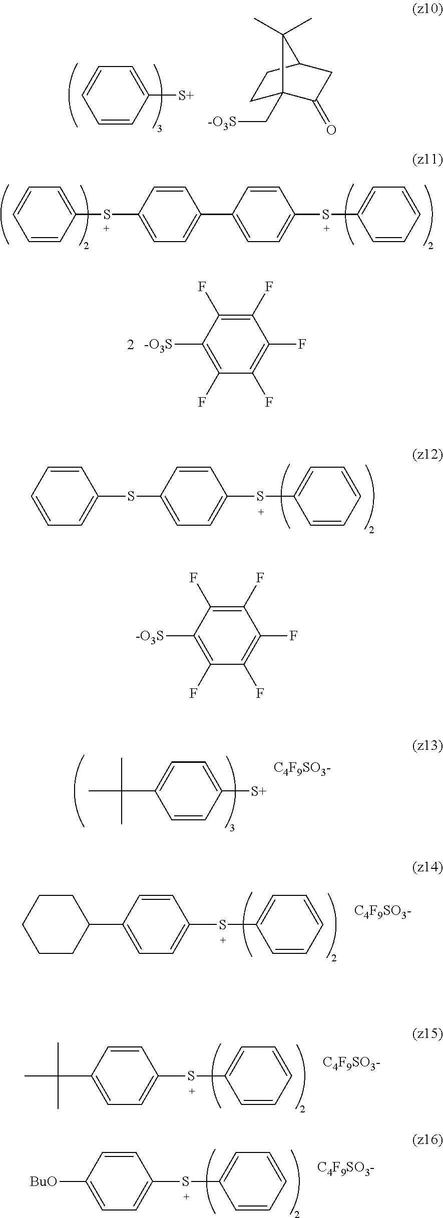

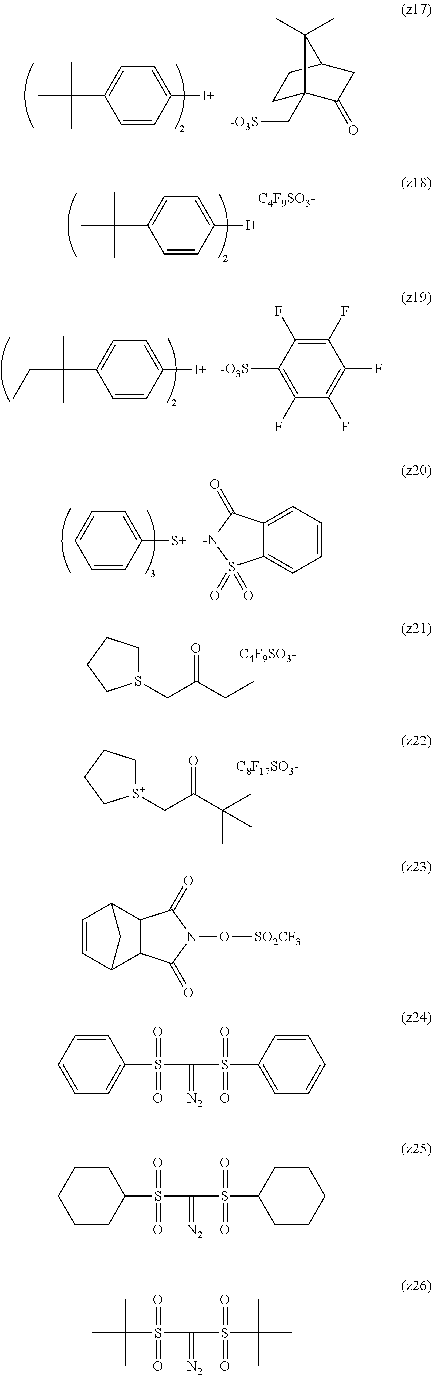

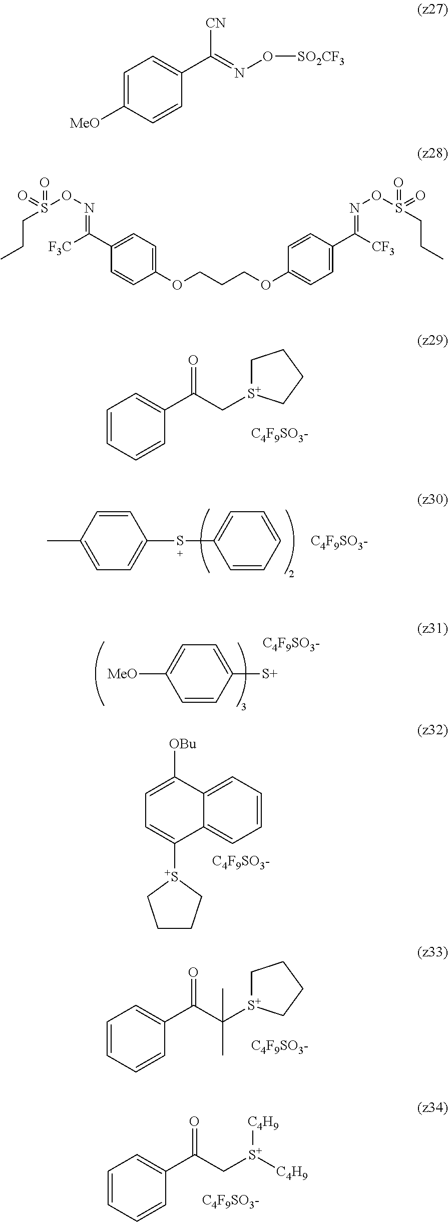

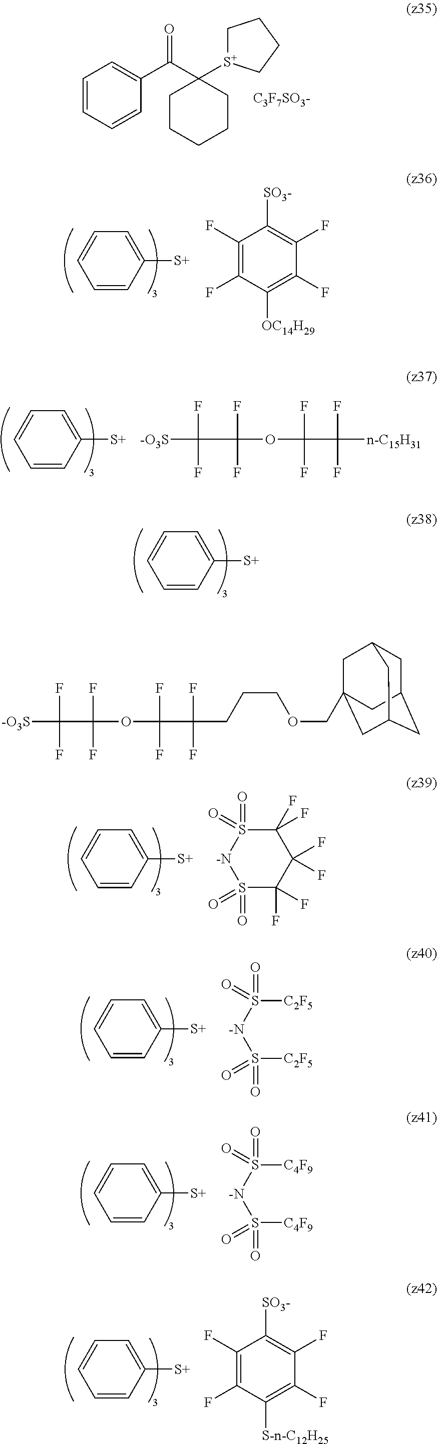

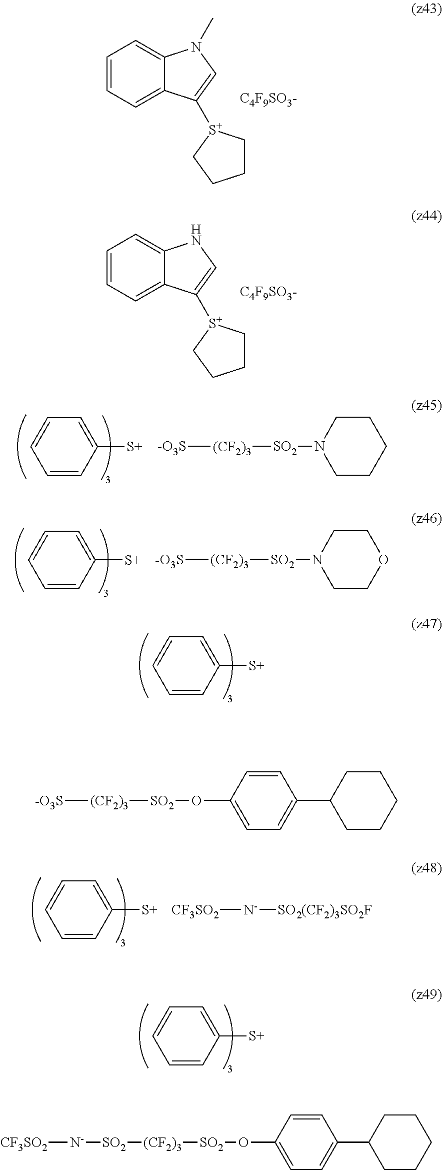

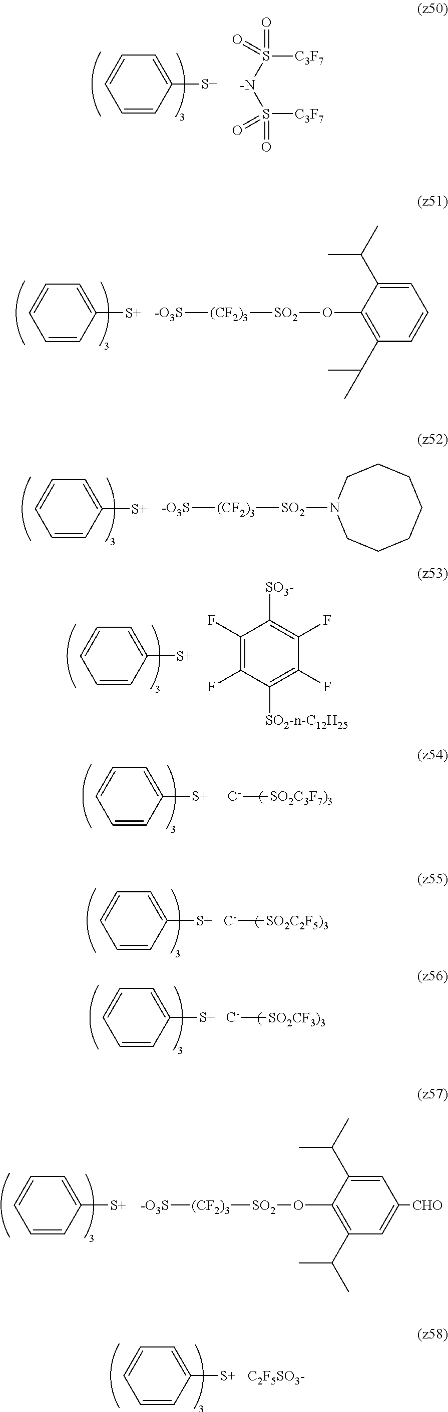

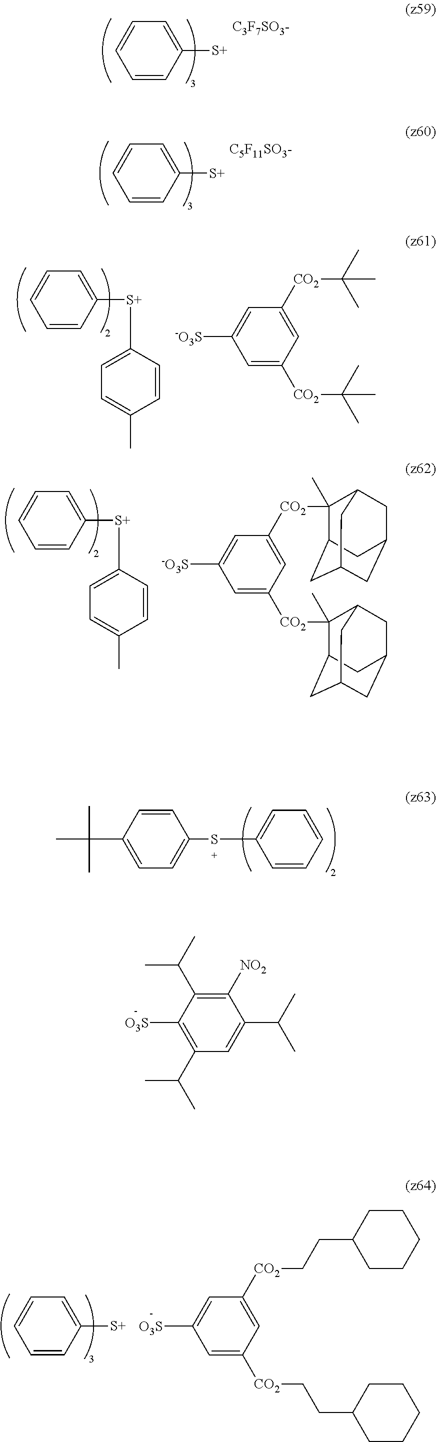

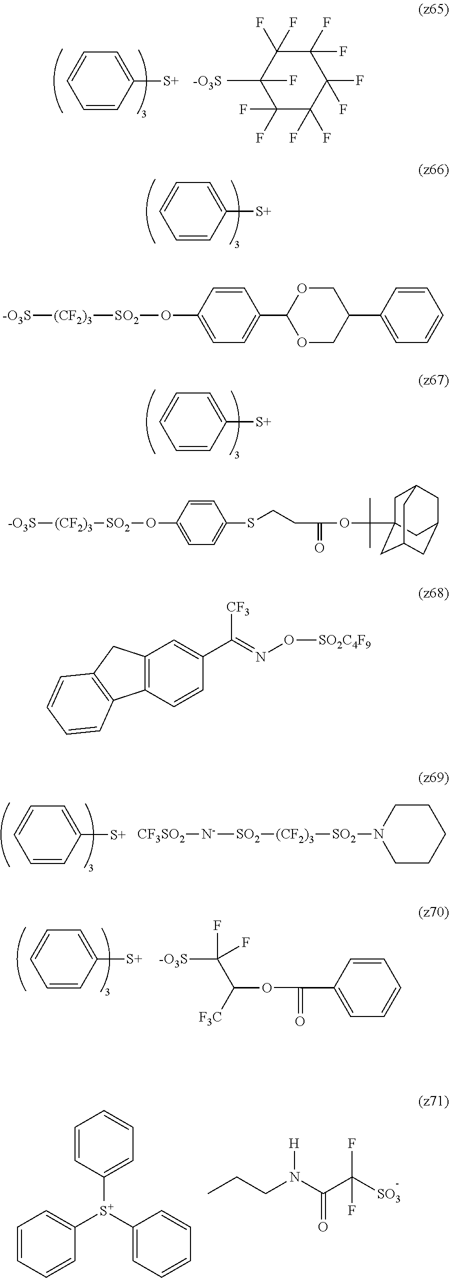

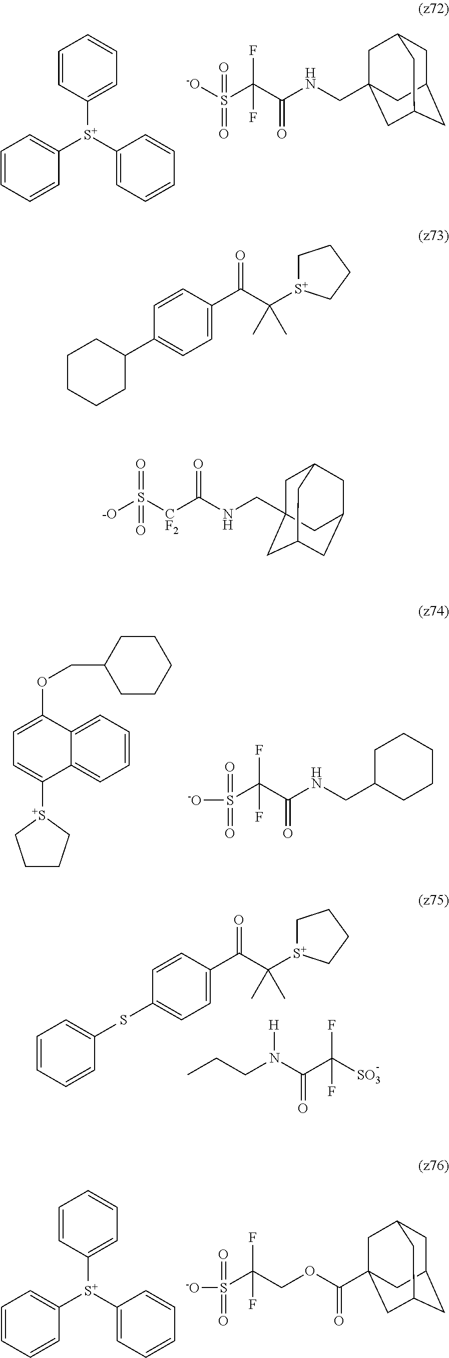

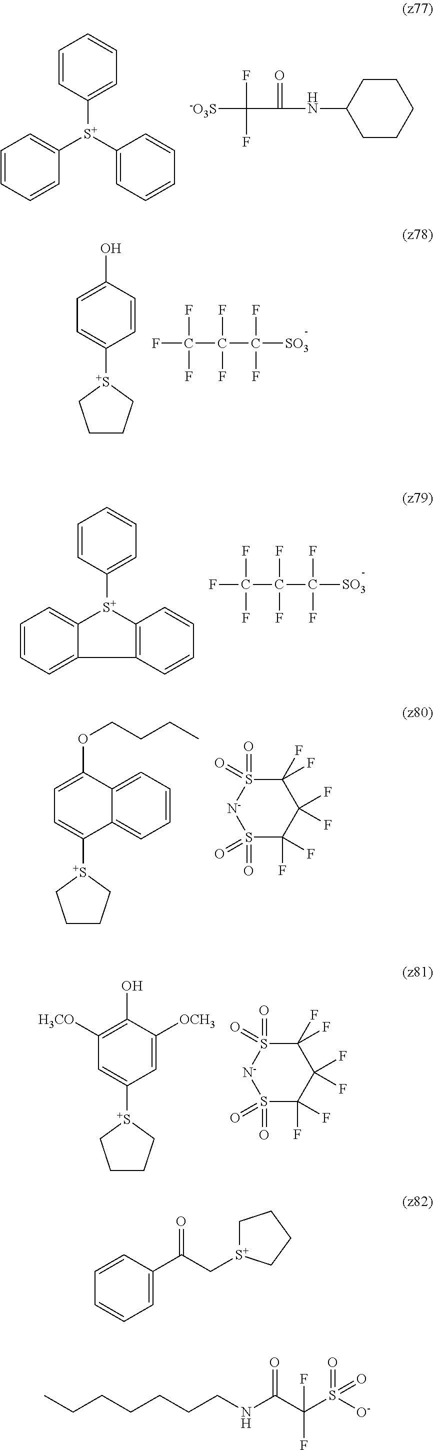

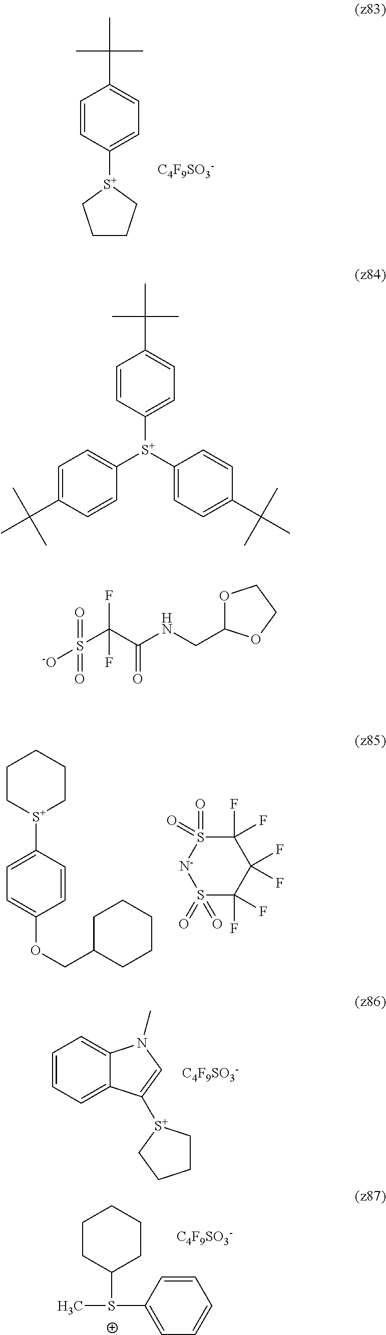

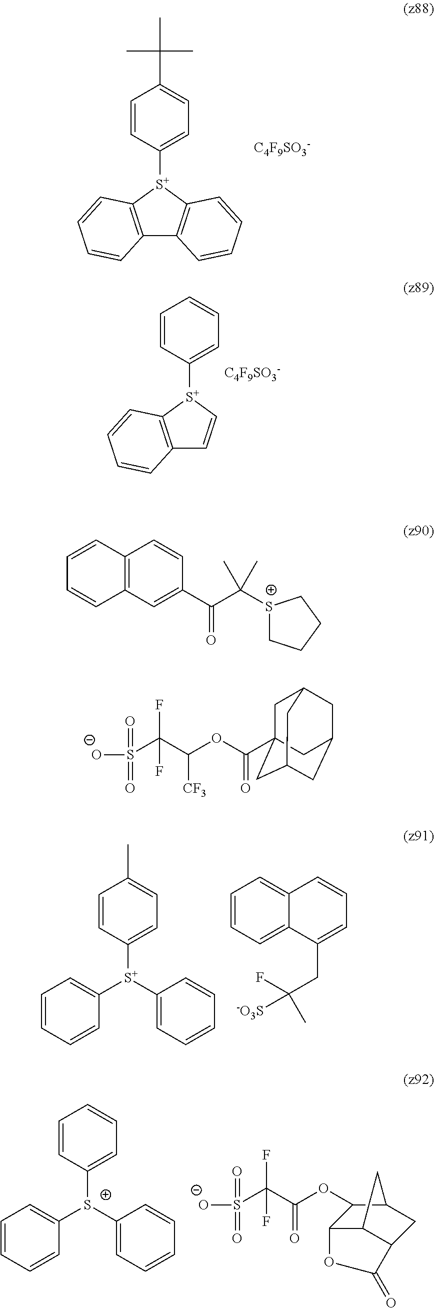

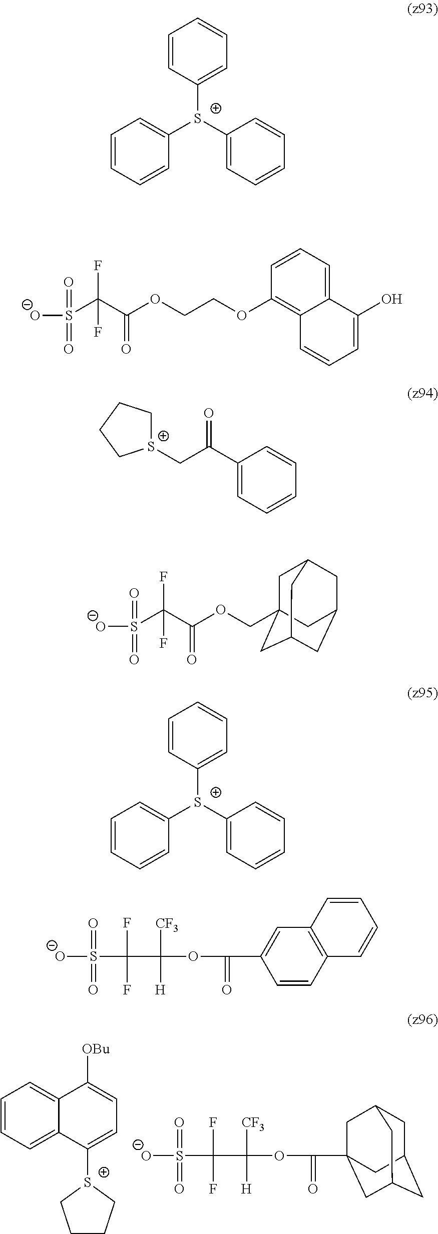

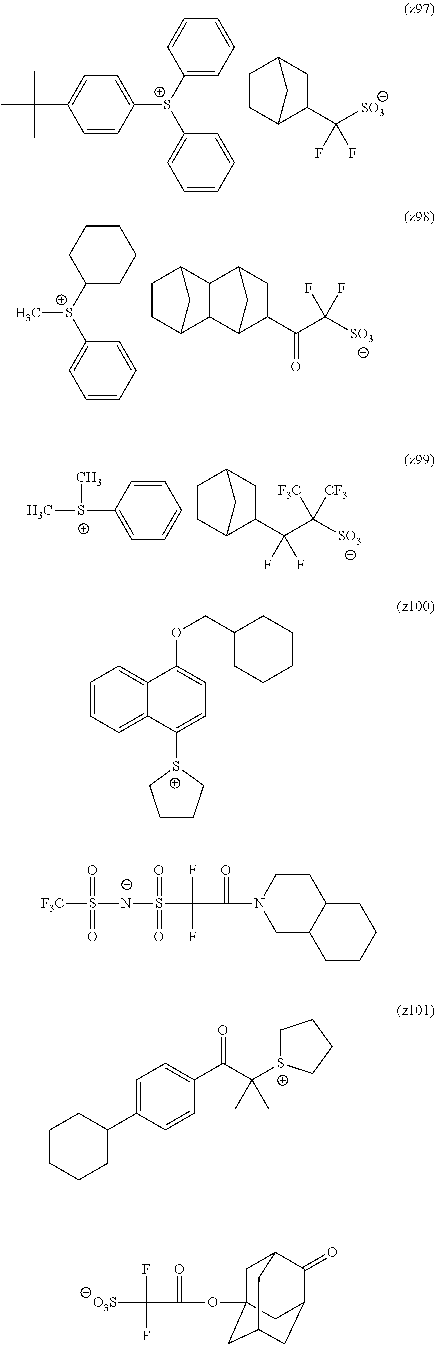

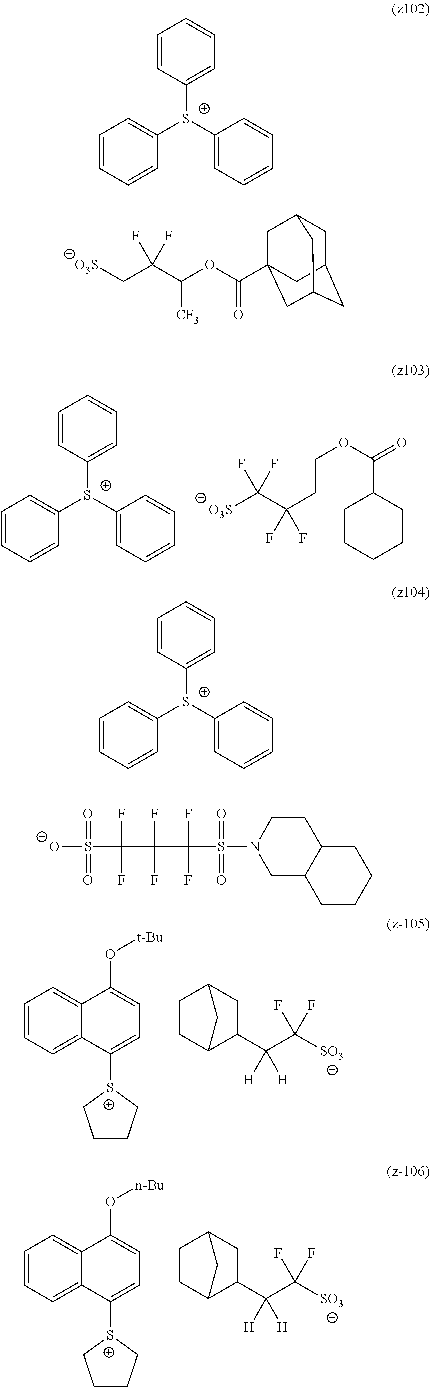

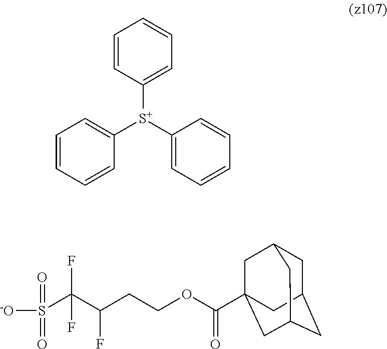

The compounds are able to maintain a high transmittance in the formed film with respect to ArF light with a wavelength of 193 nm and, for example, for a 100 nm film, it is possible to make the transmittance with respect to light with a wavelength of 193 nm 60% to 85%. The transmittance with respect to ArF light being high imparts a favorable performance in patterning using ArF light.

It is possible to calculate the transmittance with respect to light with a wavelength of 193 nm, for example, by coating an active light-sensitive or radiation-sensitive resin composition on a quartz glass substrate by spin coating, forming a film with a film thickness of 100 nm by performing prebaking at 100° C., and determining the light absorbance of the film at a wavelength 193 nm using an Ellipsometer EPM-222 (manufactured by J. A. Woollam Co., Inc.) or the like.

The total amount of the compound (A′) preferably contains 50 mass % to 100 mass % of the compounds which are represented by General Formula (1-1) or (1-2), more preferably 80 mass % to 100 mass %, and particularly preferably 90 mass % to 100 mass %.

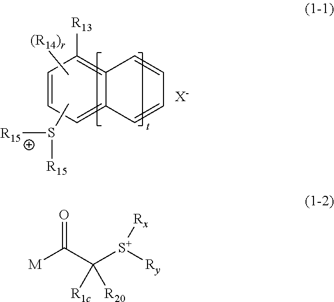

In General Formula (1-1),

R₁₃ represents a hydrogen atom, a fluorine atom, a hydroxyl group, an alkyl group, a cycloalkyl group, an alkoxy group, an alkoxycarbonyl group, a group which has a monocyclic or polycyclic cycloalkyl skeleton, and an alkylene oxide chain.

In a case where a plurality of R₁₄ is present, R₁₄ each independently represent an alkyl group, a cycloalkyl group, an alkoxy group, an alkoxycarbonyl group, an alkylcarbonyl group, an alkylsulfonyl group, a cycloalkylsulfonyl group, a group which has a monocyclic or polycyclic cycloalkyl skeleton, or an alkylene oxide chain.

R₁₅ each independently represents an alkyl group, a cycloalkyl group, or a naphthyl group. Two of R₁₅'s may bond with each other to form a ring.

1 represents an integer of 0 to 2.

r represents an integer of 0 to 8.

X⁻ represents a non-nucleophilic anion.

In General Formula (1-2),

M represents an alkyl group, a cycloalkyl group, an aryl group, or a benzyl group, and, when M has a ring structure, the ring structure may include an oxygen atom, a sulfur atom, an ester bond, an amide bond, or a carbon-carbon double bond.

R_{1c} and R_{2c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, an alkoxycarbonylalkyl group, an allyl group, or a vinyl group.

Rₓ and R_{y} may bond with each other to form a ring. In addition, at least two of M, R_{1c}, and R_{2c} may bond with each other to form a ring and a carbon-carbon double bond may be included in the ring structure.

X⁻ represents a non-nucleophilic anion.

Firstly, detailed description will be given of General Formula (1-1).

In General Formula (1-1), an alkyl group of R₁₃, R₁₄, and R₁₅ is straight-chain or branched and preferably has 1 to 10 carbon atoms and examples thereof include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group, and the like. Among the alkyl groups, a methyl group, an ethyl group, an n-butyl group, a t-butyl group, and the like are preferable.

Examples of the cycloalkyl group of R₁₃, R₁₄, and R₁₅ include a cyclopropyl group, a cyclobutyl group, a cyclopentyl group, a cyclohexyl group, a cycloheptyl group, a cyclooctyl group, a cyclododecanyl group, a cyclopentenyl group, a cyclohexenyl group, a cyclooctadienyl group, an adamantyl group, and the like, and cyclopropyl group, cyclopentyl group, cyclohexyl group, and cyclooctyl group are particularly preferable.

An alkoxy group of R₁₃ and R₁₄ is straight-chain, branched, or cyclic and preferably has 1 to 10 carbon atoms and examples thereof include a methoxy group, an ethoxy group, an n-propoxy group, an i-propoxy group, an n-butoxy group, 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, a cycloheptyloxy group, a cyclooctyloxy group, and the like. Among the alkoxy groups, a methoxy group, an ethoxy group, an n-propoxy group, an n-butoxy group, and the like are preferable.

An alkoxycarbonyl group of R₁₃ and R₁₄ is straight-chain or branched and preferably has 2 to 11 carbon atoms and examples thereof include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group, and the like. Among the alkoxycarbonyl groups, a methoxycarbonyl group, an ethoxycarbonyl group, an n-butoxycarbonyl group, and the like are preferable.

Examples of a group which has the monocyclic or polycyclic cycloalkyl skeleton of R₁₃ and R₁₄ include a monocyclic or polycyclic cycloalkyloxy group, or an alkoxy group which has a monocyclic or polycyclic cycloalkyl group. The groups may further have a sub stituent group.

A monocyclic or polycyclic cycloalkyloxy group of R₁₃ and R₁₄ preferably has 7 or more carbon atoms in total, and more preferably has 7 to 15 carbon atoms in total, and additionally, preferably has a monocyclic cycloalkyl skeleton. The monocyclic cycloalkyloxy group with 7 or more carbon atoms in total is a monocyclic cycloalkyloxy group which arbitrarily has a substituent group of an alkyl group such as a methyl group, an ethyl group, a propyl group, a butyl group, a pentyl group, a hexyl group, a heptyl group, an octyl group, a dodecyl group, a 2-ethylhexyl group, an isopropyl group, a sec-butyl group, a t-butyl group, and an iso-amyl, a hydroxyl group, a halogen atom (fluorine, chloride, bromine, and iodine), a nitro group, a cyano group, an amide group, a sulfonamide group, an alkoxy group such as a methoxy group, an ethoxy group, a hydroxyethoxy group, a propoxy group, a hydroxypropoxy group, and a butoxy group, an alkoxycarbonyl group such as a methoxycarbonyl group and an ethoxycarbonyl group, an acyl group such as a formyl group, an acetyl group, and a benzoyl group, an acyloxy group such as an acetoxy group and a butyryloxy group, and a carboxy group in a cycloalkyloxy group such as a cyclopropyloxy group, a cyclobutyloxy group, a cyclopentyloxy group, a cyclohexyloxy group, a cycloheptyloxy group, a cyclooctyloxy group, and a cyclododecanyloxy group, and represents a monocyclic cycloalkyloxy group in which the total number of carbon atoms combined with the arbitrary substituent group on the cycloalkyl group is 7 or more.

In addition, examples of a polycyclic cycloalkyloxy group with 7 or more carbon atoms in total include a norbornyloxy group, a tricyclodecanyloxy group, a tetracyclodecanyloxy group, an adamantanetyloxy group, and the like, and these examples may have the substituent groups described above.

The alkoxy group which has a monocyclic or polycyclic cycloalkyl skeleton of R₁₃ and R₁₄ preferably has 7 or more carbon atoms in total, and more preferably has 7 to 15 carbon atoms in total, and additionally, is preferably an alkoxy group which has a monocyclic cycloalkyl skeleton. The alkoxy group with 7 or more carbon atoms in total which has a monocyclic cycloalkyl skeleton is an alkoxy group in which an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, t-butoxy, and iso-amyloxy is substituted with a monocyclic cycloalkyl group which may have the substituent group described above and represents an alkoxy group in which the total number of the carbon atoms including the substituent group is 7 or more. Examples thereof include a cyclohexylmethoxy group, a cyclopentylethoxy group, a cyclohexylethoxy group, and the like, and a cyclohexylmethoxy group is preferable.

In addition, examples of an alkoxy group with 7 or more carbon atoms in total which has a polycyclic cycloalkyl skeleton include a norbornylmethoxy group, norbornylethoxy group, a tricyclodecanylmethoxy group, a tricyclodecanylethoxy group, a tetracyclodecanylmethoxy group, a tetracyclodecanylethoxy group, an adamantanemetylmethoxy group, an adamantanemetylethoxy group, and the like and among these, a norbornylmethoxy group and a norbornylethoxy group are preferable. These may have the substituent groups described above.

Examples of the alkyl group of the alkylcarbonyl group of R₁₄ include the same specific examples as the alkyl group for R₁₃ to R₁₅ described above.

The alkylsulfonyl group and the cycloalkylsulfonyl group of R₁₄ are straight-chain, branched, or cyclic and preferably have 1 to 10 carbon atoms and examples thereof include a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, n-nonanesulfonyl group, an n-decanesulfonyl group, a cyclopentanesulfonyl group, a cyclohexanesulfonyl group, and the like. Among the alkylsulfonyl groups and the cycloalkylsulfonyl groups, a methanesulfonyl group, an ethanesulfonyl group, an n-propanesulfonyl group, an n-butanesulfonyl group, a cyclopentanesulfonyl group, a cyclohexanesulfonyl group, and the like are preferable.

Examples of the alkylene oxide chain of R₁₃ and R₁₄ include an ethylene oxide chain, a propylene oxide chain, and a butylene oxide chain. The number of repeating units of the alkylene oxide chain is preferably 1 to 10, more preferably 1 to 5, and particularly preferably 2 to 4.

Each of the groups described above may have a substituent group and examples of the sub stituent group include a halogen atom (for example, a fluorine atom), a hydroxyl group, a carboxyl group, a cyano group, a nitro group, an alkoxy group, an alkoxyalkyl group, an alkoxycarbonyl group, an alkoxycarbonyloxy group, and the like.

Examples of the alkoxy group described above include a straight-chain, branched, or cyclic alkoxy group or the like with 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, and a cyclohexyloxy group.

Examples of the alkoxyalkyl group described above include a straight-chain, branched, or cyclic alkoxyalkyl group or the like with 2 to 21 carbon atoms, such as a methoxymethyl group, an ethoxymethyl group, a 1-methoxyethyl group, a 2-methoxyethyl group, a 1-ethoxyethyl group, and a 2-ethoxyethyl group.

Examples of the alkoxycarbonyl group described above include a straight-chain, branched, or cyclic alkoxycarbonyl group or the like with 2 to 21 carbon atoms such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, and a cyclohexyloxycarbonyl group.

Examples of the alkoxycarbonyloxy group described above include a straight-chain, branched, or cyclic alkoxycarbonyloxy group or the like with 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, a cyclopentyloxycarbonyloxy group, and a cyclohexyloxycarbonyloxy group.

Examples of a ring structure which two R₁₅'s may bond with each other to form include a ring with 5 members or 6 members which two divalent R₁₅'s form with a sulfur atom in General Formula (1-1), and particularly preferably a ring with 5 members (that is, a tetrahydrothiophene ring), and the ring structure may be condensed with an aryl group or a cycloalkyl group. The divalent R₁₅ may have a substituent group and examples of the sub stituent group include a hydroxyl group, a carboxyl group, a cyano group, a nitro group, an alkoxy group, an alkoxyalkyl group, an alkoxycarbonyl group, an alkoxycarbonyloxy group, and the like.

R₁₅ is preferably a methyl group, an ethyl group, a naphthyl group, a divalent group in which two R₁₅'s are bonded with each other to form a tetrahydrothiophene ring structure with a sulfur atom, or the like.

Examples of the substituent group which R₁₃ and R₁₄ may have include a hydroxyl group, an alkoxy group, an alkoxycarbonyl group, or a halogen atom (particularly, a fluorine atom).

l is preferably 0 or 1, and more preferably 1.

r is preferably 0 to 2.

Examples of the salts which are represented by General Formula (1-1) of the present invention include the specific examples below.

In the formulas below, X⁻ represents a counter anion.

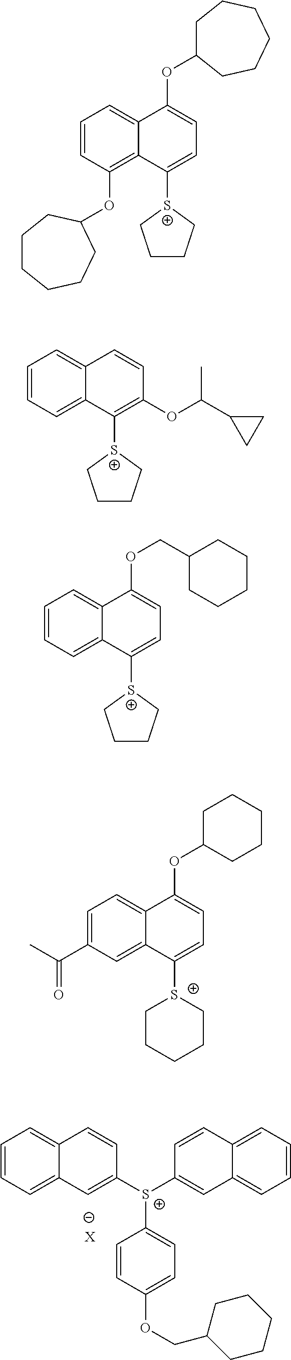

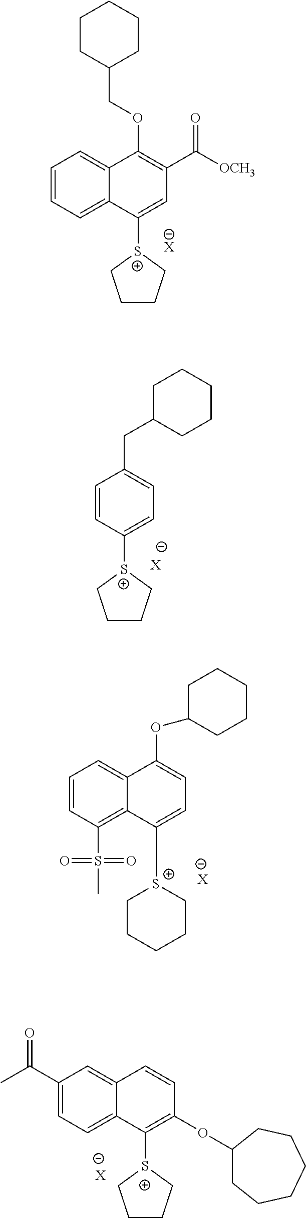

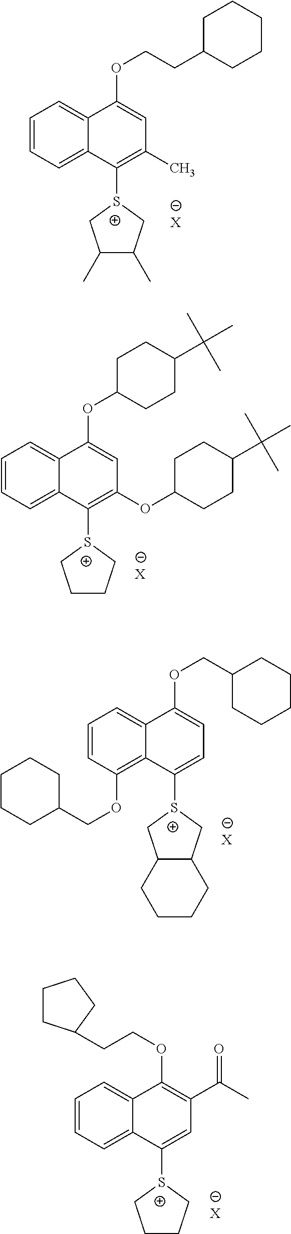

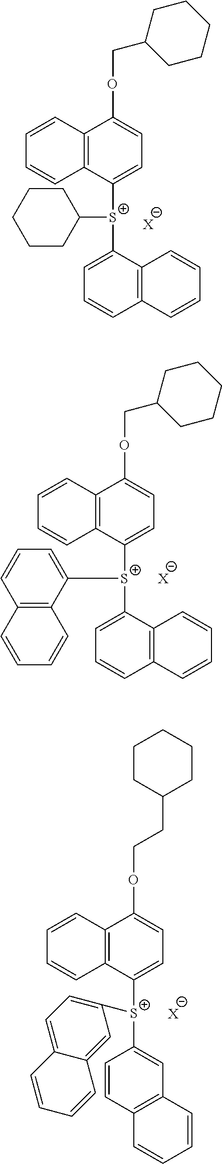

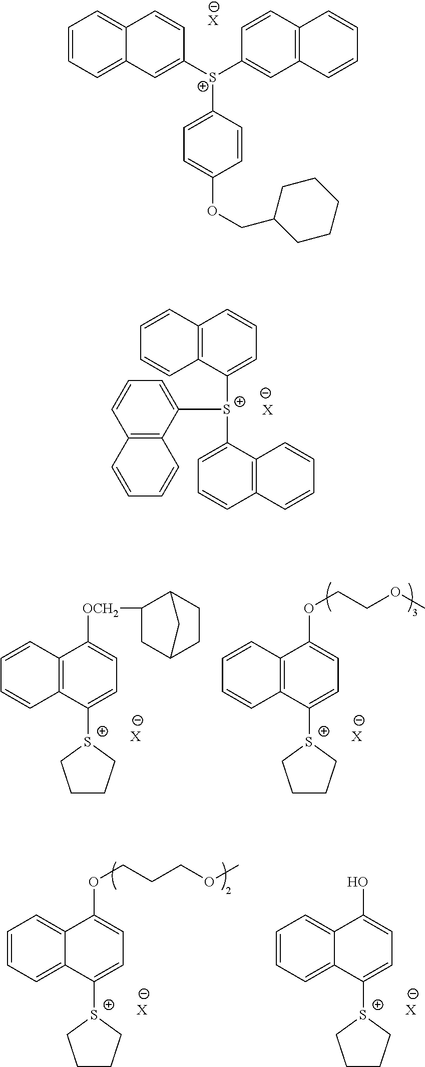

Next, description will be given of General Formula (1-2).

In the formula, R_{1c} and R_{2c} each independently represent a hydrogen atom, an alkyl group, a cycloalkyl group, a halogen atom, a cyano group, or an aryl group.

Rₓ and R_{y} each independently represent an alkyl group, a cycloalkyl group, a 2-oxoalkyl group, an alkoxycarbonylalkyl group, an allyl group, or a vinyl group.

M represents an alkyl group, a cycloalkyl group, an aryl group, or a benzyl group and, when M has a ring structure, the ring structure may include an oxygen atom, a sulfur atom, an ester bond, an amide bond, or a carbon-carbon double bond.

Rₓ and R_{y} may bond with each other to form a ring. In addition, at least two of M, R_{1c}, and R_{2c} may bond with each other to form a ring and a carbon-carbon double bond may be included in the ring structure.

An alkyl group as M may be either straight-chain or branched and is, for example, an alkyl group with 1 to 20 carbon atoms, and preferably a straight-chain and branched alkyl group with 1 to 12 carbon atoms, and examples thereof include a methyl group, an ethyl group, an n-propyl group, an isopropyl group, an n-butyl group, a sec-butyl group, a tert-butyl group, a pentyl group, a hexyl group, an octyl group, and a 2-ethylhexyl group.

A cycloalkyl group as M is a cyclic alkyl group with 3 to 12 carbon atoms and examples thereof include a cyclopropyl group, a cyclobutyl group, a cyclopentyl group, a cyclohexyl group, a cycloheptyl group, a cyclodecyl group, and the like.

An aryl group as M preferably has 5 to 15 carbon atoms and examples thereof include a phenyl group and a naphthyl group.

Each group as M may have a cycloalkyl group, an alkoxy group, a halogen atom, a phenylthio group, and the like as a substituent group. A cycloalkyl group and an aryl group as M may further have an alkyl group as a substituent group. The number of carbon atoms of the substituent group is preferably 15 or less.

When M is a phenyl group, it is preferable to have at least one of a straight-chain, branched, or cyclic alkyl group, a straight-chain, branched, or cyclic alkoxy group, or a phenylthio group as a substituent group, and the sum of the carbon atoms of the substituent group is more preferably 2 to 15. Due to this, the solvent solubility is more improved and the generation of particles during the storage is suppressed.

Examples of an alkyl group as R_{1c} and R_{2c} include an alkyl group with 1 to 12 carbon atoms, and preferably a straight-chain and branched alkyl group with 1 to 5 carbon atoms (for example, a methyl group, an ethyl group, a straight-chain or branched propyl group).

Examples of the cycloalkyl group as R_{1c} and R_{2c} include a cycloalkyl group with 3 to 12 carbon atoms, preferably a cyclopropyl group, a cyclobutyl group, a cyclopentyl group, a cyclohexyl group, a cycloheptyl group, a cyclodecyl group, and the like.

Examples of a halogen atom include a fluorine atom, a chlorine atom, a bromine atom, and an iodine atom.

An aryl group as R_{1c} and R_{2c} preferably has 5 to 15 carbon atoms and examples thereof include a phenyl group and a naphthyl group.

Examples of a ring structure formed by at least two of M, R_{1c}, and R_{2c} bonding with each other preferably include a ring with 3 to 12 members, more preferably a ring with 3 to 10 members, and even more preferably a ring with 3 to 6 members. A ring skeleton may have a carbon-carbon double bond.

In a case where R_{1c} and R_{2c} bond with each other to form a ring, a group which R_{1c} and R_{2c} bond with each other to form is preferably an alkylene group with 2 to 10 carbon atoms and examples thereof include an ethylene group, a propylene group, a butylene group, a pentylene group, a hexylene group, and the like. In addition, a ring which R_{1c} and R_{2c} bond with each other to form may have a hetero atom such as an oxygen atom in a ring.

Examples of an alkyl group as Rₓ and R_{y} include the same examples as the alkyl group as R_{1c} and R_{2c}.

The cycloalkyl group is, for example, preferably a cycloalkyl group with 3 to 8 carbon atoms and examples thereof include a cyclopentyl group, a cyclohexyl group, and the like.

Examples of a 2-oxoalkyl group include a group which has >C═O in the second position of an alkyl group as R_{1c} and R_{2c}.

An alkoxy group in an alkoxycarbonylalkyl group may be straight-chain, branched, or cyclic, and examples thereof include an alkoxy group with 1 to 10 carbon atoms, preferably a straight-chain or branched alkoxy group with 1 to 5 carbon atoms (for example, a methoxy group, an ethoxy group, a straight-chain or branched propoxy group, a straight-chain or branched butoxy group, and a straight-chain or branched pentoxy group) and a cyclic alkoxy group with 3 to 8 carbon atoms (for example, a cyclopentyloxy group and a cyclohexyloxy group). In addition, examples of an alkyl group in an alkoxycarbonylalkyl group include an alkyl group with 1 to 12 carbon atoms, preferably a straight-chain alkyl group with 1 to 5 carbon atoms (for example, a methyl group and an ethyl group).

The allyl group is not particularly limited but is preferably an allyl group which is unsubstituted or substituted with a monocyclic, or polycyclic cycloalkyl group.

A vinyl group is not particularly limited, but is preferably a vinyl group which is unsubstituted or substituted with a monocyclic, or polycyclic cycloalkyl group.

Examples of a ring structure which Rₓ and R_{y} may bond with each other to form include a ring with 5 members or 6 members which a divalent Rₓ and R_{y} (for example, a methylene group, an ethylene group, a propylene group, and the like) form with a sulfur atom in General Formula (1-2), and particularly preferably a ring with 5 members (that is, a tetrahydrothiophene ring).

Rₓ and R_{y} are preferably an alkyl group with 4 or more carbon atoms, more preferably an alkyl group with 6 or more carbon atoms, and even more preferably an alkyl group with 8 or more carbon atoms.

Examples of a cation of a compound which is represented by General Formula (1-2) of the present invention include the specific examples below.

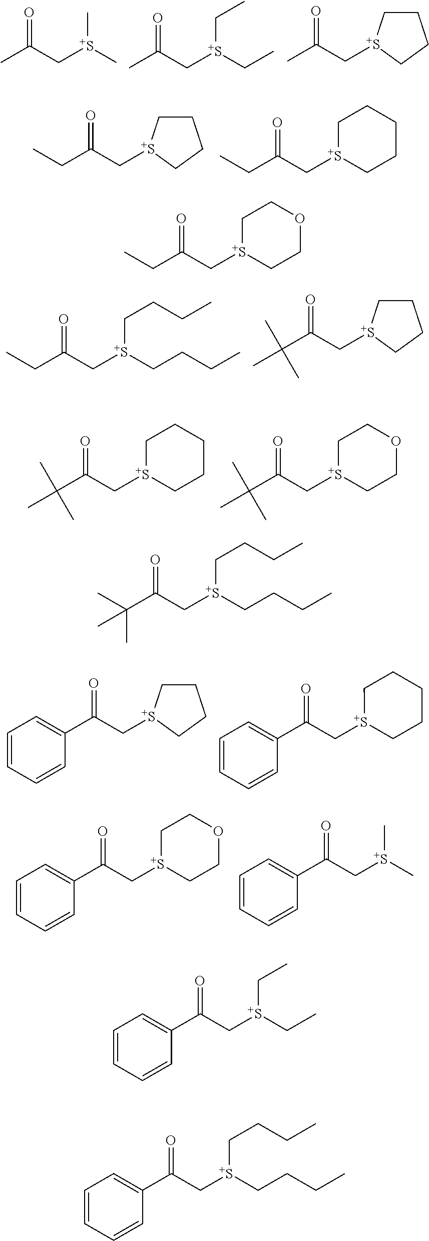

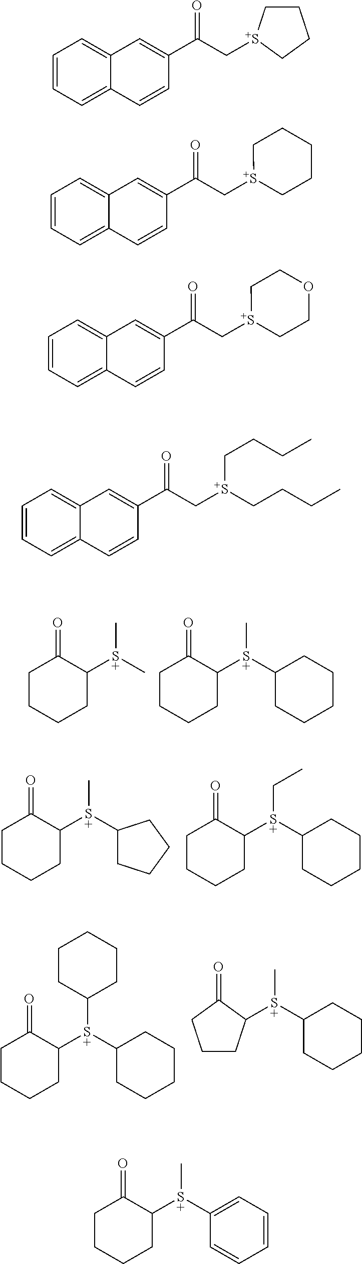

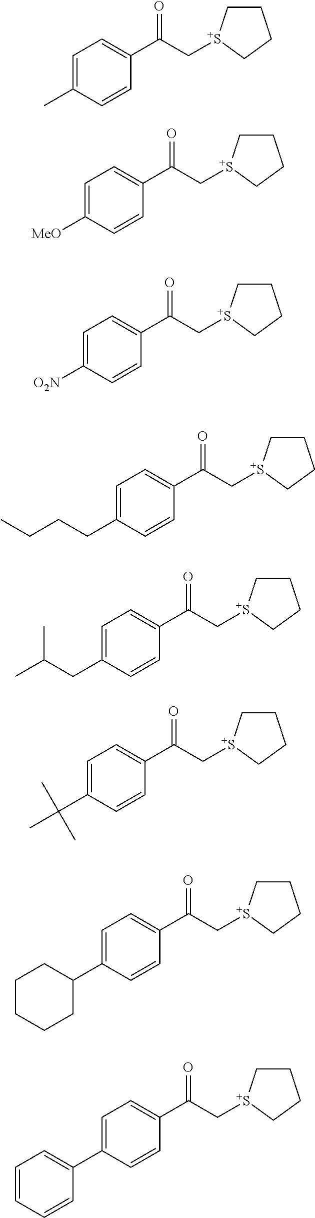

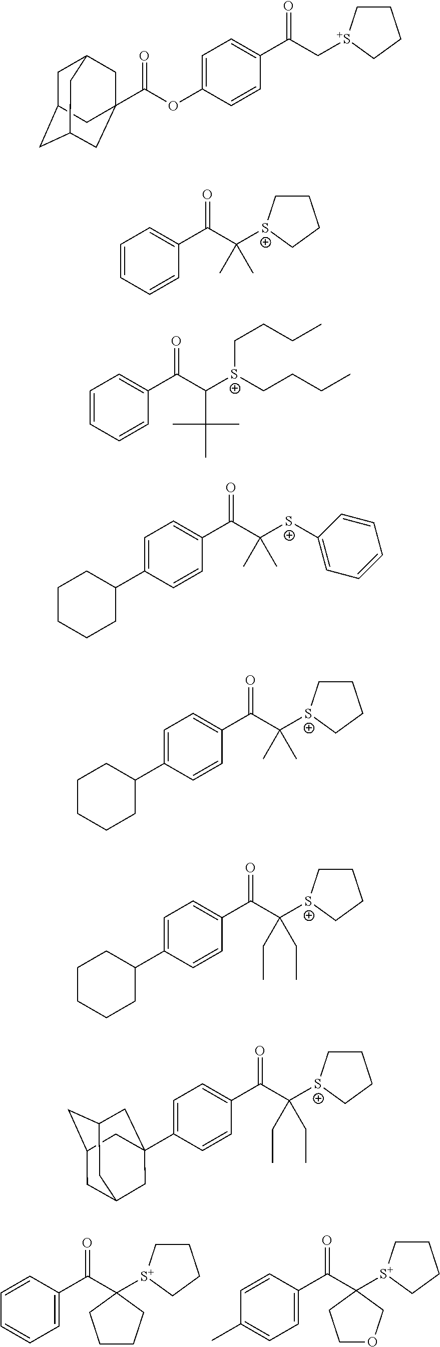

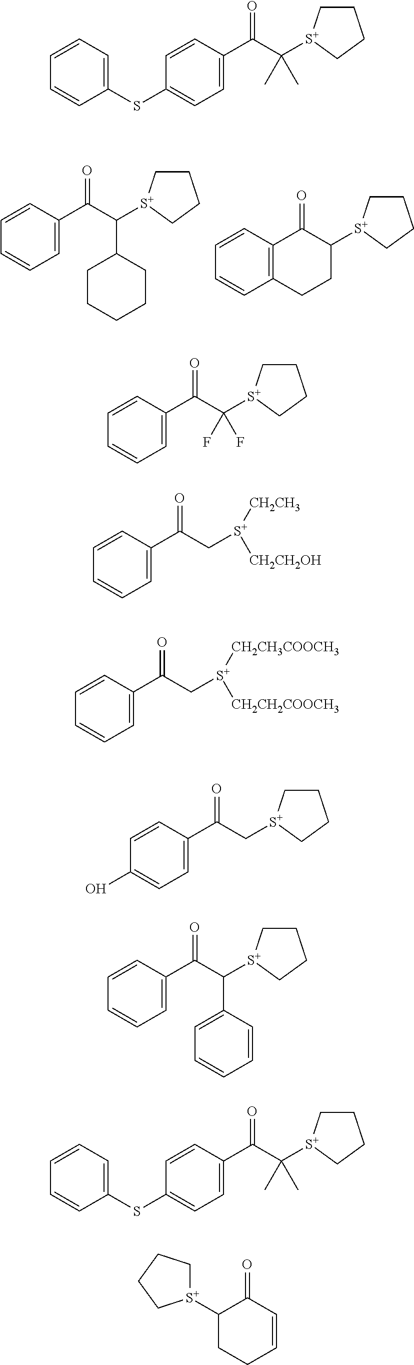

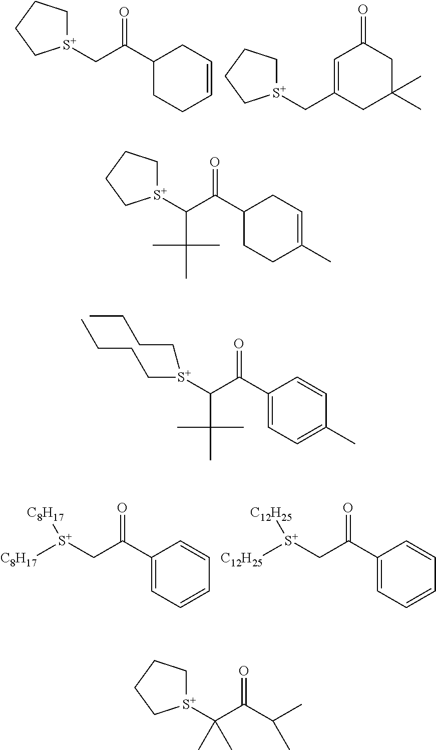

The mass ratio (compound (A)/compound (A′)) of the usage amount of the compound (A) and a photoacid generator when used together with the compound (A′) is preferably 99/1 to 20/80, more preferably 99/1 to 40/60, and even more preferably 99/1 to 50/50.

[2] Resin (B)

The active light-sensitive or radiation-sensitive resin composition of the present invention includes a resin (also referred to below as a resin (B)) which includes a repeating unit which is represented by General Formula (1) below and of which, due to being decomposed by an action of an acid, the solubility increases with respect to an alkali developer as an essential component. The active light-sensitive or radiation-sensitive resin composition of the present invention may be embodied as a positive type or a negative type active light-sensitive or radiation-sensitive resin composition. The resin (B) which is included in the composition is a resin (also referred to below as an “acid-decomposable resin”) of which, due to being decomposed by an action of an acid, the solubility increases with respect to an alkali developer. In this case, the resin (B) has a group (also referred to below as an “acid-decomposable group”) which is decomposed by an action of an acid and which generates an alkali-soluble group in a side chain or both the main chain and a side chain. That is, the resin (B) includes a repeating unit which has an acid-decomposable group.

(1) Repeating Unit which has an Acid-Decomposable Group

An acid-decomposable group preferably has a structure which is protected by a group which decomposes and desorbs an alkali-soluble group due to the action of an acid.

Examples of the alkali-soluble group described above preferably include a carboxyl group, a fluorinated alcohol group (preferably hexafluoroisopropanol), a sulfonic acid group, and the like.

A preferable group as an acid-decomposable group is a group in which the hydrogen atoms in the alkali-soluble groups are substituted with groups which are made to leave by an acid.

Examples of the groups which are made to leave by an acid include —C(R₃₆)(R₃₇)(R₃₈), —C(R₃₆)(R₃₇)(OR₃₉), —C(R₀₁)(R₀₂)(OR₃₉), and the like.

In the formula, R₃₆ to R₃₉ each independently represent an alkyl group, a cycloalkyl group, an aryl group, an aralkyl group, or an alkenyl group. R₃₆ and R₃₇ may bond with each other to form a ring.

R₀₁ and R₀₂ each independently represent a hydrogen atom, an alkyl group, a cycloalkyl group, an aryl group, an aralkyl group, or an alkenyl group.

The acid-decomposable group is preferably a cumyl ester group, an enol ester group, an acetal ester group, a tertiary alkyl ester group, and the like. The tertiary alkyl ester group is more preferable.

A repeating unit which has an acid-decomposable group and which may be contained in the resin (B) is preferably a repeating unit which is represented by General Formula (AI) below.

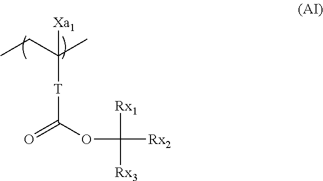

In General Formula (AI),

Xa₁ represents a hydrogen atom, a methyl group which may have a substituent group, or a group which is represented by —CH₂—R₉. R₉ represents a hydroxyl group or a monovalent organic group. Examples of the monovalent organic group include an alkyl group with 5 or less carbon atoms and an acyl group, and an alkyl group with 3 or less carbon atoms is preferable and a methyl group is more preferable. Xa₁ preferably represents a hydrogen atom, a methyl group, a trifluoromethyl group, or a hydroxy methyl group.

T represents a single bond or a divalent linking group.

Rx₁ to Rx₃ each independently represent an alkyl group (straight-chain or branched) or a cycloalkyl group (monocyclic or polycyclic).

At least two of Rx₁ to Rx₃ may bond with each other to form a cycloalkyl group (monocyclic or polycyclic).

Examples of a divalent linking group of T include an alkylene group, —COO—Rt- group, —O—Rt- group, and the like. In the formulas, Rt represents an alkylene group or a cycloalkylene group.

T is preferably a single bond or —COO—Rt- group. Rt is preferably an alkylene group with 1 to 5 carbon atoms and more preferably —CH₂— group and —(CH₂)₃—.

An alkyl group of Rx₁ to Rx₃ is preferably a straight-chain or branched alkyl group with 1 to 4 carbon atoms.

A cycloalkyl group of Rx₁ to Rx₃ is preferably a monocyclic cycloalkyl group with 3 to 8 carbon atoms and a polycyclic cycloalkyl group with 7 to 20 carbon atoms.

A cycloalkyl group which is formed by at least two of Rx₁ to Rx₃ bonding with each other is preferably a monocyclic cycloalkyl group with 3 to 8 carbon atoms and a polycyclic cycloalkyl group with 7 to 20 carbon atoms. A monocyclic cycloalkyl group with 5 or 6 carbon atoms is particularly preferable.

An aspect where Rx₁ is a methyl group or an ethyl group and Rx₂ and Rx₃ bond with each other to form the cycloalkyl group described above is preferable.

In a case of using an alkali developer which will be described below as a developer, the content ratio of a repeating unit which has an acid-decomposable group is preferably 10 mol % to 70 mol % with respect to the total repeating units in the resin (B), more preferably 25 mol % to 60 mol %, preferably 35 mol % to 55 mol %, and most preferably 45 mol % to 55 mol %.

In addition, in a case of using an organic-based developer which will be described below as the developer, the content ratio of a repeating unit which has an acid-decomposable group is preferably 30 mol % to 80 mol % with respect to all of the repeating units in the resin (B), more preferably 40 mol % to 80 mol %, preferably 50 mol % to 75 mol %, and most preferably 55 mol % to 75 mol %.

Specific examples of a repeating unit which has a preferable acid-decomposable group will be shown below; however, the present invention is not limited thereto. Here, in the formulas, Xa₁ represents any of H, CH₃, CF₃, and CH₂OH and Rxa and Rxb each represent a straight-chain or branched alkyl group with 1 to 4 carbon atoms.

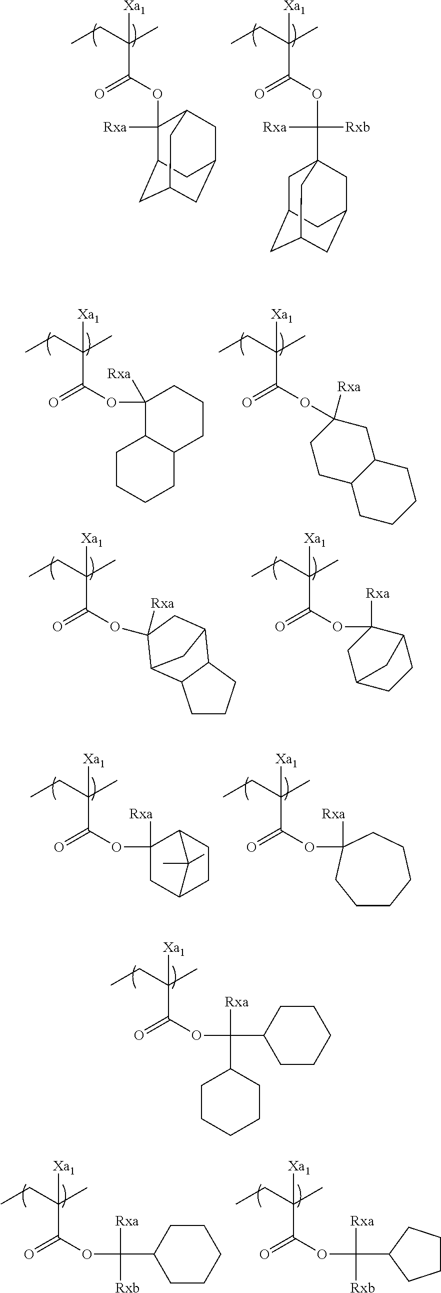

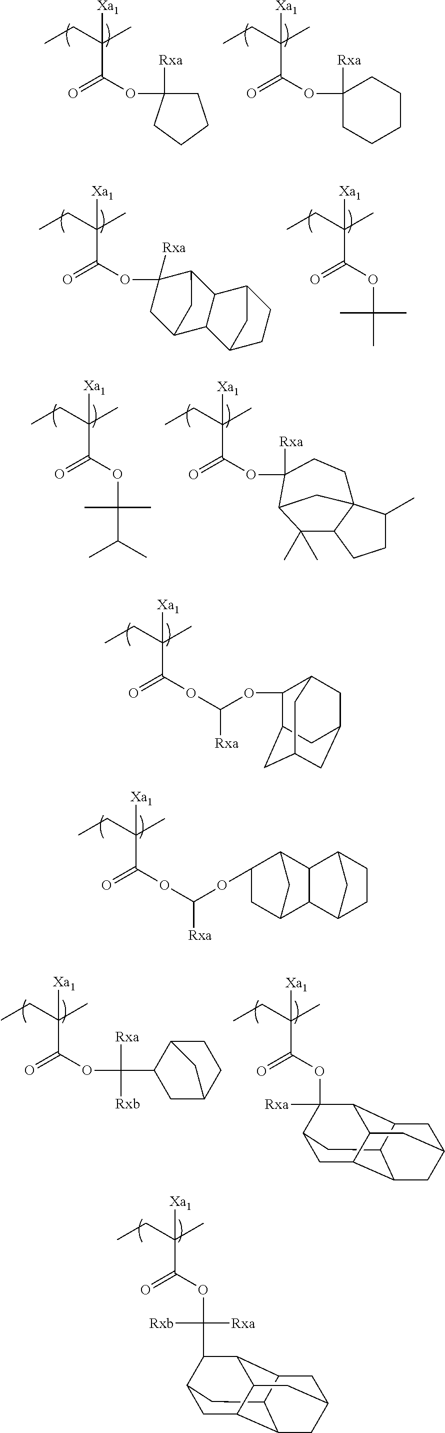

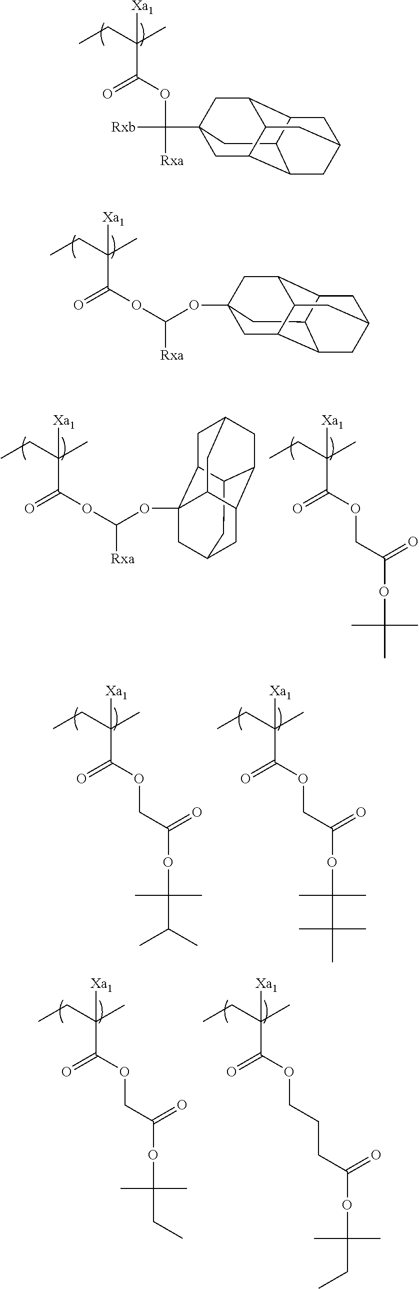

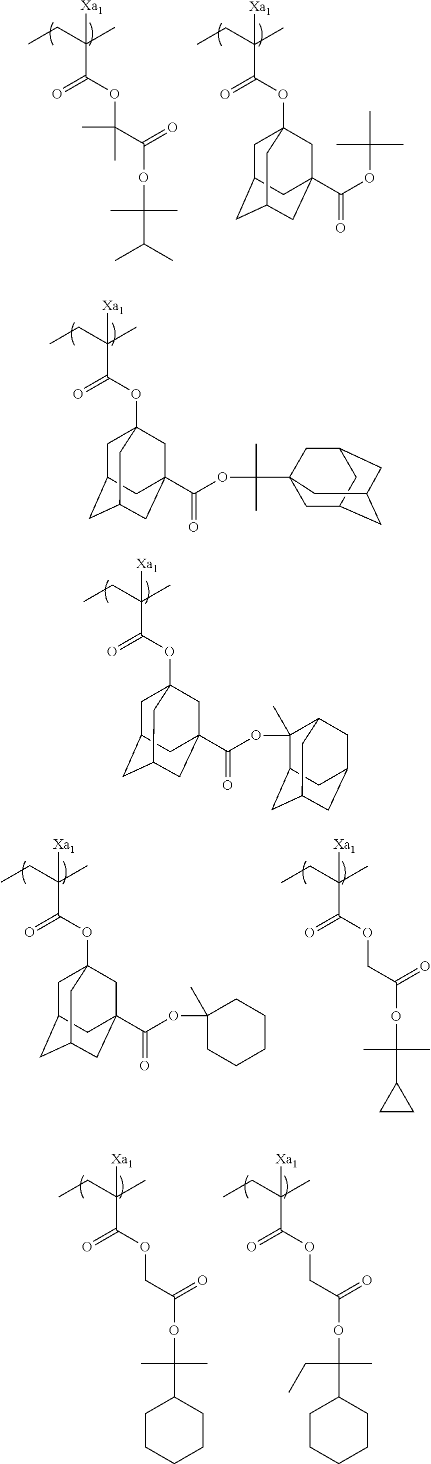

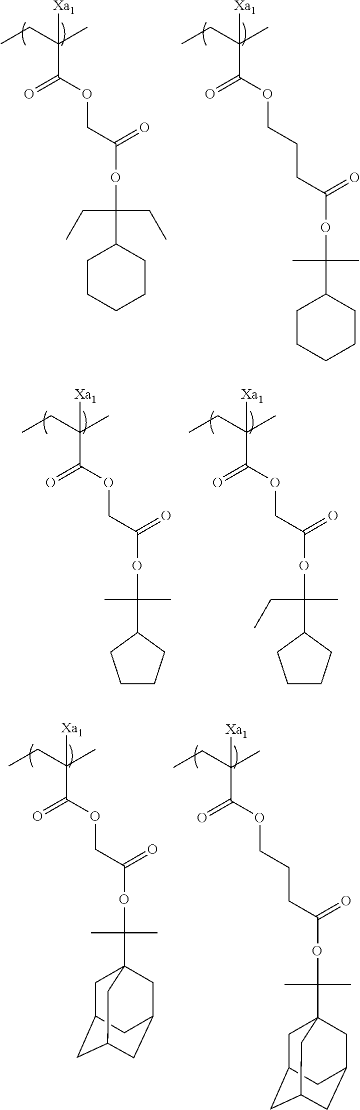

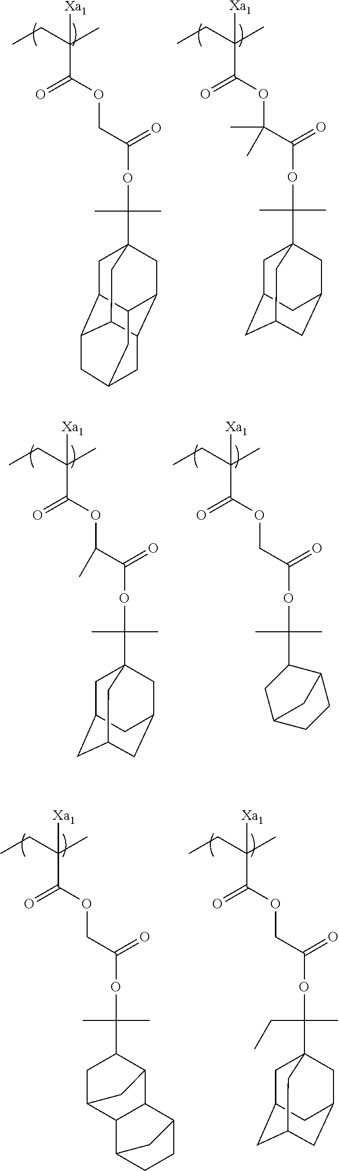

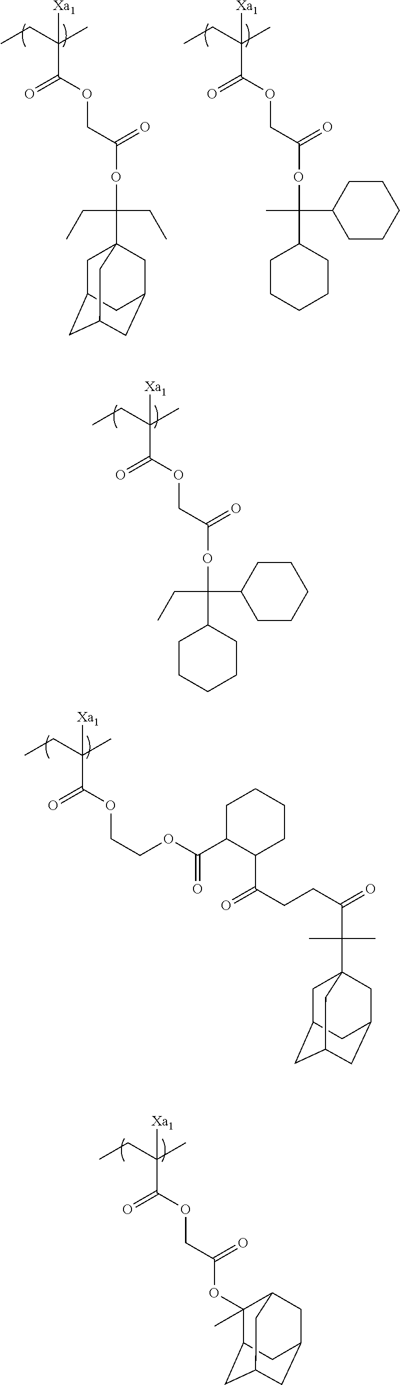

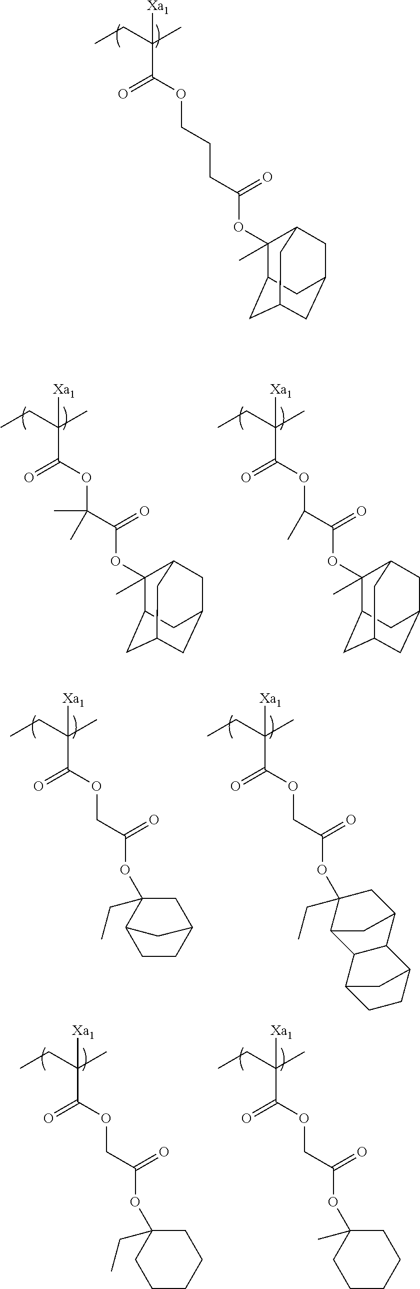

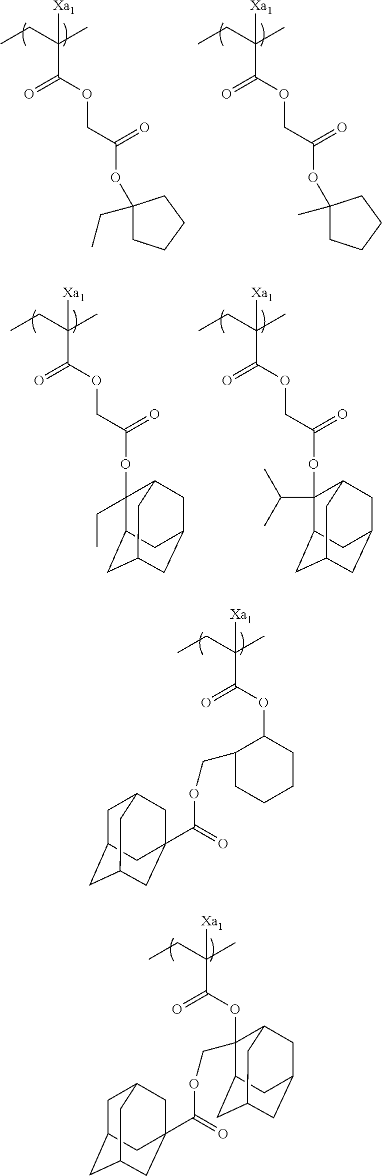

The resin (B) has a repeating unit which is represented by General Formula (1) below.

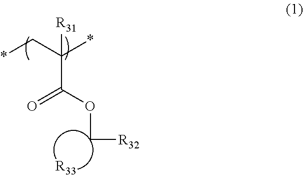

In General Formula (1),
R₃₁ represents a hydrogen atom, an alkyl group, or a fluorinated alkyl group, and R₃₂ represents an alkyl group or a cycloalkyl group.

R₃₂ is preferably a methyl group, an ethyl group, an n-propyl group, an isopropyl group, an n-butyl group, an isobutyl group, or a sec-butyl group.

R₃₃ represents an atom group which is necessary for forming a monocyclic alicyclic hydrocarbon structure with a carbon atom bonded with R₃₂.

In the alicyclic hydrocarbon structure described above, some carbon atoms which configure a ring may be substituted with hetero atoms or groups which have hetero atoms.

An alkyl group of R₃₁ may have a substituent group and examples thereof include a fluorine atom, a hydroxyl group, and the like.

R₃₁ is preferably a hydrogen atom, a methyl group, a trifluoromethyl group, or a hydroxy methyl group.

R₃₂ is preferably a methyl group, an ethyl group, an n-propyl group, or an isopropyl group, more preferably a methyl group or an ethyl group.

A monocyclic alicyclic hydrocarbon structure which R₃₃ forms with carbon atoms is preferably a ring with 3 to 8 members, more preferably a ring with 5 or 6 members.

Examples of hetero atoms which are able to substitute some carbon atoms which configure a ring in the monocyclic alicyclic hydrocarbon structure which R₃₃ forms with carbon atoms include an oxygen atom, a sulfur atom, and the like and examples of a group which has a hetero atom include a carbonyl group and the like. However, a group which has a hetero atom is preferably not an ester group (an ester bond).

A monocyclic alicyclic hydrocarbon structure which R₃₃ forms with carbon atoms is preferably formed only of carbon atoms and hydrogen atoms.

A repeating unit which is represented by General Formula (1) is preferably a repeating unit which is represented by General Formula (1′) below.

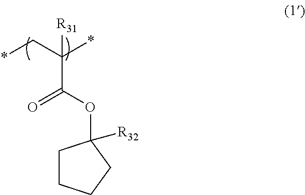

In General Formula (1′), R₃₁ and R₃₂ are respectively the same as in General Formula (1) described above.

Specific examples of a repeating unit which has a structure which is represented by General Formula (1) will be given below; however, the present invention is not limited thereto.

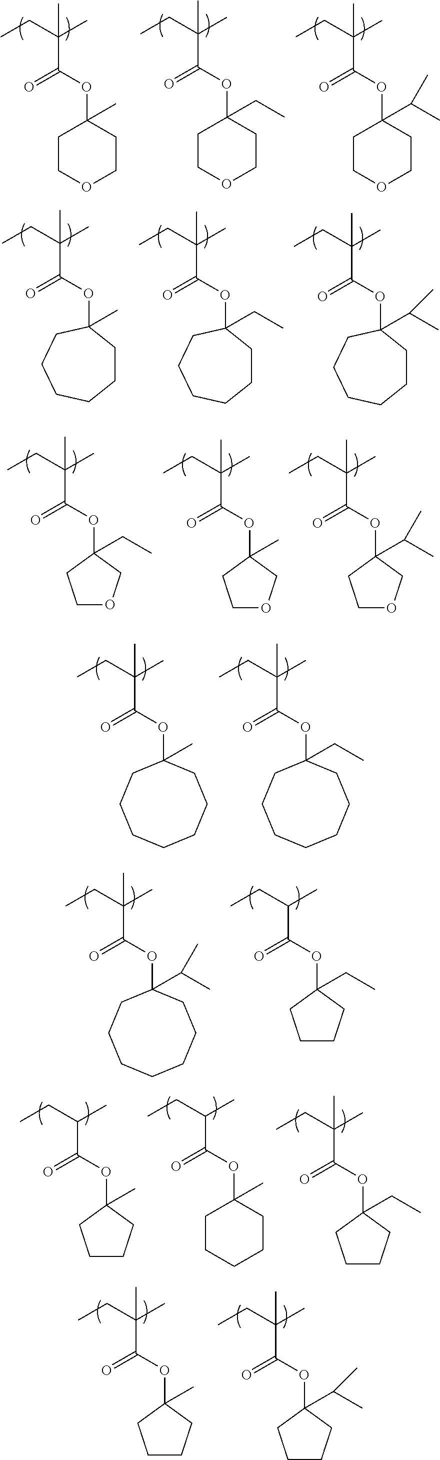

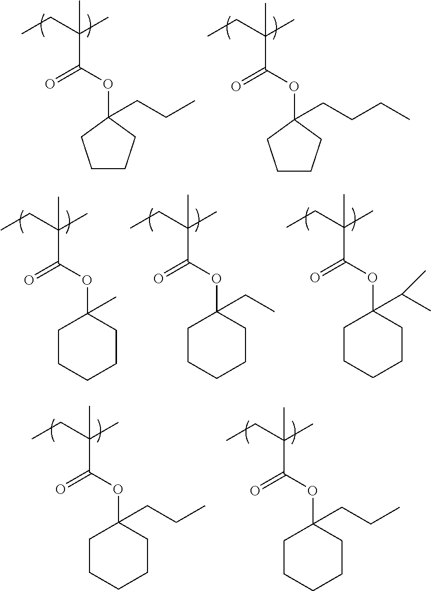

The content of a repeating unit which has a structure which is represented by General Formula (1) is preferably 10 mol % to 70 mol % with respect to all of the repeating units in the resin (B), more preferably 25 mol % to 65 mol %, and even more preferably 30 mol % to 50 mol %.

The repeating unit which has an acid-decomposable group which is included in the resin (B) may be one type, or two or more types may be used together. In a case of using a combination of two or more types, it is preferable to combine a repeating unit which is represented by General Formula (1) and an acid-decomposable repeating unit which has a polycyclic alicyclic hydrocarbon group.

Preferable examples of combinations in a case of being used together include the following. The specific structure is preferably a combination of the following. In the formulas below, R each independently represents a hydrogen atom or a methyl group.

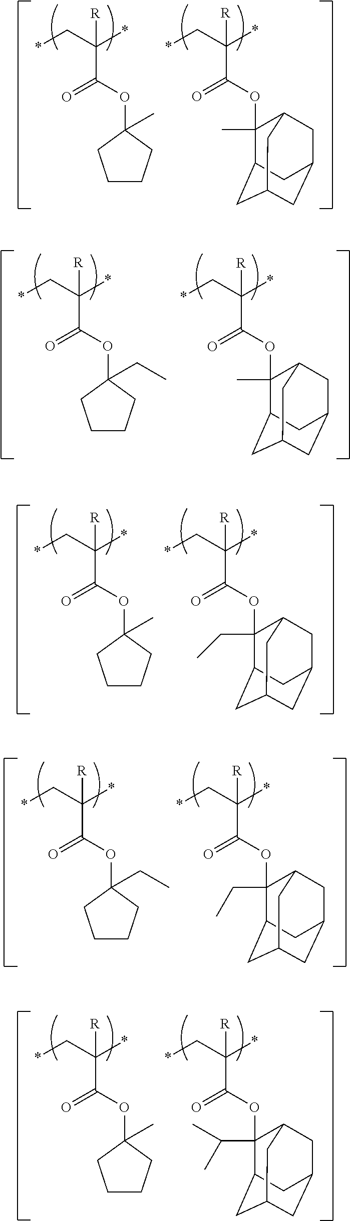

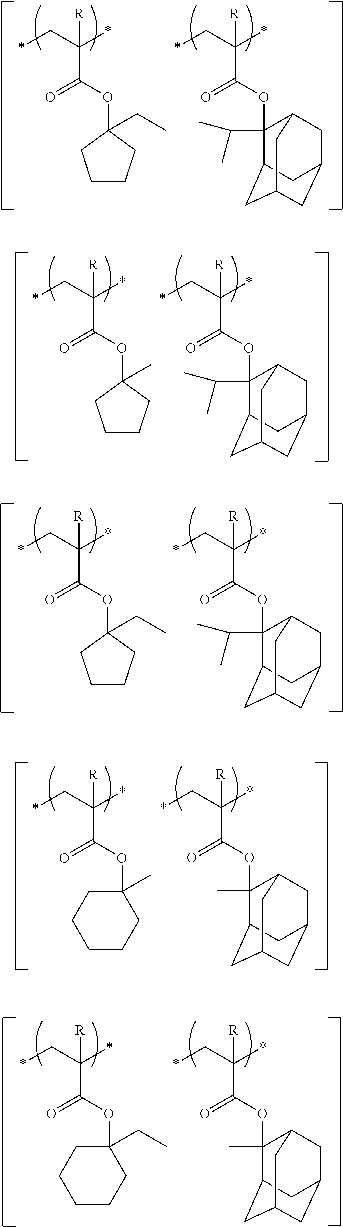

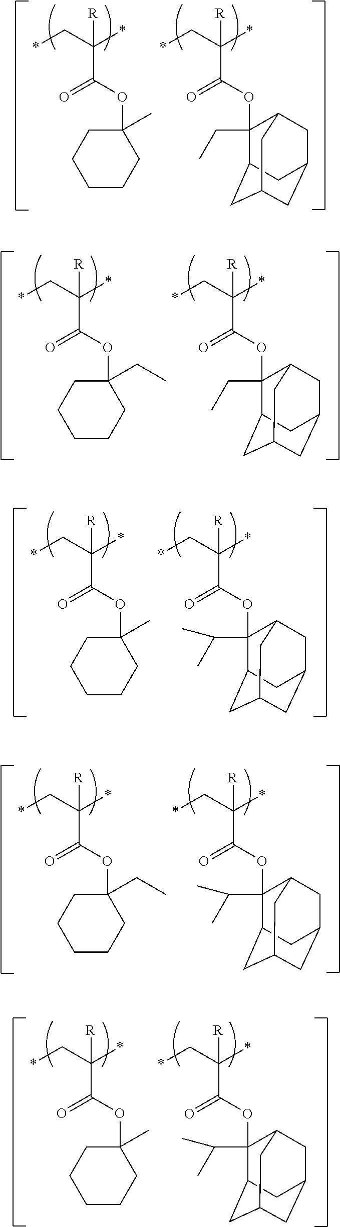

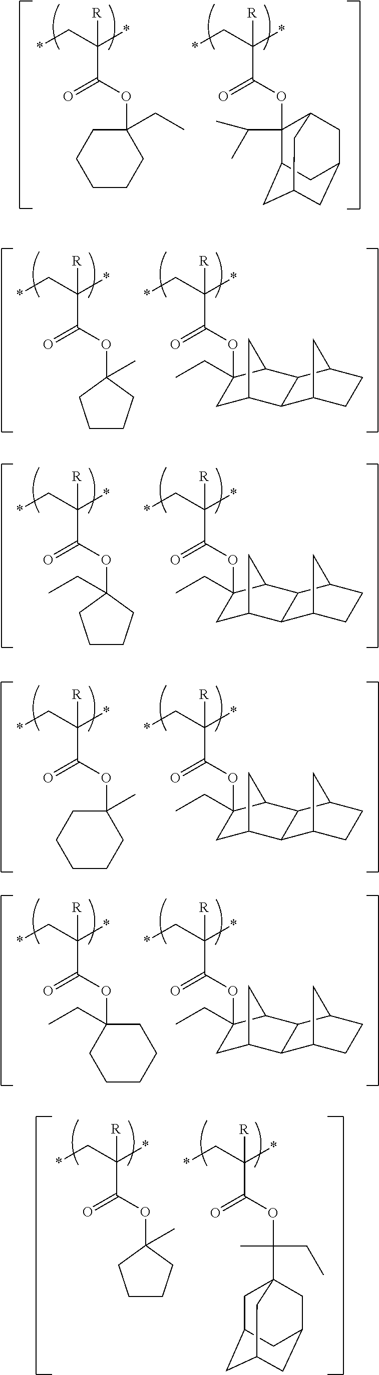

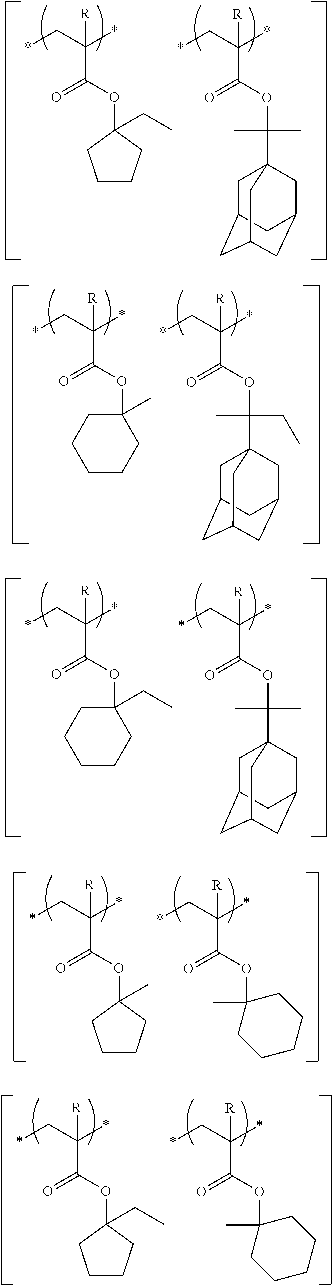

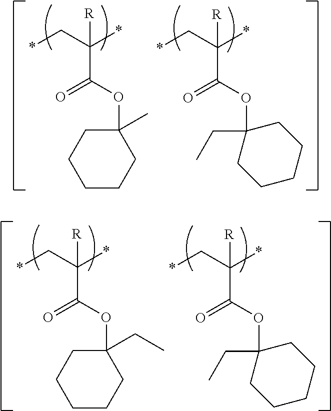

An acid-decomposable resin which is included in the active light-sensitive or radiation-sensitive resin composition of the present invention preferably has a repeating unit which has a cyclic carbonic ester structure.

The cyclic carbonic ester structure is a structure which has a ring which includes a bond which is represented by —O—C(═O)—O— as an atom group which configures a ring. A ring which includes a bond which is represented by —O—C(═O)—O— as an atom group which configures a ring is preferably a ring with 5 to 7 members and most preferably a ring with 5 members. The ring may form a condensed ring by being condensed with another ring.

The resin (B) in the present invention preferably contains a repeating unit which is represented by General Formula (A-1) below as a repeating unit which has a cyclic carbonic ester structure.

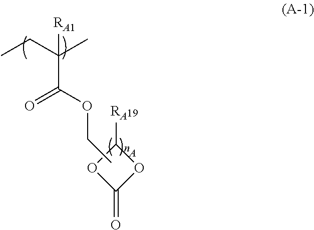

In General Formula (A-1), R_{A}¹ represents a hydrogen atom or an alkyl group.

R_{A}¹⁹ each independently represents a hydrogen atom or a chain hydrocarbon group.

A represents a single bond, a divalent or trivalent chain hydrocarbon group, a divalent or trivalent alicyclic hydrocarbon group, or a divalent or trivalent aromatic hydrocarbon group and, in a case where A is trivalent, a ring structure is formed by carbon atoms which are included in A and carbon atoms which configure the cyclic carbonic ester being bonded with each other.

n_{A} represents an integer of 2 to 4.

In General Formula (A-1), R_{A}¹ represents a hydrogen atom or an alkyl group. An alkyl group which is represented by R_{A}¹ may have a substituent group such as a fluorine atom. R_{A}¹ preferably represents a hydrogen atom, a methyl group, or a trifluoromethyl group, and more preferably represents a methyl group.

R_{A}¹⁹ each independently represents a hydrogen atom or a chain hydrocarbon group. A chain hydrocarbon group which is represented by R_{A}¹⁹ is preferably a chain hydrocarbon group with 1 to 5 carbon atoms. A chain hydrocarbon group may have a substituent group such as a hydroxyl group. R_{A}¹⁹ most preferably represents a hydrogen atom.

In General Formula (A-1), n_{A} represents an integer of 2 to 4.

n_{A} is preferably 2 or 3, and more preferably 2.

In General Formula (A-1), A represents a single bond, a divalent or trivalent chain hydrocarbon group, a divalent or trivalent alicyclic hydrocarbon group, or a divalent or trivalent aromatic hydrocarbon group.

A divalent or trivalent chain hydrocarbon group is preferably a divalent or trivalent chain hydrocarbon group with 1 to 30 carbon atoms.

A divalent or trivalent alicyclic hydrocarbon group is preferably a divalent or trivalent alicyclic hydrocarbon group with 3 to 30 carbon atoms.

A divalent or trivalent aromatic hydrocarbon group is preferably a divalent or trivalent aromatic hydrocarbon group with 6 to 30 carbon atoms.

A preferably represents a divalent or trivalent chain hydrocarbon group or a divalent or trivalent alicyclic hydrocarbon group, more preferably represents a divalent or trivalent chain hydrocarbon group, and even more preferably represents a straight-chain alkylene group with 1 to 5 carbon atoms.

One type out of the repeating units which are represented by General Formula (A-1) may be individually included in the resin (B), or two or more types may be included. The content ratio of a repeating unit which has a cyclic carbonic ester structure (preferably a repeating unit which is represented by General Formula (A-1)) is preferably 3 mol % to 80 mol % with respect to all of the repeating units which configure the resin (B), more preferably 3 mol % to 60 mol %, particularly preferably 3 mol % to 30 mol %, and most preferably 10 mol % to 15 mol %. By setting such a content ratio, it is possible to improve the resist developing characteristics, the low defect property, the low LWR, the low PEB temperature dependency, the profile, and the like.

Specific examples of a repeating unit which is represented by General Formula (A-1) (repeating units (A-1a) to (A-1w)) will be given below; however, the present invention is not limited thereto.

Here, R_{A}¹ in the specific examples below are the same as R_{A}¹ in General Formula (A-1).

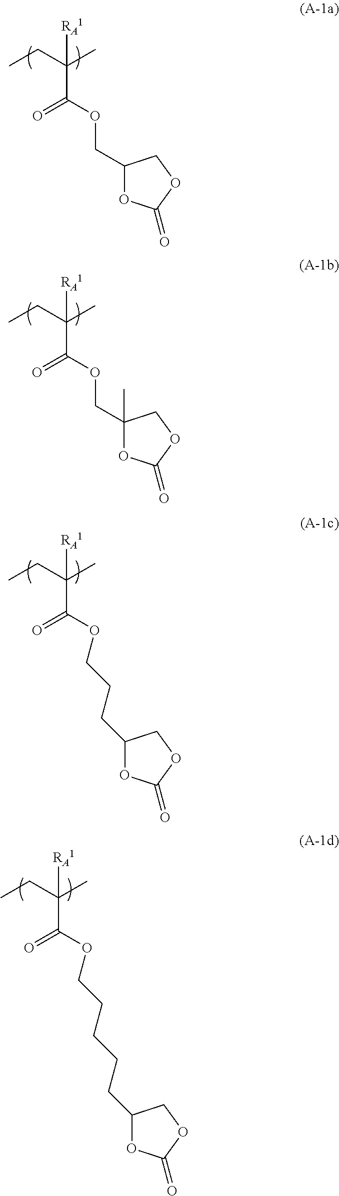

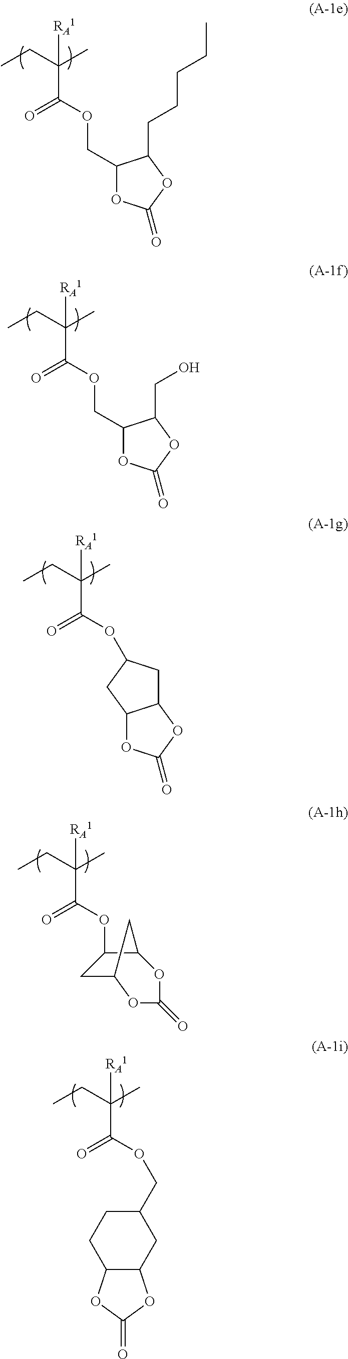

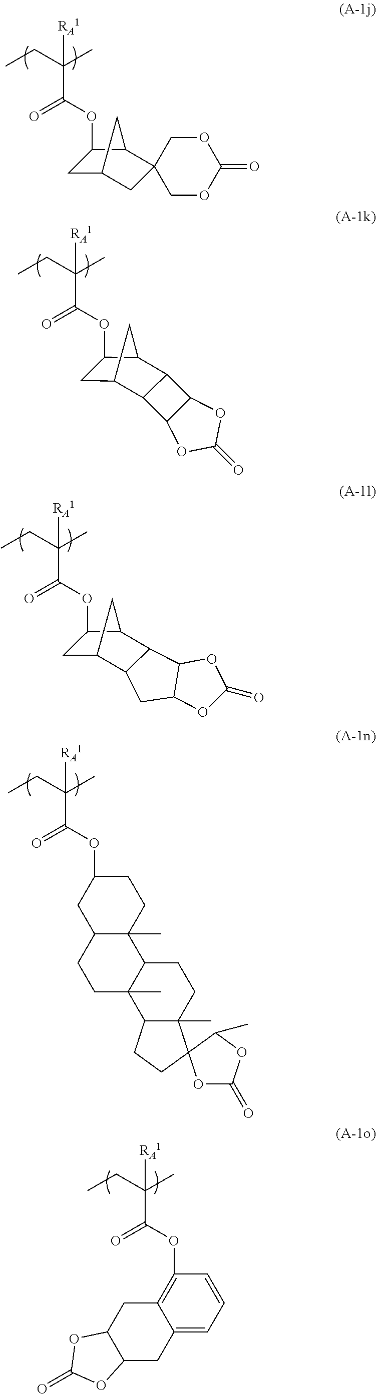

(2) Repeating Unit which has at Least One Type of a Group Selected from a Lactone Group, a Sultone Group (a Cyclic Sulfonic Acid Ester Group), a Hydroxyl Group, a Cyano Group, and an Alkali-Soluble Group

The resin (B) preferably further has a repeating unit which has at least one type of a group selected from a lactone group, a sultone group, a hydroxyl group, a cyano group, and an alkali-soluble group.

Description will be given of a repeating unit which has a lactone group and a repeating unit which has a sultone group which may be contained in the resin (B).

It is possible to use any lactone group as long as the group has a lactone structure; however, a ring lactone structure with 5 to 7 members is preferable, and a lactone group in which another ring structure is condensed in a form which forms a bicyclo structure and a spiro structure in the ring lactone structure with 5 to 7 members is preferable. It is more preferable to have a repeating unit which has a lactone structure which is represented by any of General Formulas (LC1-1) to (LC1-17) below. In addition, a lactone structure may be directly bonded with the main chain. A preferable lactone structure is (LC1-1), (LC1-4), (LC1-5), (LC1-6), (LC1-13), (LC1-14), and (LC1-17), and the line edge roughness and the developing defects are made favorable by using a specific lactone structure.

It is possible to use any sultone group as long as the group has a sultone structure; however, a ring sultone structure with 5 to 7 members is preferable, and a sultone group in which another ring structure is condensed in a form which forms a bicyclo structure and a spiro structure in the ring sultone structure with 5 to 7 members is preferable. It is more preferable to have a repeating unit which has a sultone structure which is represented by either General Formula (SL1-1) or (SL1-2) below.

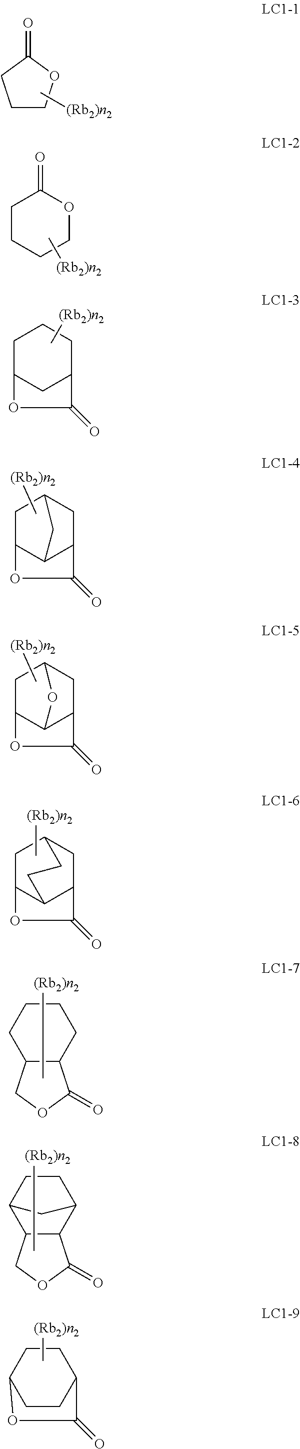

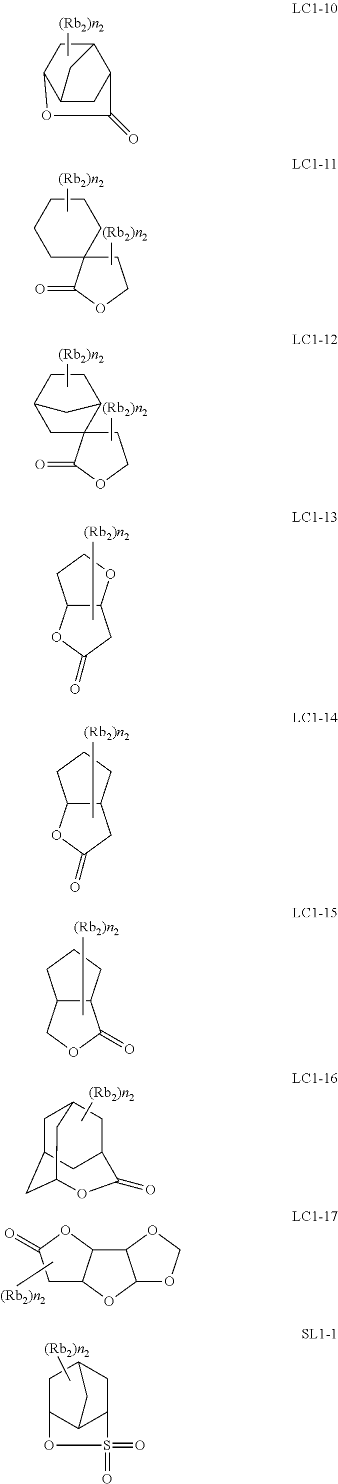

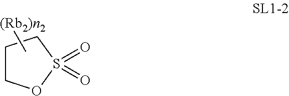

A lactone structure portion and a sultone structure portion may or may not have a substituent group (Rb₂). Examples of a preferable substituent group (Rb₂) include an alkyl group with 1 to 8 carbon atoms, a cycloalkyl group with 4 to 7 carbon atoms, an alkoxy group with 1 to 8 carbon atoms, an alkoxycarbonyl group with 2 to 8 carbon atoms, a carboxyl group, a halogen atom, a hydroxyl group, a cyano group, an acid-decomposable group, or the like. An alkyl group with 1 to 4 carbon atoms, a cyano group, and an acid-decomposable group are more preferable. n₂ represents an integer of 0 to 4. When n₂ is 2 or more, a plurality of the substituent groups (Rb₂) which are present may be the same or may be different and, additionally, the plurality of substituent groups (Rb₂) which are present may bond with each other to form a ring.

Examples of a repeating unit which has a partial structure which is represented by any of General Formulas (LC1-1) to (LC1-17), (SL1-1), and (SL1-2) include a repeating unit which is represented by General Formula (AII) below.

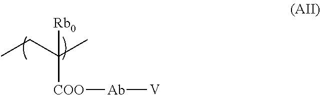

In General Formula (AII),

Rb₀ represents a hydrogen atom, a halogen atom, or an alkyl group with 1 to 4 carbon atoms which may have a substituent group. Examples of a preferable substituent group which an alkyl group of Rb₀ may have include a hydroxyl group and a halogen atom. Examples of a halogen atom of Rb₀ include a fluorine atom, a chlorine atom, a bromine atom, and an iodine atom. Rb₀ is preferably a hydrogen atom, a methyl group, a hydroxy methyl group, or a trifluoromethyl group, and particularly preferably a hydrogen atom or a methyl group.

Ab represents a single bond, an alkylene group, a divalent linking group which has a monocyclic or polycyclic alicyclic hydrocarbon structure, an ether group, an ester group, a carbonyl group, or a divalent linking group with a combination thereof. A single bond and a divalent linking group which is represented by -Ab₁-CO₂— are preferable.

Ab₁ is a straight-chain or branched alkylene group or a monocyclic or polycyclic cycloalkylene group, and preferably a methylene group, an ethylene group, a cyclohexylene group, an adamantylene group, and a norbornylene group.

V represents a group which has a structure which is illustrated in any of General Formulas (LC1-1) to (LC1-17), (SL1-1), and (SL1-2).

In a repeating unit which has a lactone group or a sultone group, a general optical isomer is present; however, any optical isomer may be used. In addition, one type of an optical isomer may be used individually, or a plurality of optical isomers may be used in a mixture. In a case of mainly using one type of optical isomer, the optical purity (ee) thereof is preferably 90 or more, and more preferably 95 or more.

The content ratio of a repeating unit which has a lactone group or a sultone group is preferably 15 mol % to 60 mol % with respect to all of the repeating units in the resin (B), more preferably 20 mol % to 50 mol %, and even more preferably 30 mol % to 50 mol %.

Specific examples of a repeating unit which has a lactone group and a sultone group will be given below; however, the present invention is not limited thereto.

(Rx in the formula is H, CH₂OH or CF₃)

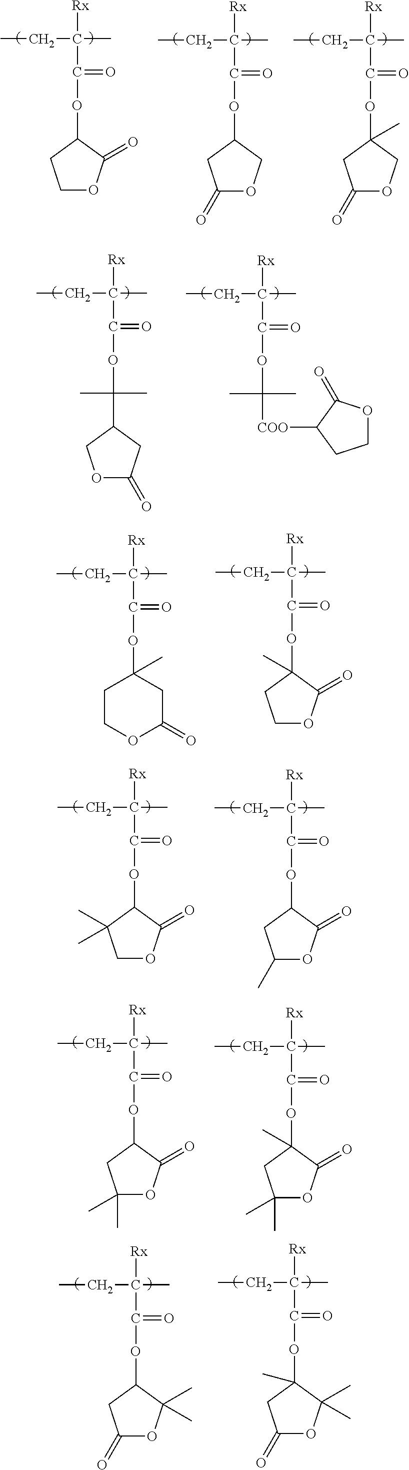

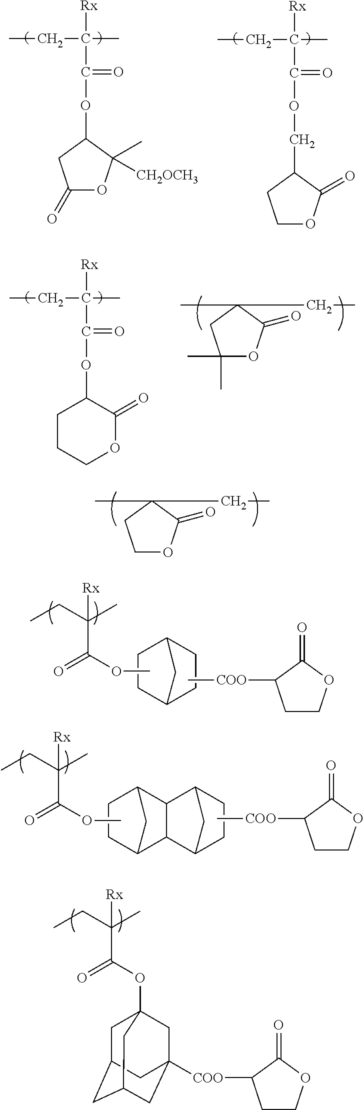

(Rx in the formula is H, CH₃, CH₂OH, or CF₃)

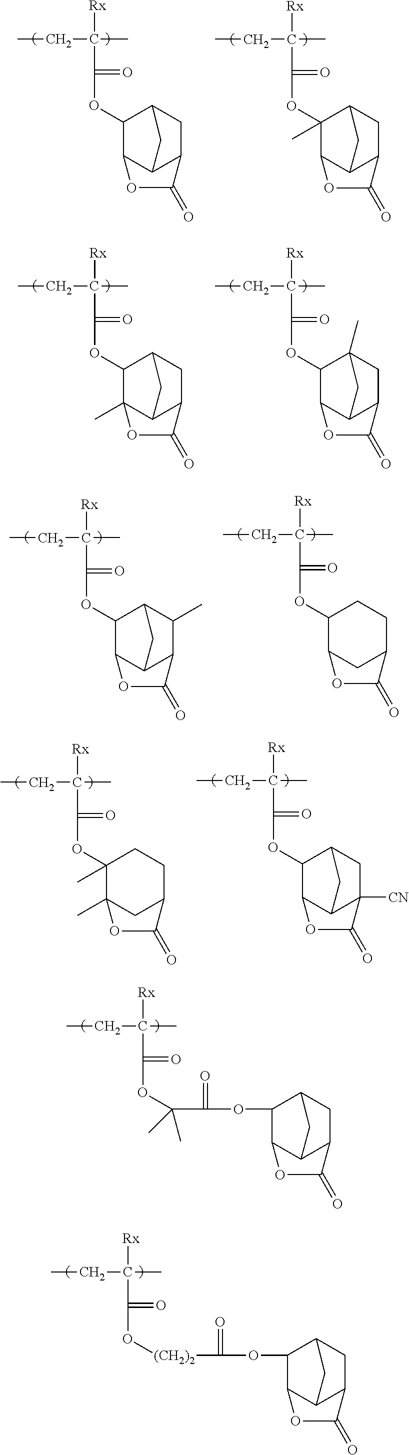

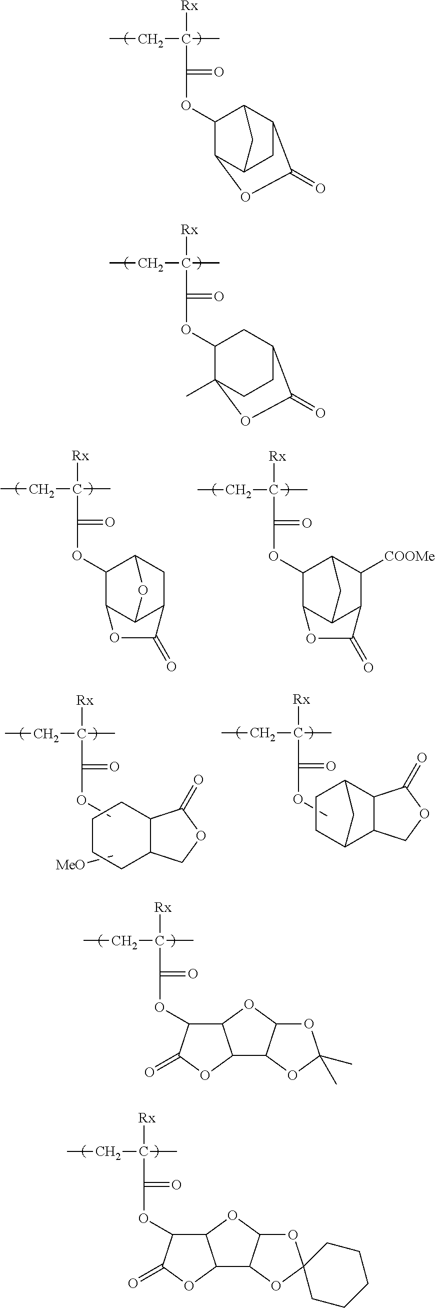

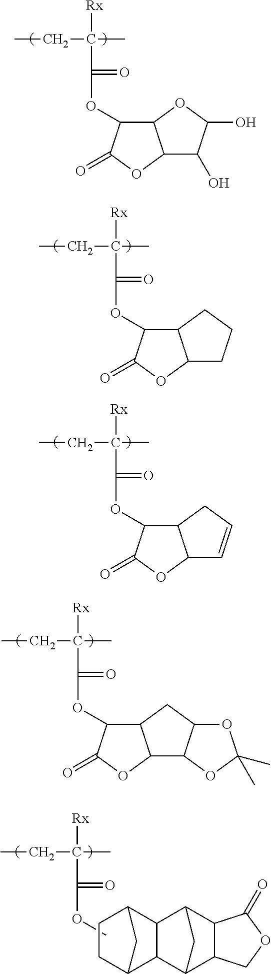

(Rx in the formula is H, CH₃, CH₂OH, or CF₃)

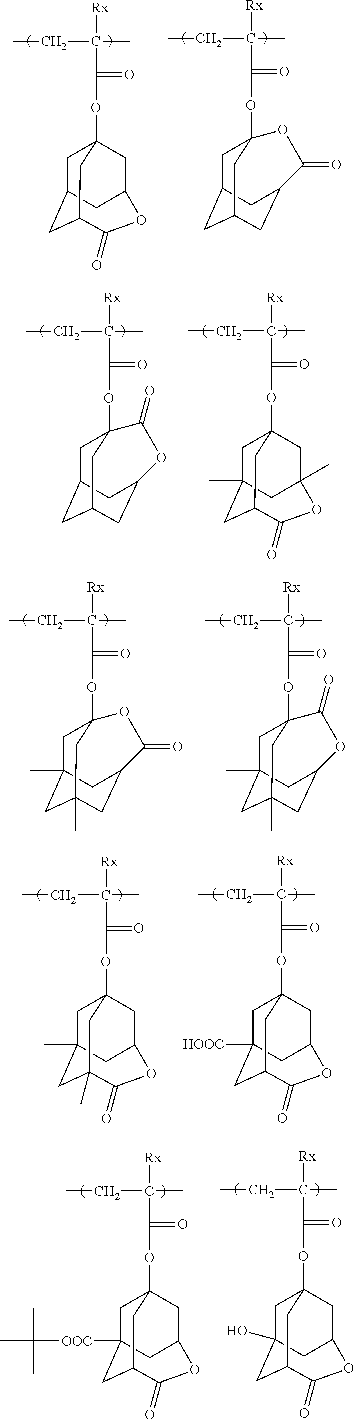

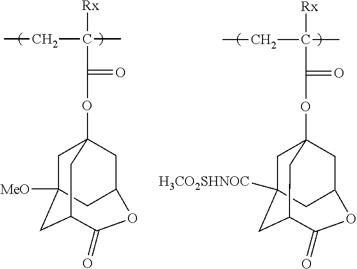

Examples of a repeating unit which has a particularly preferable lactone group include the repeating units below. Selecting a suitable lactone group makes the pattern profile and density dependency favorable.

(Rx in the formula is H, CH₃, CH₂OH, CF₃)

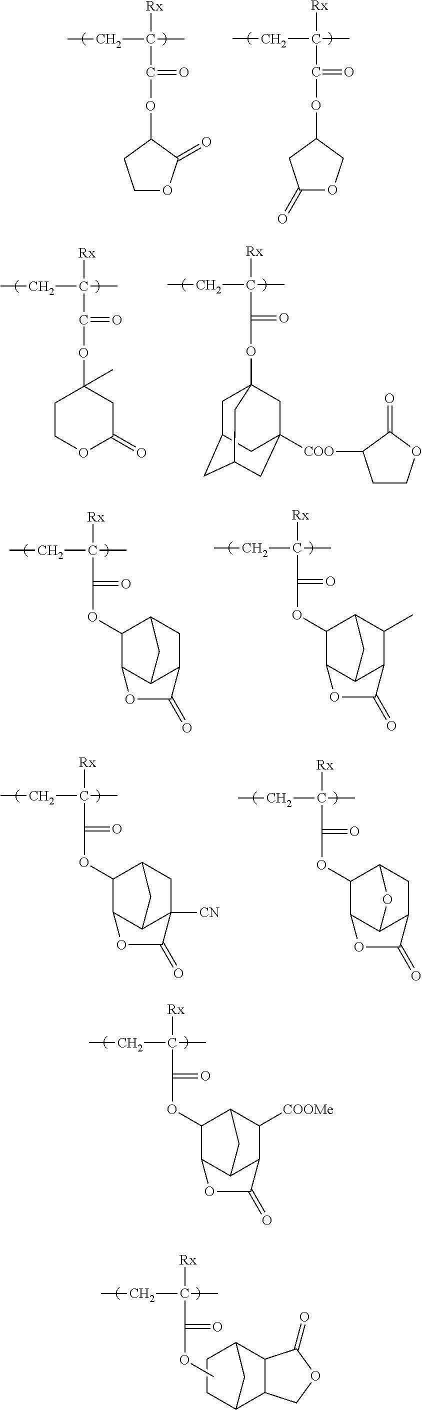

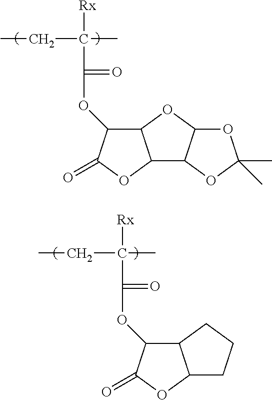

The resin (B) preferably has a repeating unit which has a hydroxyl group or a cyano group other than the repeating units of General Formulas (AI) and (AII). Due to this, the substrate adhesion and developer compatibility are improved. A repeating unit which has a hydroxyl group or a cyano group is preferably a repeating unit which has an alicyclic hydrocarbon structure which is substituted with a hydroxyl group or a cyano group, and, in addition, preferably does not have an acid-decomposable group. Examples of the repeating unit which has the structure include repeating units which are represented by General Formulas (AIIa) to (AIId) below.

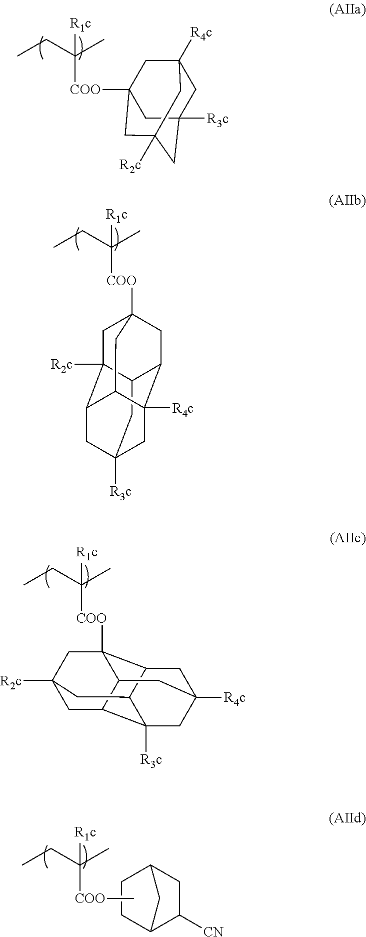

In General Formulas (AIIa) to (AIId),

R_{1c} represents a hydrogen atom, a methyl group, a trifluoromethyl group, or a hydroxy methyl group.

R₂c to R₄c each independently represent a hydrogen atom, a hydroxyl group, or a cyano group. However, at least one out of R₂c to R₄c represents a hydroxyl group or a cyano group. Preferably, one or two out of R₂c to R₄c are hydroxyl groups and the remaining one or more are hydrogen atoms. More preferably, two out of R₂c to R₄c are hydroxyl groups and the remaining one or more are hydrogen atoms.

The content ratio of a repeating unit which has a hydroxyl group or a cyano group is preferably 5 mol % to 40 mol % with respect to all of the repeating units in the resin (B), more preferably 5 mol % to 30 mol %, and even more preferably 10 mol % to 25 mol %.

Specific examples of a repeating unit which has a hydroxyl group or a cyano group will be given below; however, the present invention is not limited thereto.

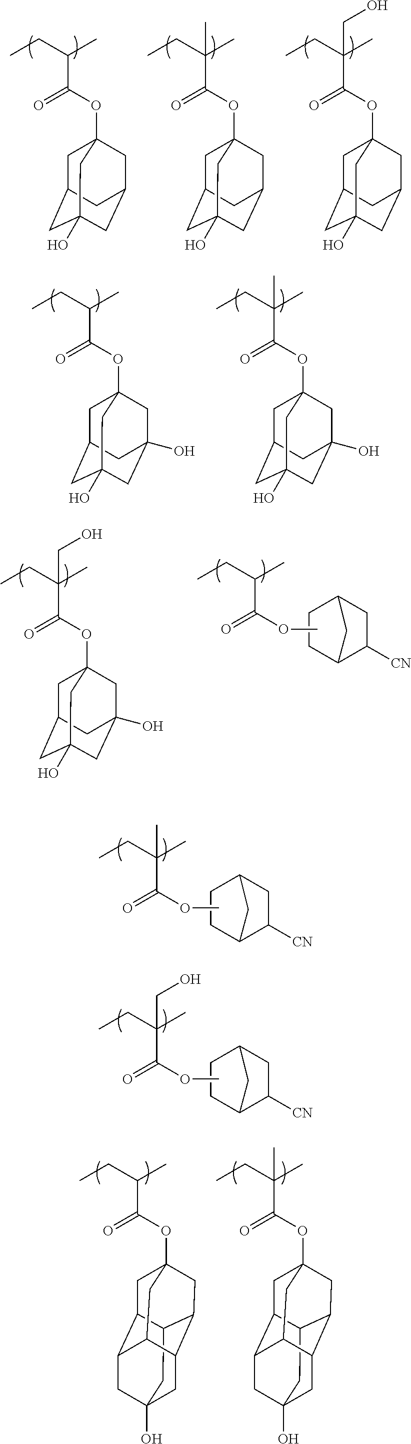

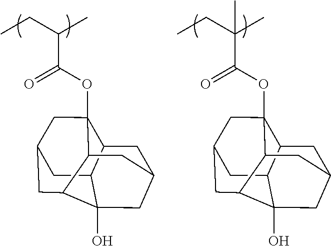

The resin (B) preferably has a repeating unit which has an alkali-soluble group. Examples of the alkali-soluble group include a carboxyl group, a sulfonamide group, a sulfonylimide group, a bisulfonylimide group, and an aliphatic alcohol in which the α-position is substituted with an electron withdrawing group (for example, a hexafluoroisopropanol group), and it is more preferable to have a repeating unit which has a carboxyl group. Containing a repeating unit which has an alkali-soluble group increases the resolution for the purpose of contact holes. As a repeating unit which has an alkali-soluble group, any of a repeating unit in which an alkali-soluble group is directly bonded with a main chain of a resin such as a repeating unit using acrylic acid or methacrylic acid, a repeating unit in which an alkali-soluble group is bonded with a main chain of a resin via a linking group, or, in addition, introduction to the end of a polymer chain using a polymerization initiator or a chain transfer agent which has an alkali-soluble group during the polymerization, is preferable, and a linking group may have a monocyclic or polycyclic cyclic hydrocarbon structure. A repeating unit using acrylic acid and methacrylic acid is particularly preferable.

The content ratio of the repeating unit which has an alkali-soluble group is preferably 0 mol % to 20 mol % with respect to all of the repeating units in the resin (B), more preferably 3 mol % to 15 mol %, and even more preferably 5 mol % to 10 mol %.

Specific examples of the repeating unit which has an alkali-soluble group will be illustrated below; however, the present invention is not limited thereto. In the specific examples, Rx represents H, CH₃, CH₂OH, or CF₃.

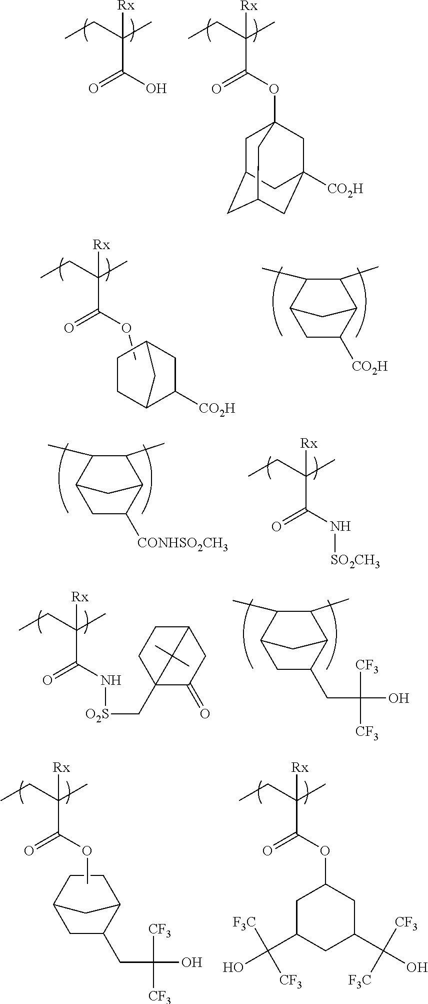

A repeating unit which has at least one type of a group selected from a lactone group, a hydroxyl group, a cyano group, and an alkali-soluble group is more preferably a repeating unit which has at least two selected from a lactone group, a hydroxyl group, a cyano group, and an alkali-soluble group, and preferably a repeating unit which has a cyano group and a lactone group. A repeating unit which has a structure in which a cyano group is substituted with the lactone structure of (LCI-4) described above is particularly preferable.

(3) Repeating Unit which has an Alicyclic Hydrocarbon Structure and does not Exhibit Acid-Decomposability

The resin (B) may further have a repeating unit which has an alicyclic hydrocarbon structure and does not exhibit acid-decomposability. Due to this, it is possible to reduce the elution of low molecular components from a resist film to the immersion liquid during liquid immersion exposure. Examples of the repeating unit include a repeating unit using 1-adamantyl(meth)acrylate, diamantyl(meth)acrylate, tricyclodecanyl(meth)acrylate, cyclohexyl(meth)acrylate, or the like.

(4) Repeating Unit which has Neither a Hydroxyl Group Nor a Cyano Group

The resin (B) of the present invention preferably further contains a repeating unit which is represented by General Formula (III) and which has neither a hydroxyl group nor a cyano group.

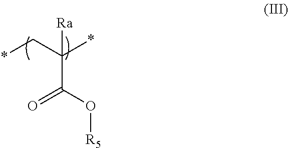

In General Formula (III), R₅ represents a hydrocarbon group which has at least one cyclic structure and has neither a hydroxyl group nor a cyano group.

Ra represents a hydrogen atom, an alkyl group, or a —CH₂—O—Ra₂ group. In the formula, Ra₂ represents a hydrogen atom, an alkyl group, or an acyl group.

A monocyclic hydrocarbon group and a polycyclic hydrocarbon group are included in a cyclic structure of R₅. Examples of the monocyclic hydrocarbon group include a cycloalkyl group with 3 to 12 carbon atoms (more preferably with 3 to 7 carbon atoms), and a cycloalkenyl group with 3 to 12 carbon atoms.

A ring-aggregated hydrocarbon group and a cross-linked cyclic hydrocarbon group are included in the polycyclic hydrocarbon group and examples of the cross-linked cyclic hydrocarbon ring include a 2-ring type hydrocarbon ring, a 3-ring type hydrocarbon ring, a 4-ring type hydrocarbon ring, and the like. In addition, for example, a condensed ring where a plurality of cycloalkane rings with 5 to 8 members are condensed is also included in the cross-linked cyclic hydrocarbon ring.

Examples of a preferable cross-linked cyclic hydrocarbon ring include a norbornyl group, an adamantyl group, a bicyclooctanyl group, a tricyclo[5,2,1,0^{2,6}]decanyl group, and the like. Examples of a more preferable cross-linked cyclic hydrocarbon ring include a norbornyl group and an adamantyl group.

The alicyclic hydrocarbon groups may have a substituent group and examples of preferable substituent groups include a halogen atom, an alkyl group, a hydroxyl group which is protected by a protective group, an amino group which is protected by a protective group, and the like. Examples of a preferable halogen atom include a bromine atom, a chlorine atom, and a fluorine atom, and examples of a preferable alkyl group include a methyl, an ethyl, a butyl, and a t-butyl group. The alkyl groups described above may further have a substituent group and examples of the substituent groups which the alkyl groups may further have include a halogen atom, an alkyl group, a hydroxyl group which is protected by a protective group, and an amino group which is protected by a protective group.

Examples of the protective group include an alkyl group, a cycloalkyl group, an aralkyl group, a substituted methyl group, a substituted ethyl group, an alkoxycarbonyl group, and an aralkyloxycarbonyl group. Examples of a preferable alkyl group include an alkyl group with 1 to 4 carbon atoms, examples of a preferable substituted methyl group include a methoxymethyl, a methoxythiomethyl, a benzyloxymethyl, a t-butoxymethyl, and a 2-methoxyethoxymethyl group, examples of a preferable substituted ethyl group include 1-ethoxyethyl and 1-methyl-1-methoxyethyl, examples of a preferable acyl group include an aliphatic acyl group with 1 to 6 carbon atoms such as a formyl, an acetyl, a propionyl, a butyryl, an isobutyryl, a valeryl, and a pivaloyl group, and examples of an alkoxycarbonyl group include an alkoxycarbonyl group with 1 to 4 carbon atoms.

The content ratio of a repeating unit which is represented by General Formula (III) and which has neither a hydroxyl group nor a cyano group is preferably 0 mol % to 40 mol % with respect to all of the repeating units in the resin (B) and more preferably 0 mol % to 20 mol %.

Specific examples of the repeating unit which is represented by General Formula (III) will be given below; however, the present invention is not limited thereto. In the formulas, Ra represents H, CH₃, CH₂OH, or CF₃.

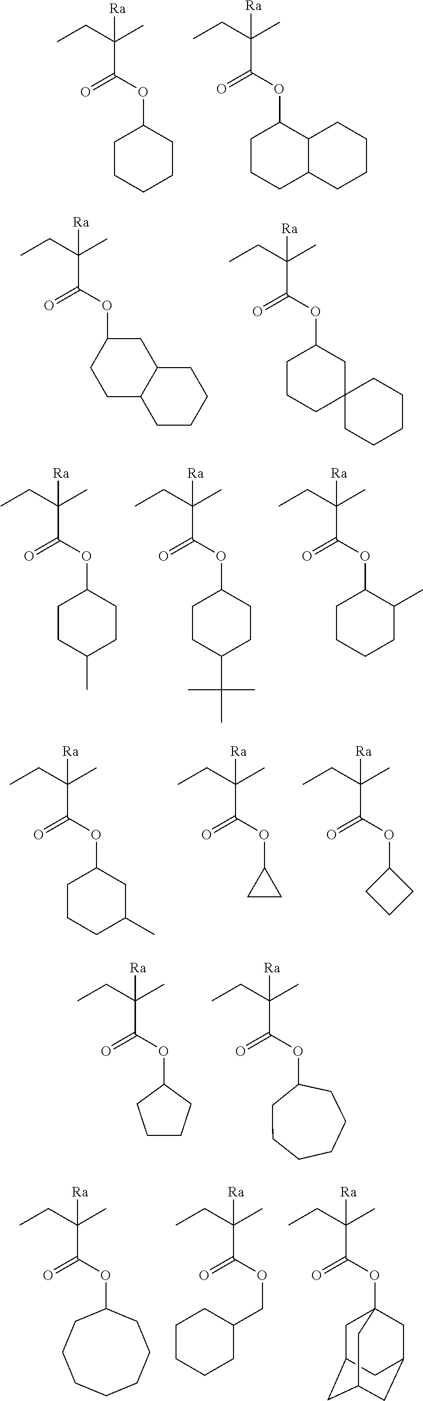

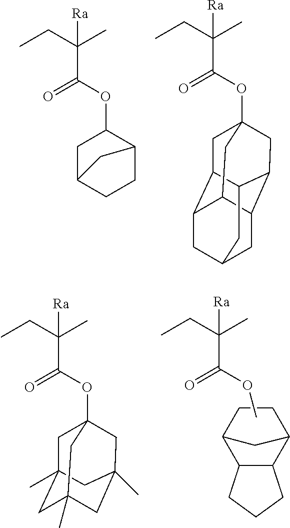

The resin (B) is able to have various types of repeating structure units other than the repeating structure units described above for the purpose of adjusting the dry etching resistance or standard developer aptitude, the substrate adhesion, and the resist profile, in addition to the typical characteristics necessary for a resist such as resolving power, heat resistance, sensitivity, and the like.

Examples of the repeating structure unit include repeating structure units which are equivalent to the monomer below; however, the present invention is not limited thereto.

Due to this, it is possible to carry out fine adjustment of the properties which are demanded for the resin (B), in particular,

(1) solubility with respect to a coating solvent,

(2) film-forming property (glass transition point),

(3) alkali developing characteristics,

(4) film thinning (selecting hydrophilic-hydrophobic properties and alkali-soluble groups),

(5) adhesion of a non-exposed section to a substrate,

(6) dry etching resistance, and the like.

Examples of such monomers include compounds or the like which have one addition-polymerizable unsaturated bond which is selected from, for example, acrylic acid esters, methacrylic acid esters, acrylamides, methacrylamides, allyl compounds, vinyl ethers, vinyl esters, and the like.

Apart from the above, copolymerizing may be carried out with an addition-polymerizable unsaturated compound which is able to be copolymerized with a monomer which is equivalent to the various types of repeating structure units described above.

In the resin (B), the content molar ratio of each repeating structure unit is appropriately set in order to adjust the dry etching resistance or standard developer aptitude of the resist, the substrate adhesion, and the resist profile, in addition to the typical characteristics necessary for a resist such as resolving power, heat resistance, sensitivity, and the like.

When the resist composition of the present invention is used for ArF exposure, the resin (B) preferably does not have an aromatic group from the point of view of transparency to ArF light. In addition, the resin (B) of the present invention preferably does not contain a fluorine atom or a silicon atom from the viewpoint of the mutual solubility with a hydrophobic resin which will be described below.

The resin (B) is preferably a resin where all of the repeating units are formed of (meth)acrylate-based repeating units. In this case, it is possible to use any of a resin where all of the repeating units are methacrylate-based repeating units, a resin where all of the repeating units are acrylate-based repeating units, and a resin where all of the repeating units are methacrylate-based repeating units and acrylate-based repeating units; however, the acrylate-based repeating units are preferably 50 mol % or less of all of the repeating units. More preferably the copolymer is a copolymer which is represented by General Formula (AI) and which includes 20 mol % to 50 mol % of (meth)acrylate-based repeating units which have an acid-decomposable group, 20 mol % to 50 mol % of (meth)acrylate-based repeating units which have a lactone group, 5 mol % to 30 mol % of (meth)acrylate-based repeating units which have an alicyclic hydrocarbon structure which is substituted with a hydroxyl group or a cyano group, and 0 mol % to 20 mol % of other (meth)acrylate-based repeating units.

In a case of irradiating the resist composition of the present invention with KrF excimer laser light, electron beams, X-rays, or high energy rays with wavelength of 50 nm or less (such as EUV), the resin (B) preferably further has a hydroxystyrene-based repeating unit other than the repeating unit which is represented by General Formula (AI). It is more preferable to have a hydroxystyrene-based repeating unit, a hydroxystyrene-based repeating unit which is protected by an acid-decomposable group, and an acid-decomposable repeating unit such as (meth)acrylic acid tertiary alkylester.

Examples of a repeating unit which has a preferable acid-decomposable group include a repeating unit and the like using t-butoxycarbonyloxystyrene, 1-alkoxyethoxystyrene, and (meth)acrylic acid tertiary alkylester, and a repeating unit using 2-alkyl-2-adamantyl (meth)acrylate and dialkyl (1-adamantyl) methyl(meth)acrylate is more preferable.

It is possible to synthesize the resin (B) using normal methods (for example, radical polymerization). Examples of typical synthesizing methods include a collective polymerization method in which polymerization is performed by dissolving a type of monomer and an initiator in a solvent and heating, a dripping polymerization method in which a solution of a type of monomer and an initiator is dripped and added to a heating solvent over 1 to 10 hours, and the like, and the dripping polymerization method is preferable. Examples of reaction solvents include ethers such as tetrahydrofuran, 1-4-dioxane, and diisopropylether, ketones such as methylethyl ketone and methylisobutyl ketone, ester solvents such as ethyl acetate, amide solvents such as dimethylformamide and dimethylacetamide, and, furthermore, solvents which dissolve the composition of the present invention which will be described below such as propylene glycol monomethyl ether acetate, propylene glycol monomethyl ether, and cyclohexanone. It is more preferable to carry out polymerization using the same solvent as the solvent which is used for the resist composition of the present invention. Due to this, it is possible to suppress the generation of particles during the storage.

The polymerization reaction is preferably performed under an inert gas atmosphere such as nitrogen or argon. The polymerization is initiated using a commercially available radical initiator (an azo-based initiator, peroxide, and the like) as a polymerization initiator. The radical initiator is preferably an azo-based initiator, and preferably an azo-based initiator which has an ester group, a cyano group, or a carboxyl group. Examples of preferable initiators include azobisisobutyronitrile, azobisdimethylvaleronitrile, dimethyl 2,2′-azobis(2-methylpropionate), and the like. As desired, an initiator is added or added in separate parts and, after the reaction ends, the desired polymer is recovered by a method such as powder or solid recovery by placing the resultant in a solvent. The concentration of the reaction liquid is 5 mass % to 50 mass % and preferably 10 mass % to 30 mass %. The reaction temperature is normally 10° C. to 150° C., preferably 30° C. to 120° C., and more preferably 60° C. to 100° C.

The weight average molecular weight of the resin (B) is preferably 1,000 to 200,000 as a polystyrene conversion value according to a GPC method, more preferably 2,000 to 20,000, even more preferably 3,000 to 15,000, and particularly preferably 3,000 to 10,000. By setting the weight average molecular weight to 1,000 to 200,000, it is possible to prevent deterioration in the heat resistance or dry etching resistance and it is possible to prevent the developing characteristics from deteriorating or the film-forming property from deteriorating due to the viscosity being increased.

A resin (B) where the dispersity (molecular weight distribution) is normally in a range of 1 to 3, preferably 1 to 2.6, more preferably 1 to 2, and particularly preferably 1.4 to 1.7 is used. A resin (B) with a smaller molecular weight distribution is excellent in terms of the resolution and the resist shape and the side wall of a resist pattern is smooth and has excellent roughness.

In the resist composition of the present invention, the mixing ratio of the resin (B) in the entire composition is preferably 50 mass % to 99 mass % of the total solid content and more preferably 60 mass % to 95 mass %.

In addition, in the present invention, one type of the resin (B) may be used or a plurality thereof may be used together.

[3] Hydrophobic Resin

The active light-sensitive or radiation-sensitive resin composition of the present invention may contain a hydrophobic resin (also referred to below as a “hydrophobic resin (HR)”) which has at least either a fluorine atom or a silicon atom particularly when being applied to liquid immersion exposure. Due to this, the hydrophobic resin (HR) is unevenly distributed in the film surface layer and, in a case where the liquid immersion medium is water, it is possible to improve the static/dynamic contact angle of a resist film surface with respect to the water and improve the liquid immersion liquid conformance.

The hydrophobic resin (HR) is unevenly distributed on the interface as described above; however, unlike a surfactant, it is not necessary to have a hydrophilic group in the molecule, and the resin need not contribute to the uniform mixing of polar/nonpolar substances.

The hydrophobic resin typically includes a fluorine atom and/or a silicon atom. The fluorine atom and/or the silicon atom in the hydrophobic resin (HR) may be included in the main chain of the resin or may be included in a side chain.

In a case where the hydrophobic resin includes a fluorine atom, a resin which has an alkyl group which has a fluorine atom, a cycloalkyl group which has a fluorine atom, or an aryl group which has a fluorine atom is preferable as the partial structure which has a fluorine atom.

The alkyl group which has a fluorine atom is a straight-chain or branched alkyl group in which at least one hydrogen atom is substituted with a fluorine atom, preferably with 1 to 10 carbon atoms, and more preferably 1 to 4 carbon atoms, and may further have another sub stituent group.

The cycloalkyl group which has a fluorine atom is a monocyclic or polycyclic cycloalkyl group in which at least one hydrogen atom is substituted with a fluorine atom and may further have another substituent group.

Examples of the aryl group which has a fluorine atom include an aryl group such as a phenyl group and a naphthyl group in which at least one hydrogen atom thereof is substituted with a fluorine atom and the aryl group may further have another substituent group.

Examples of the alkyl group which has a fluorine atom, a cycloalkyl group which has a fluorine atom, or an aryl group which has a fluorine atom preferably include groups which are represented by any of General Formulas (F2) to (F4) below; however, the present invention is not limited thereto.

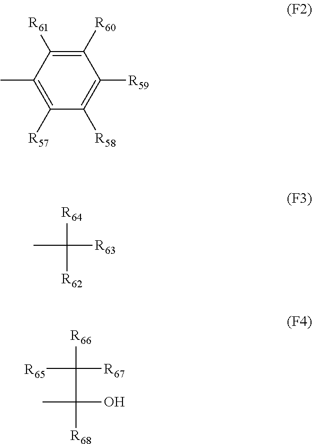

In General Formulas (F2) to (F4),
R₅₇ to R₆₈ each independently represent a hydrogen atom, a fluorine atom, or an alkyl group (straight-chain or branched). However, at least one of R₅₇ to R₆₁, at least one of R₆₂ to R₆₄, and at least one of R₆₅ to R₆₈ represent a fluorine atom or an alkyl group (preferably with 1 to 4 carbon atoms) in which at least one hydrogen atom thereof is substituted with a fluorine atom.

R₅₇ to R₆₁ and R₆₅ to R₆₇ are preferably all fluorine atoms. R₆₂, R₆₃, and R₆₈ are preferably fluoroalkyl groups (preferably with 1 to 4 carbon atoms) and more preferably perfluoroalkyl groups with 1 to 4 carbon atoms. When R₆₂ and R₆₃ are perfluoroalkyl groups, R₆₄ is preferably a hydrogen atom. R₆₂ and R₆₃ may form a ring by linking with each other.

Specific examples of a group which is represented by General Formula (F2) include a p-fluorophenyl group, a pentafluorophenyl group, a 3,5-di(trifluoromethyl)phenyl group, and the like.

Specific examples of a group which is represented by General Formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-t-butyl group, a perfluoroisopentyl group, a perfluorooctyl group, a perfluoro(trimethyl)hexyl group, a 2,2,3,3-tetrafluorocyclobutyl group, a perfluorocyclohexyl group, and the like. A hexafluoroisopropyl group, a heptafluoroisopropyl group, a hexafluoro(2-methyl)isopropyl group, an octafluoroisobutyl group, a nonafluoro-t-butyl group, and a perfluoroisopentyl group are preferable and a hexafluoroisopropyl group and a heptafluoroisopropyl group are more preferable.

Specific examples of a group which is represented by General Formula (F4) include —C(CF₃)₂OH, —C(C₂F₅)₂OH, —C(CF₃)(CH₃)OH, —CH(CF₃)OH, and the like, and —C(CF₃)₂OH is preferable.

A partial structure which includes a fluorine atom may be directly bonded with the main chain and furthermore, may be bonded with the main chain via a group selected from a group consisting of an alkylene group, a phenylene group, an ether bond, a thioether bond, a carbonyl group, an ester bond, an amide bond, a urethane bond, and a ureylene bond, or a group combining two or more thereof

Examples of a favorable repeating unit which has a fluorine atom include the following.

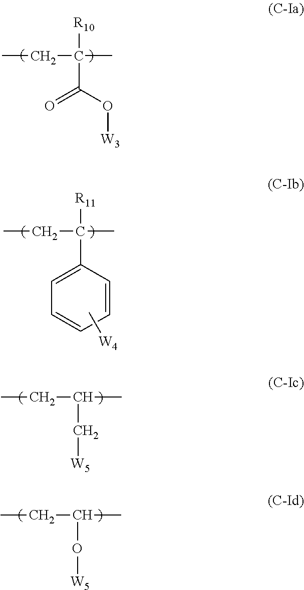

In Formulas (C-Ia) to (C-Id), R₁₀ and R₁₁ each independently represent a hydrogen atom, a fluorine atom, or an alkyl group. The alkyl group is preferably a straight-chain or branched alkyl group with 1 to 4 carbon atoms and may have a substituent group and examples of the alkyl group which has a substituent group include a fluorinated alkyl group in particular.

W₃ to W₆ each independently represent an organic group which contains at least one or more fluorine atoms. In detail, examples thereof include an atom group of (F2) to (F4) described above.

In addition, as well as these, the hydrophobic resin may have a unit as described below as the repeating unit which has a fluorine atom.

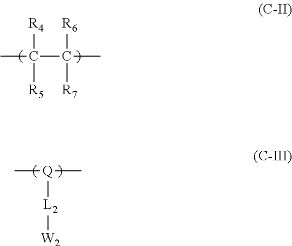

In Formulas (C-II) and (C-III), R₄ to R₇ each independently represent a hydrogen atom, a fluorine atom, or an alkyl group. The alkyl group is preferably a straight-chain or branched alkyl group with 1 to 4 carbon atoms and may have a substituent group and examples of the alkyl group which has a substituent group include a fluorinated alkyl group in particular.

However, at least one of R₄ to R₇ represents a fluorine atom. R₄ and R₅ or R₆ and R₇ may form a ring.

W₂ represents an organic group which contains at least one fluorine atom. In detail, examples thereof include an atom group of (F2) to (F4) described above.

L₂ indicates a single bond or a divalent linking group. The divalent linking group indicates a substituted or unsubstituted arylene group, a substituted or unsubstituted alkylene group, a substituted or unsubstituted cycloalkylene group, —O—, —SO₂—, —CO—, —N(R)— (in the formula, R represents a hydrogen atom or alkyl), and —NHSO₂— or a divalent linking group in a combination of a plurality thereof

Q represents an alicyclic structure. The alicyclic structure may have a substituent group, may be a monocyclic type, may be a polycyclic type, and may be a bridged type in a case of a polycyclic type. The monocyclic type is preferably a cycloalkyl group with 3 to 8 carbon atoms and examples thereof include a cyclopentyl group, a cyclohexyl group, a cyclobutyl group, a cyclooctyl group, and the like. Examples of the polycyclic type include a group which has a bicyclo, tricyclo, or tetracyclo structure and the like with 5 or more carbon atoms and a cycloalkyl group with 6 to 20 carbon atoms is preferable. Examples thereof include an adamantyl group, a norbornyl group, a dicyclopentyl group, a tricyclodecanyl group, a tetracyclododecyl group, and the like. Here, at least one carbon atom in a cycloalkyl group may be substituted with a hetero atom such as an oxygen atom. Examples of Q particularly preferably include a norbornyl group, a tricyclodecanyl group, a tetracyclododecyl group, and the like.

The hydrophobic resin may contain a silicon atom.

It is preferable to have an alkylsilyl structure (preferably a trialkylsilyl group) or a cyclic siloxane structure as a partial structure which has a silicon atom.

Examples of an alkylsilyl structure or a cyclic siloxane structure specifically include groups which are represented by General Formulas (CS-1) to (CS-3) below, and the like.

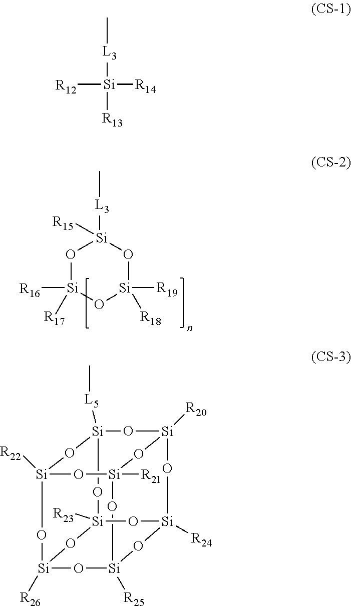

In General Formulas (CS-1) to (CS-3), R₁₂ to R₂₆ each independently represent a straight-chain or branched alkyl group (preferably with 1 to 20 carbon atoms) or a cycloalkyl group (preferably with 3 to 20 carbon atoms).

L₃ to L₅ represent a single bond or a divalent linking group. Examples of the divalent linking group include an individual group or a combination of two or more groups selected from a group consisting of an alkylene group, a phenylene group, an ether bond, a thioether bond, a carbonyl group, an ester bond, an amide bond, a urethane bond, or a ureylene bond.

n represents an integer of 1 to 5. n is preferably an integer of 2 to 4.

A repeating unit which has at least either a fluorine atom or a silicon atom is preferably a (meth)acrylate-based repeating unit.

Specific examples of a repeating unit which has at least either a fluorine atom or a silicon atom will be given below; however, the present invention is not limited thereto. Here, in the specific examples, X₁ represents a hydrogen atom, —CH₃, —F, or —CF₃, and X₂ represents —F or —CF₃.

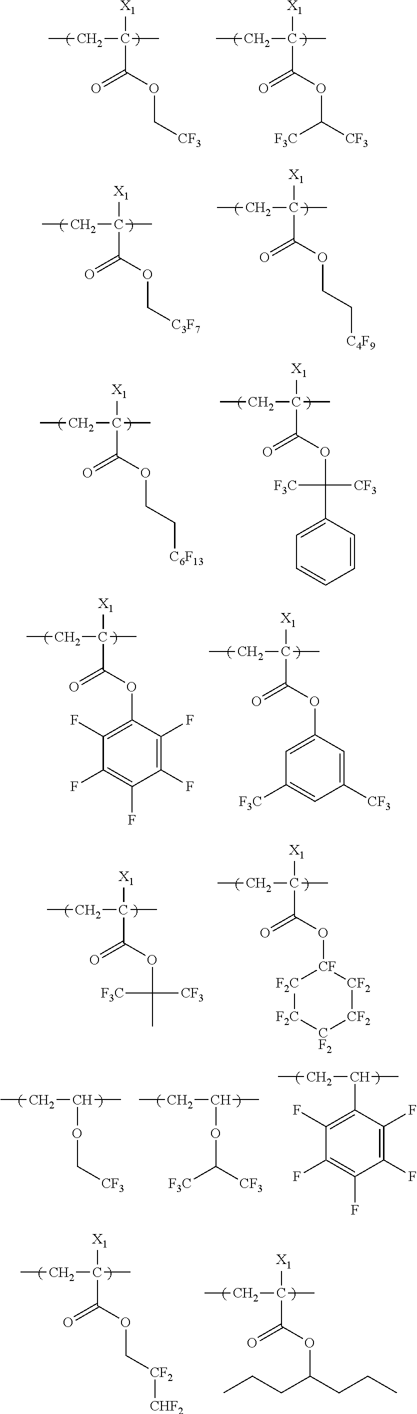

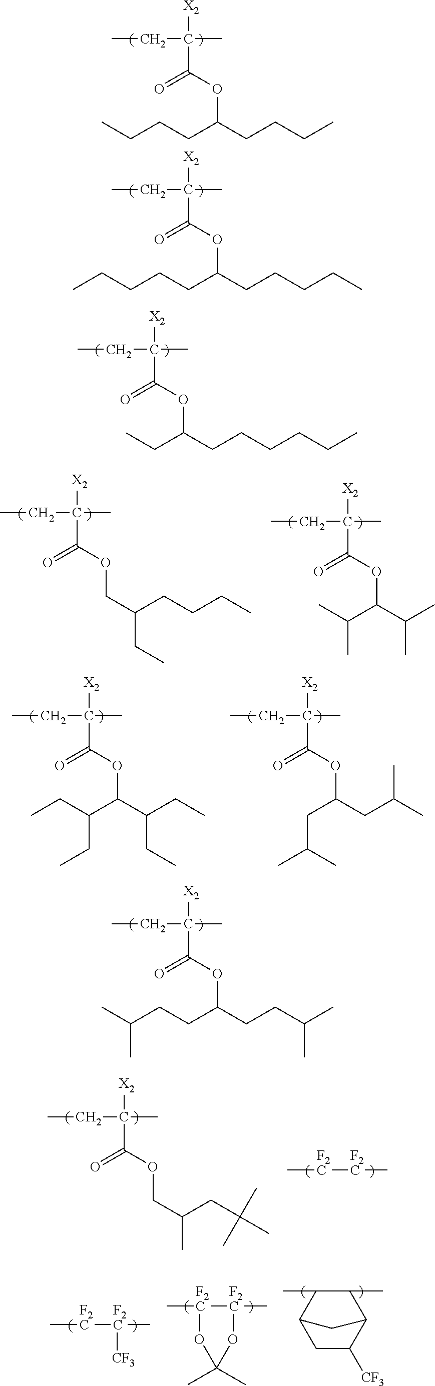

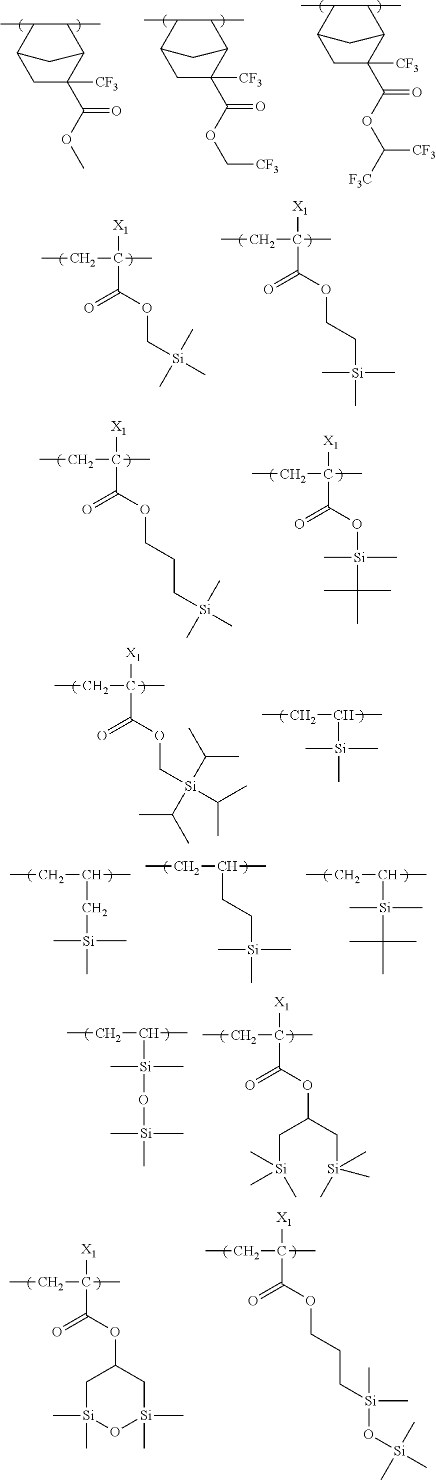

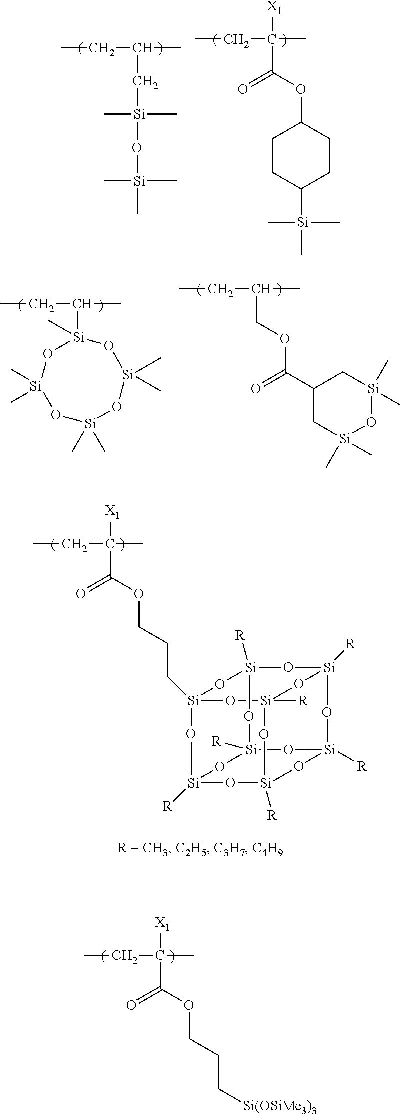

The hydrophobic resin preferably has a repeating unit (b) which has at least one group selected from a group consisting of (x) to (z) below.

(x) Alkali-soluble group

(y) Group of which the solubility increases with respect to an alkali developer due to being decomposed by the effect of an alkali developer (also referred to below as a polar conversion group)

(z) Group of which, due to being decomposed by an action of an acid, the solubility increases with respect to an alkali developer

Examples of the repeating unit (b) include the types below.
Repeating unit (b′) which has at least either a fluorine atom or a silicon atom and at least one group selected from a group consisting of (x) to (z) described above on one side chain
Repeating unit (b*) which has at least one group selected from a group consisting of (x) to (z) described above and does not have a fluorine atom or a silicon atom
Repeating unit (b″) which has at least one group selected from a group consisting of (x) to (z) described above on one side chain and has at least either a fluorine atom or a silicon atom on a side chain which is different from the side chain described above in the same repeating unit

The hydrophobic resin more preferably has the repeating unit (b′) as the repeating unit (b). That is, the repeating unit (b) which has at least one group selected from a group consisting of (x) to (z) described above more preferably has at least either a fluorine or a silicon atom.

Here, in a case where the hydrophobic resin has the repeating unit (b*), it is preferably a copolymer with a repeating unit which has at least either a fluorine atom or a silicon atom (a repeating unit which is different from the repeating units (b′) and (b″) described above). In addition, it is preferable that a side chain which has at least one group selected from a group consisting of (x) to (z) described above and a side chain which has at least either a fluorine atom or a silicon atom in the repeating unit (b″) are bonded with the same carbon atom in the main chain, that is, in a positional relationship such as in Formula (K1) below.

In the formula, B1 represents a partial structure which has at least one group selected from a group consisting of (x) to (z) described above and B2 represents a partial structure which has at least either a fluorine atom or a silicon atom.

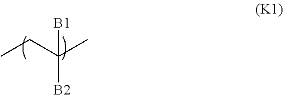

A group selected from a group consisting of (x) to (z) described above is preferably (x) an alkali-soluble group or (y) a polar conversion group and more preferably (y) a polar conversion group.

Examples of the alkali-soluble group (x) include a phenolic hydroxyl group, a carboxylic acid group, a fluorinated alcohol group, a sulfonic acid group, a sulfonamide group, a sulfonylimide group, an (alkylsulfonyl) (alkylcarbonyl) methylene group, an (alkylsulfonyl) (alkylcarbonyl) imide group, a bis(alkylcarbonyl) methylene group, a bis(alkylcarbonyl) imide group, a bis(alkylsulfonyl) methylene group, a bis(alkylsulfonyl) imide group, a tris(alkylcarbonyl) methylene group, a tris(alkylsulfonyl) methylene group, and the like.

Examples of a preferable alkali-soluble group include a fluorinated alcohol group (preferably hexafluoroisopropanol), a sulfonimide group, and a bis(carbonyl) methylene group.

Examples of a repeating unit (bx) which has the alkali-soluble group (x) include a repeating unit in which an alkali-soluble group is directly bonded with a main chain of a resin such as a repeating unit by acrylic acid and methacrylic acid, a repeating unit in which an alkali-soluble group is bonded with the main chain of a resin via a linking group, and the like and furthermore, it is also possible to use a polymerization initiator or a chain transfer agent which has an alkali-soluble group during the polymerization to introduce the polymerization initiator or the chain transfer agent to the end of a polymer chain, and either case is preferable.

In a case where the repeating unit (bx) is a repeating unit which has at least either a fluorine atom or a silicon atom (that is, in a case of being equivalent to the repeating unit (b′) or (b″) described above), examples of a partial structure which has a fluorine atom in the repeating unit (bx) include the same examples as for the repeating unit which has at least either a fluorine atom or a silicon atom described above and preferable examples thereof include a group which is represented by General Formulas (F2) to (F4) described above. In addition, in this case, examples of a partial structure which has a silicon atom in the repeating unit (bx) include the same examples as for the repeating unit which has at least either a fluorine atom or a silicon atom, and preferably include a group which is represented by General Formulas (CS-1) to (CS-3) described above.

The content of the repeating unit (bx) which has the alkali-soluble group (x) is preferably 1 mol % to 50 mol % with respect to all of the repeating units in the hydrophobic resin, more preferably 3 mol % to 35 mol %, and even more preferably 5 mol % to 20 mol %.

Specific examples of the repeating unit (bx) which has the alkali-soluble group (x) will be shown below; however, the present invention is not limited thereto. Here, in the specific examples, X₁ represents a hydrogen atom, —CH₃, —F, or —CF₃.

In the formula. Rx represents H, CH₃, CF₃, and CH₂OH.

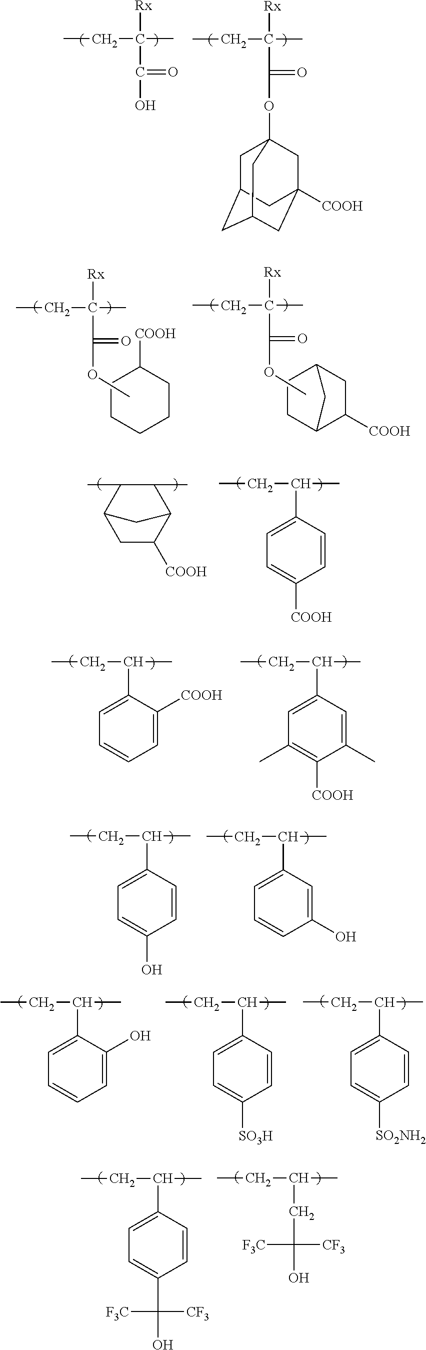

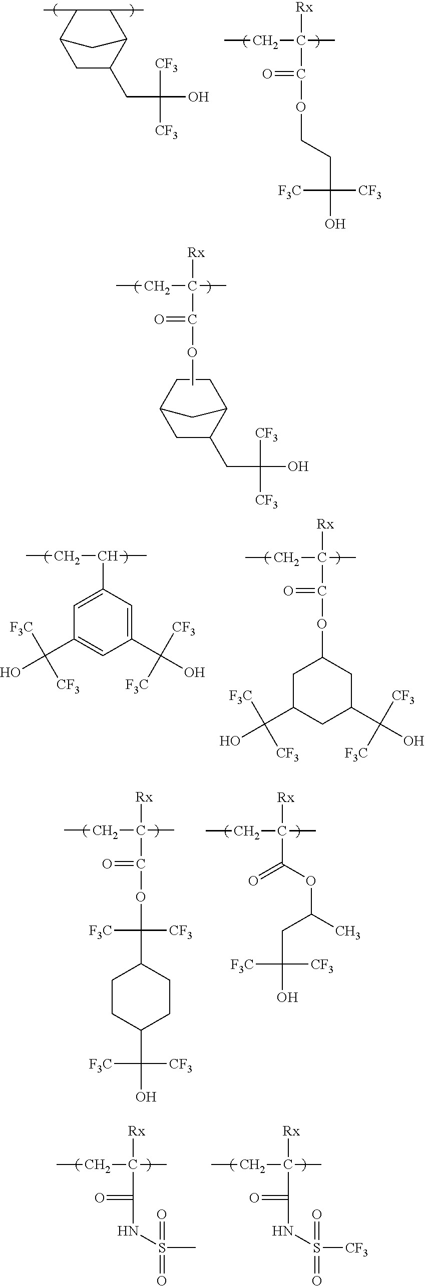

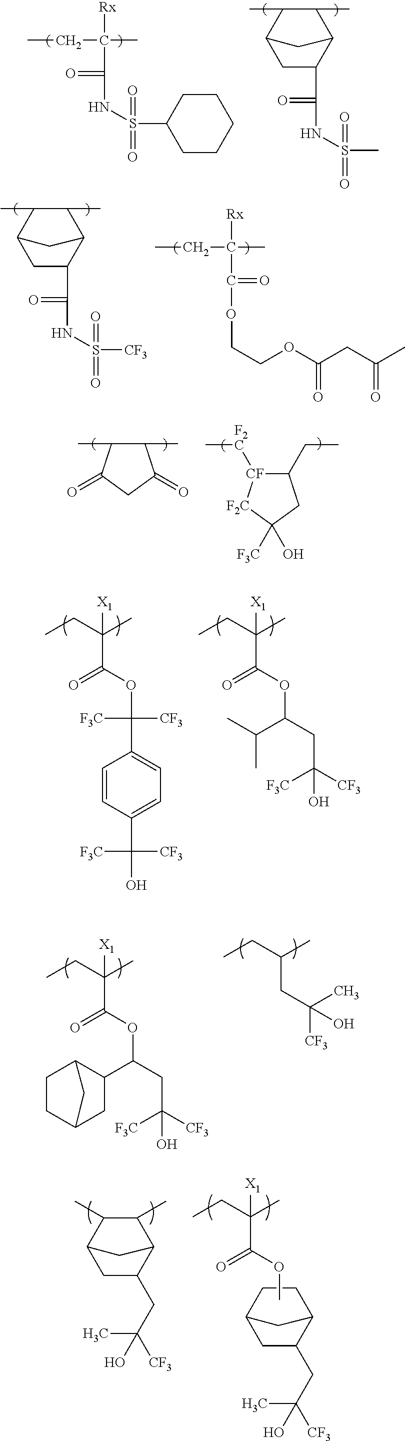

Examples of the polar conversion group (y) include a lactone group, a carboxylic acid ester group (—COO—), an acid anhydride (—C(O)OC(O)—) group, an acid imide group (—NHCONH—), a carboxylic acid thioester group (—COS—), a carbonic ester group (—OC(O)O—), a sulfate ester group (—OSO₂O—), a sulfonic acid ester group (—SO₂O—), and the like, and a lactone group is preferable.

The polar conversion group (y) is preferably, for example, either in a form introduced to a side chain of a resin by being included in a repeating unit using acrylic acid ester and methacrylic acid ester, or in a form introduced to an end of a polymer chain using a polymerization initiator or a chain transfer agent which has the polar conversion group (y) during the polymerization.

Specific examples of the repeating unit (by) which has the polar conversion group (y) include a repeating unit which has a lactone structure which is represented by Formulas (KA-1-1) to (KA-1-17) which will be described below.

Furthermore, the repeating unit (by) which has the polar conversion group (y) is preferably a repeating unit which has at least either a fluorine atom or a silicon atom (that is, equivalent to the repeating units (b′) and (b″) described above). A resin which has the repeating unit (by) has hydrophobicity and is preferable in the point of view of reduction of developing defects in particular.

Examples of the repeating unit (by) include a repeating unit which is illustrated by Formula (KO).

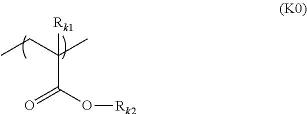

In the formula, Rₖ₁ represents a hydrogen atom, a halogen atom, a hydroxyl group, an alkyl group, a cycloalkyl group, an aryl group, or a group which has a polar conversion group.

Rₖ₂ represents an alkyl group, a cycloalkyl group, an aryl group, or a group which has a polar conversion group.

However, at least one of Rₖ₁ and Rₖ₂ represents a group which includes a polar conversion group.

The polar conversion group represents a group of which the solubility in an alkali developer increases due to being decomposed by an effect of an alkali developer as described above. The polar conversion group is preferably a group which is represented by X in a partial structure which is represented by General Formula (KA-1) or (KB-1).

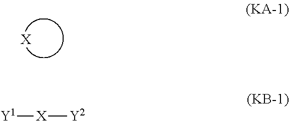

X in General Formula (KA-1) or (KB-1) represents a carboxylic acid ester group: —COO—, an acid anhydride group: —C(O)OC(O)—, an acid imide group: —NHCONH—, a carboxylic acid thioester group: —COS—, a carbonic ester group: —OC(O)O—, a sulfate ester group: —OSO₂O—, and a sulfonic acid ester group: —SO₂O—.

Y¹ and Y² may be each the same or may be different and represent an electron withdrawing group.

Here, the repeating unit (by) has a group of which the solubility increases in a preferable alkali developer due to having a group which has a partial structure which is represented by General Formula (KA-1) or (KB-1); however, in a case where the partial structure does not have an atomic bond such as in the case of a partial structure which is represented by (KB-1) in a case where the partial structure which is represented by General Formula (KA-1), Y¹, and Y² are monovalent, the group which has the partial structure is a group which has a monovalent or higher group in which at least one arbitrary hydrogen atom in the partial structure is removed.

A partial structure which is represented by General Formula (KA-1) or (KB-1) is linked with the main chain of a hydrophobic resin at an arbitrary position via a substituent group.

The partial structure which is represented by General Formula (KA-1) is a structure which forms a ring structure with a group as X.

X in General Formula (KA-1) is preferably a carboxylic acid ester group (that is, in the case of forming a lactone ring structure as KA-1), an acid anhydride group, or a carbonic ester group. A carboxylic acid ester group is more preferable.

A ring structure which is represented by General Formula (KA-1) may have a substituent group and, for example, may have nka of the substituent group Zₖₐ₁.

Zₖₐ₁ each independently represent a halogen atom, an alkyl group, a cycloalkyl group, an ether group, a hydroxyl group, an amide group, an aryl group, a lactone ring group, or an electron withdrawing group in a case where there are a plurality thereof.

Zₖₐ₁s may form a ring by linking with each other. Examples of a ring which Zₖₐ₁s form by linking with each other include a cycloalkyl ring, and a hetero ring (a cyclic ether ring, a lactone ring, and the like).

nka represents an integer of 0 to 10. nka is preferably an integer of 0 to 8, more preferably an integer of 0 to 5, even more preferably an integer of 1 to 4, and most preferably an integer of 1 to 3.

An electron withdrawing group as Zₖₐ₁ is the same as the electron withdrawing group as Y¹ and Y² which will be described below. Here, the electron withdrawing group described above may be substituted with another electron withdrawing group.

Zₖₐ₁ is preferably an alkyl group, a cycloalkyl group, an ether group, a hydroxyl group, or an electron withdrawing group, and more preferably an alkyl group, a cycloalkyl group, or an electron withdrawing group. Here, the ether group is preferably an ether group which is substituted with an alkyl group, a cycloalkyl group, or the like, that is, an alkylether group, and the like. The electron withdrawing group is the same as described above.

In addition, in one aspect, the hydrophobic resin preferably has the partial structure which will be described below.

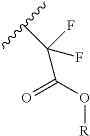

In the formula, R represents a hydrogen atom, an alkyl group which may be substituted, a cycloalkyl group which may be substituted, or an aryl group which may be substituted, and is preferably an alkyl group which is substituted with a fluorine atom.

While the hydrophobic resin naturally has few impurities such as metals in the same manner as the resin (B) described above, the residual monomers or oligomer components are preferably 0 mass % to 10 mass %, more preferably 0 mass % to 5 mass %, and even more preferably 0 mass % to 1 mass %. Due to this, a resist composition where the foreign matter in the liquid or the sensitivity or the like does not change over time is obtained. In addition, from the viewpoint of the resolution, the resist shape, the side wall of the resist pattern, the roughness, and the like, the molecular weight distribution (Mw/Mn, also referred to as the dispersity) is preferably in a range of 1 to 3, more preferably 1 to 2, even more preferably 1 to 1.8, and most preferably in a range of 1 to 1.5.

It is also possible to use various types of commercial products for the hydrophobic resin and it is possible to synthesize the resin using normal methods (for example, radical polymerization). Examples of typical synthesizing methods include a collective polymerization method in which polymerization is performed by dissolving a type of monomer and an initiator in a solvent and heating, a dripping polymerization method in which a solution of a type of monomer and an initiator is dripped and added to a heating solvent over 1 to 10 hours, and the like, and the dripping polymerization method is preferable.

The reaction solvent, the polymerization initiator, the reaction conditions (temperature, concentration, and the like), and the purifying method after reaction are the same as in the content described for the resin (B) described above.

Specific examples of the hydrophobic resin (HR) will be shown below. In addition, Table 1 below shows the molar ratio of the repeating unit in each resin (the positional relationship of each repeating unit in each resin shown in the specific examples and the positional relationship of the number of the composition ratios in Table 1 correspond to each other), the weight average molecular weight, and the dispersity.

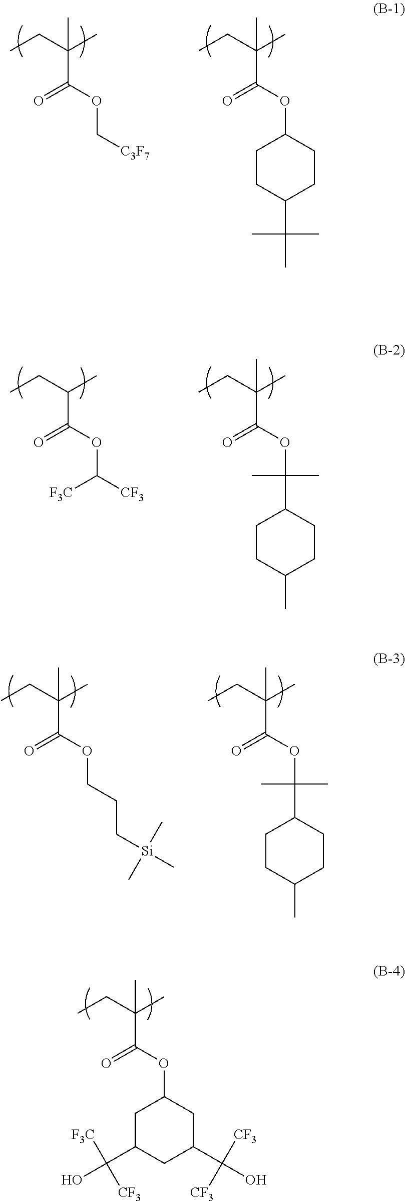

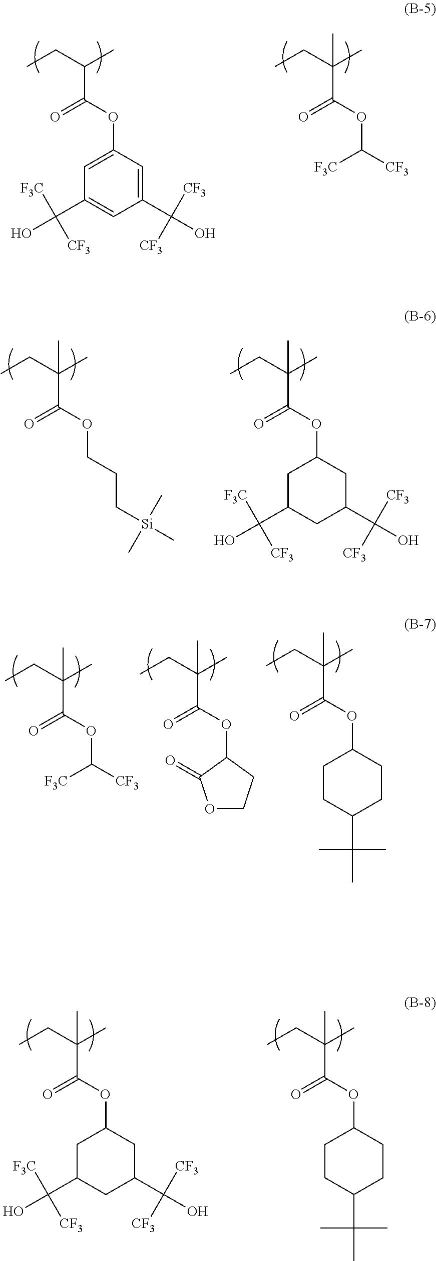

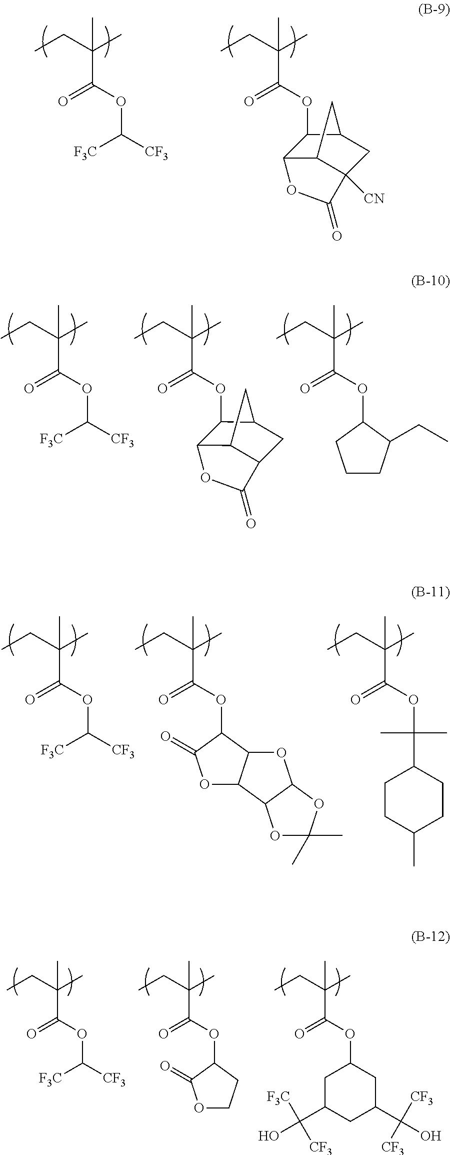

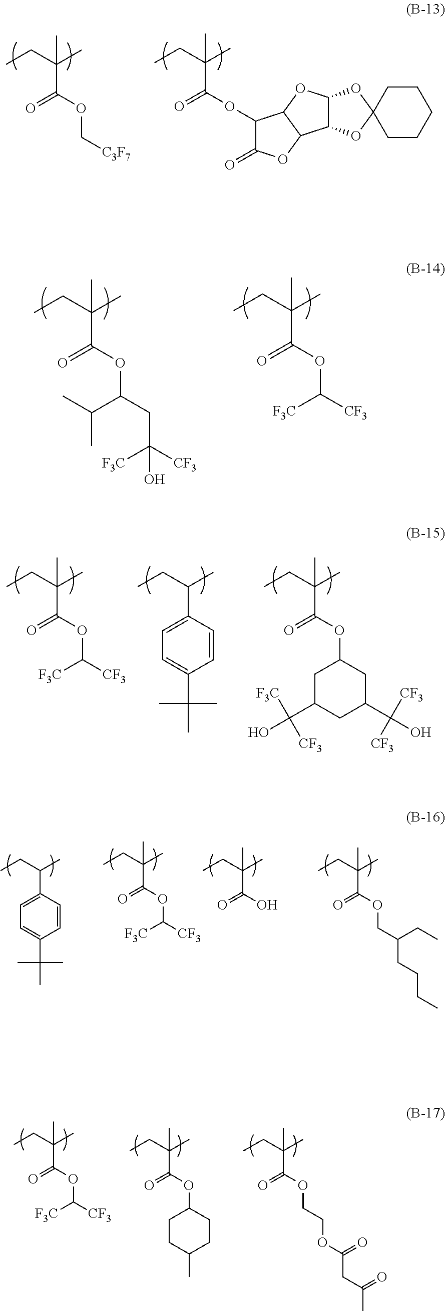

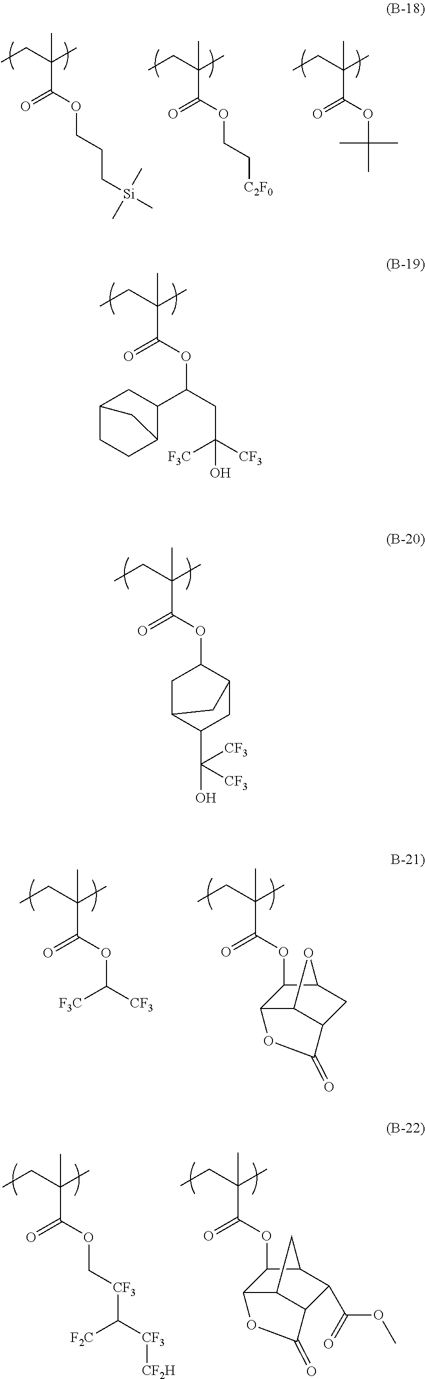

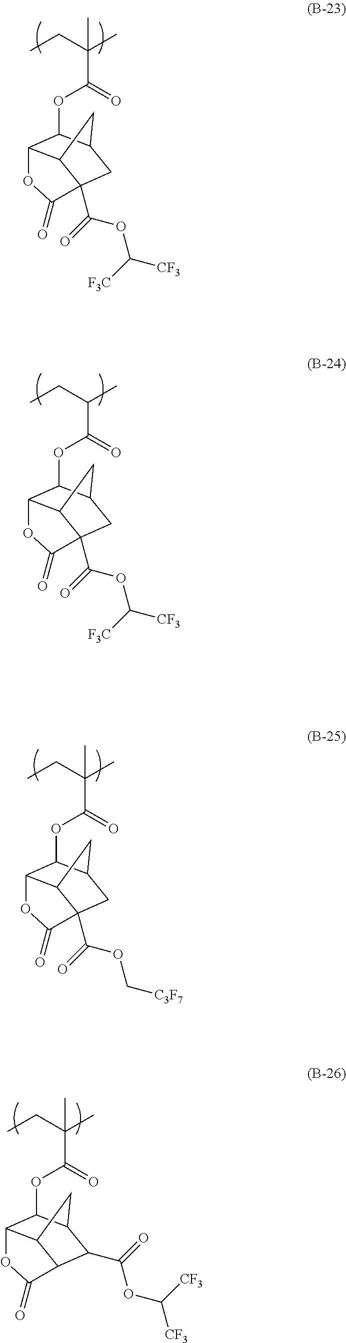

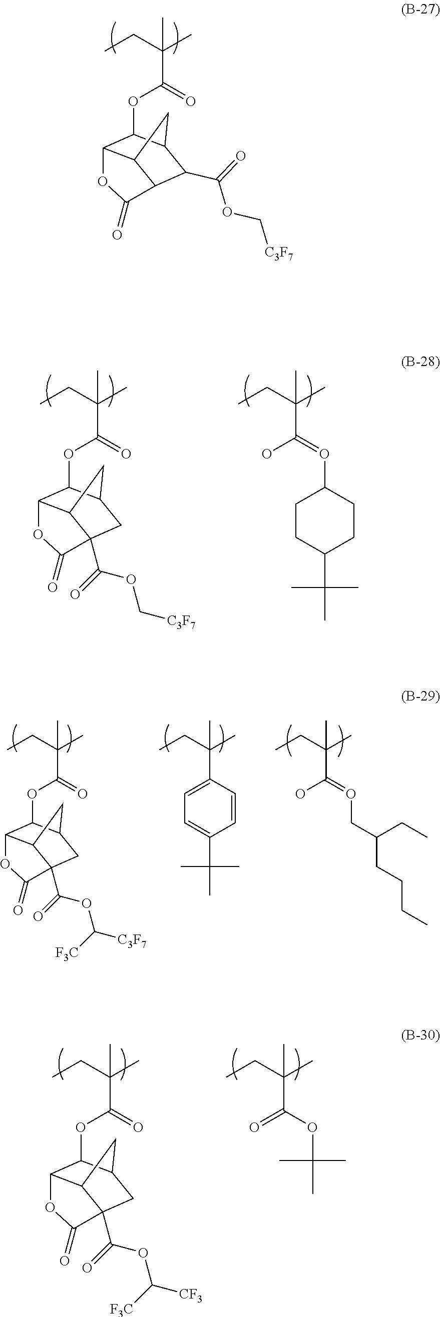

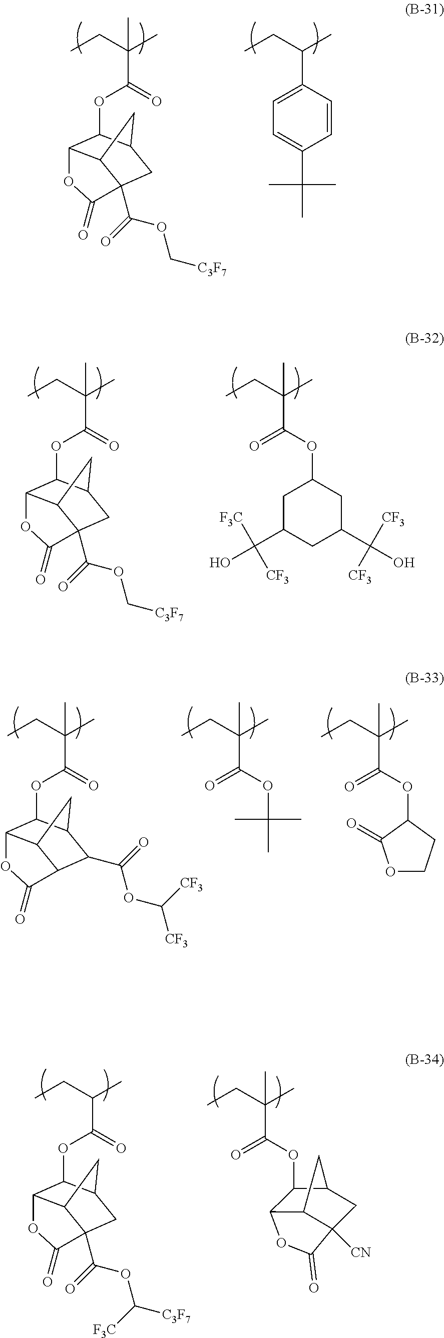

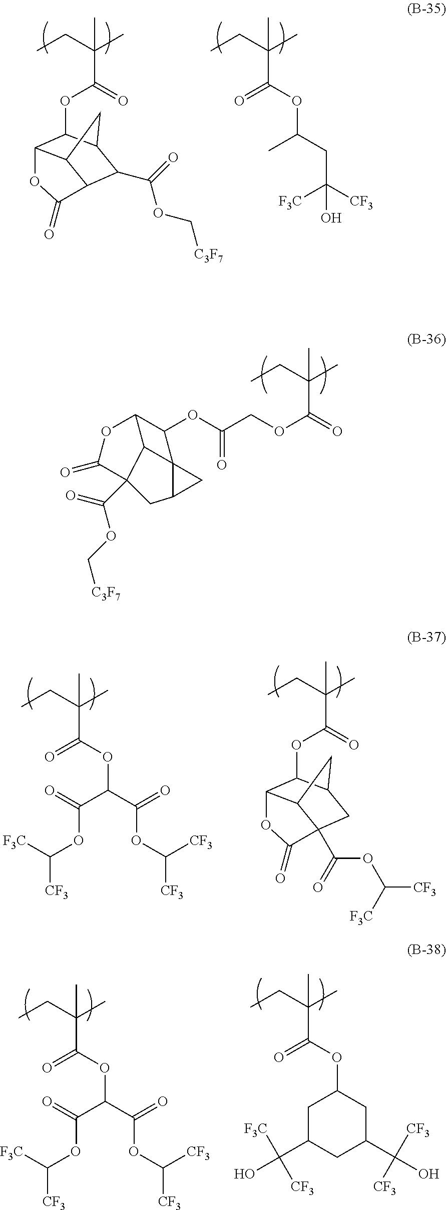

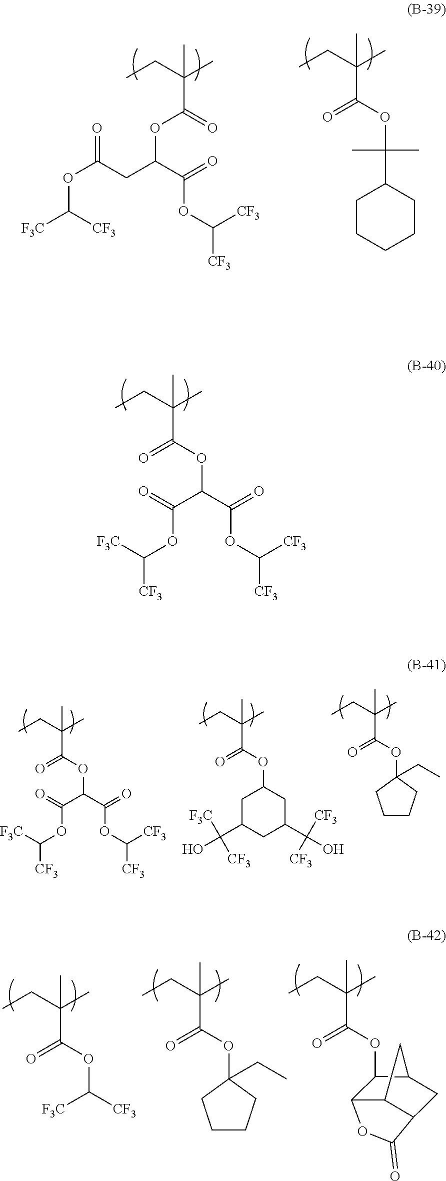

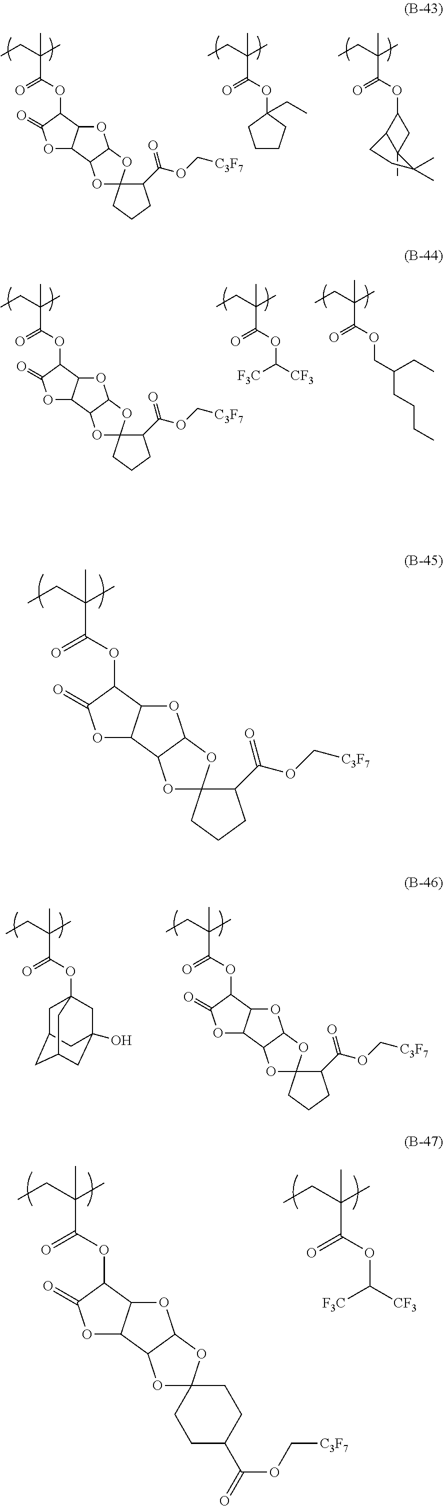

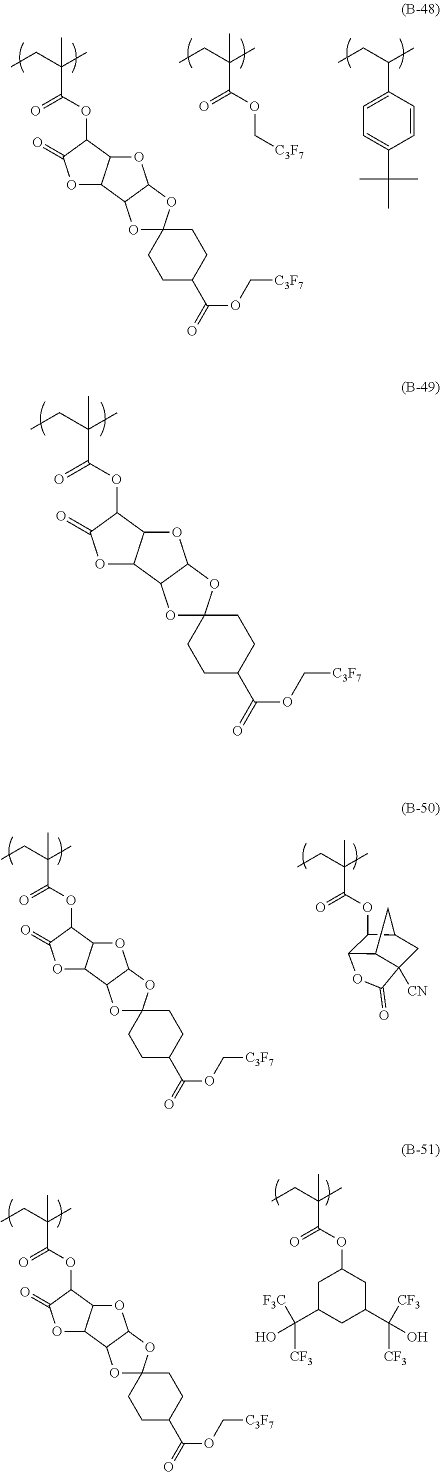

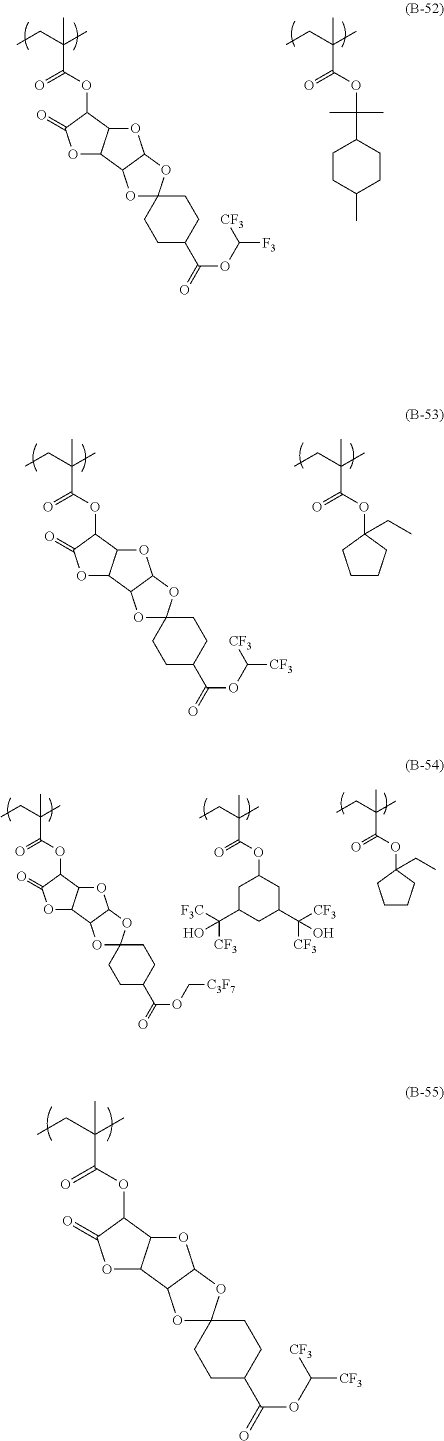

TABLE 1

| | Composition | | |
|---|---|---|---|
| Polymer | ratio (mol %) | Mw | Mw/Mn |
| B-1 | 50/50 | 6000 | 1.5 |
| B-2 | 30/70 | 6500 | 1.4 |
| B-3 | 45/55 | 8000 | 1.4 |
| B-4 | 100 | 15000 | 1.7 |
| B-5 | 60/40 | 6000 | 1.4 |
| B-6 | 40/60 | 8000 | 1.4 |
| B-7 | 30/40/30 | 8000 | 1.4 |
| B-8 | 60/40 | 8000 | 1.3 |
| B-9 | 50/50 | 6000 | 1.4 |
| B-10 | 40/40/20 | 7000 | 1.4 |
| B-11 | 40/30/30 | 9000 | 1.6 |
| B-12 | 30/30/40 | 6000 | 1.4 |
| B-13 | 60/40 | 9500 | 1.4 |
| B-14 | 60/40 | 8000 | 1.4 |
| B-15 | 35/35/30 | 7000 | 1.4 |
| B-16 | 50/40/5/5 | 6800 | 1.3 |
| B-17 | 20/30/50 | 8000 | 1.4 |
| B-18 | 25/25/50 | 6000 | 1.4 |
| B-19 | 100 | 9500 | 1.5 |
| B-20 | 100 | 7000 | 1.5 |
| B-21 | 50/50 | 6000 | 1.6 |
| B-22 | 40/60 | 9600 | 1.3 |
| B-23 | 100 | 20000 | 1.7 |
| B-24 | 100 | 25000 | 1.4 |
| B-25 | 100 | 15000 | 1.7 |
| B-26 | 100 | 12000 | 1.8 |
| B-27 | 100 | 18000 | 1.3 |
| B-28 | 70/30 | 15000 | 2.0 |
| B-29 | 80/15/5 | 18000 | 1.8 |
| B-30 | 60/40 | 25000 | 1.8 |
| B-31 | 90/10 | 19000 | 1.6 |
| B-32 | 60/40 | 20000 | 1.8 |
| B-33 | 50/30/20 | 11000 | 1.6 |
| B-34 | 60/40 | 12000 | 1.8 |
| B-35 | 60/40 | 15000 | 1.6 |
| B-36 | 100 | 22000 | 1.8 |
| B-37 | 20/80 | 35000 | 1.6 |
| B-38 | 30/70 | 12000 | 1.7 |
| B-39 | 30/70 | 9000 | 1.5 |
| B-40 | 100 | 9000 | 1.5 |
| B-41 | 40/15/45 | 12000 | 1.9 |
| B-42 | 30/30/40 | 13000 | 2.0 |
| B-43 | 40/40/20 | 23000 | 2.1 |
| B-44 | 65/30/5 | 25000 | 1.6 |
| B-45 | 100 | 15000 | 1.7 |
| B-46 | 20/80 | 9000 | 1.7 |
| B-47 | 70/30 | 18000 | 1.5 |
| B-48 | 60/20/20 | 18000 | 1.8 |
| B-49 | 100 | 12000 | 1.4 |
| B-50 | 60/40 | 20000 | 1.6 |
| B-51 | 70/30 | 33000 | 2.0 |
| B-52 | 60/40 | 19000 | 1.8 |
| B-53 | 50/50 | 15000 | 1.5 |
| B-54 | 40/20/40 | 35000 | 1.9 |
| B-55 | 100 | 16000 | 1.4 |

Due to the active light-sensitive or radiation-sensitive resin composition of the present invention containing a hydrophobic resin with a hydrophobic property which contains at least either a fluorine atom or a silicon atom, the hydrophobic resin is unevenly distributed in a surface layer of a film which is formed with the active light-sensitive or radiation-sensitive resin composition and, in a case where the immersion liquid is water, it is possible to improve the receding contact angle of the film surface with respect to the water after baking and before exposure, and to improve the immersion liquid conformance.

The receding contact angle of the film after baking a coated film formed of the active light-sensitive or radiation-sensitive resin composition of the present invention and before exposure is preferably 60° to 90° at the temperature during the exposure, at a normal room temperature of 23±3° C., and at a humidity of 45±5%, more preferably 65° or more, even more preferably 70° or more, and particularly preferably 75° or more.

The hydrophobic resin is unevenly distributed on an interface as described above; however, unlike a surfactant, it is not necessary to have a hydrophilic group in the molecule, and the resin may or may not contribute to the uniform mixing of polar/nonpolar substances.

In the liquid immersion exposure step, since it is necessary for an immersion liquid to move on a wafer by conforming to the movement of an exposure head which scans the wafer at high speed and form an exposure pattern, the contact angle of the immersion liquid with respect to the resist film in a dynamic state is important and there is a demand for the resist to have a performance which conforms to high speed scanning by the exposure head without liquid droplets remaining thereon.

Since the hydrophobic resin is hydrophobic, the state easily deteriorates with regard to developer residue (scum) and blob defects after the alkaline developing; however, since the alkali dissolving speed is improved compared to a straight-chain type resin by having three or more polymer chains via at least one branched section, the developer residue (scum) and the blob defects are improved.

In a case where the hydrophobic resin has fluorine atoms, the content of the fluorine atoms is preferably 5 mass % to 80 mass % with respect to the molecular weight of the hydrophobic resin and more preferably 10 mass % to 80 mass %. In addition, the repeating unit which includes a fluorine atom is preferably 10 mol % to 100 mol % with respect to all of the repeating units in the hydrophobic resin and more preferably 30 mol % to 100 mol %.

In a case where the hydrophobic resin has silicon atoms, the content of the silicon atoms is preferably 2 mass % to 50 mass % with respect to the molecular weight of the hydrophobic resin and more preferably 2 mass % to 30 mass %. In addition, the repeating unit which includes a silicon atom is preferably 10 mol % to 90 mol % with respect to all of the repeating units in the hydrophobic resin and more preferably 20 mol % to 80 mol %.

The weight average molecular weight of the hydrophobic resin is preferably 1,000 to 100,000, more preferably 2,000 to 50,000, and even more preferably 3,000 to 35,000. Here, the weight average molecular weight of the resin indicates a polystyrene conversion molecular weight which is measured by GPC (carrier: tetrahydrofuran (THF)).

It is possible to appropriately adjust the content of the hydrophobic resin in the active light-sensitive or radiation-sensitive resin composition for use such that the receding contact angle of the active light-sensitive or radiation-sensitive resin film is in the ranges described above; however, the content is preferably 0.01 mass % to 20 mass % based on the total solid content of the active light-sensitive or radiation-sensitive resin composition, more preferably 0.1 mass % to 15 mass %, even more preferably 0.1 mass % to 10 mass %, and particularly preferably 0.2 mass % to 8 mass %.

It is possible to use the hydrophobic resin as one type individually or in a combination of two or more types.

[4] (D) Low molecular compound which has a nitrogen atom and a group which is desorbed due to an action of an acid

The composition of the present invention is able to contain a low molecular compound (also referred to below as a “low molecular compound (D)” or a “compound (D)”) which has a nitrogen atom and a group which is desorbed due to an action of an acid.

The group which is desorbed due to the action of an acid is not particularly limited; however, an acetal group, a carbonate group, a carbamate group, a tertiary ester group, a tertiary hydroxyl group, and a hemiaminalether group are preferable, and a carbamate group and a hemiaminalether group are particularly preferable.

The molecular weight of the low molecular compound (D) which has a group which is desorbed due to an action of an acid is preferably 100 to 1000, more preferably 100 to 700, and particularly preferably 100 to 500.

The compound (D) is preferably an amine derivative which has a group which is desorbed due to an action of an acid on a nitrogen atom.

The compound (D) may have a carbamate group which has a protective group on a nitrogen atom. It is possible to represent a protective group which forms a carbamate group with General Formula (d-1) below.

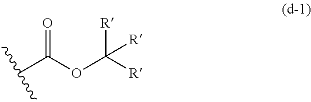

In General Formula (d-1),
R′ each independently represent a hydrogen atom, a straight-chain or branched alkyl group, a cycloalkyl group, an aryl group, an aralkyl group, or an alkoxyalkyl group. R′ may bond with each other to form a ring.

R′ is preferably a straight-chain or branched alkyl group, a cycloalkyl group, or an aryl group. A straight-chain or branched alkyl group and a cycloalkyl group are more preferable.

Specific structures of the groups will be shown below.

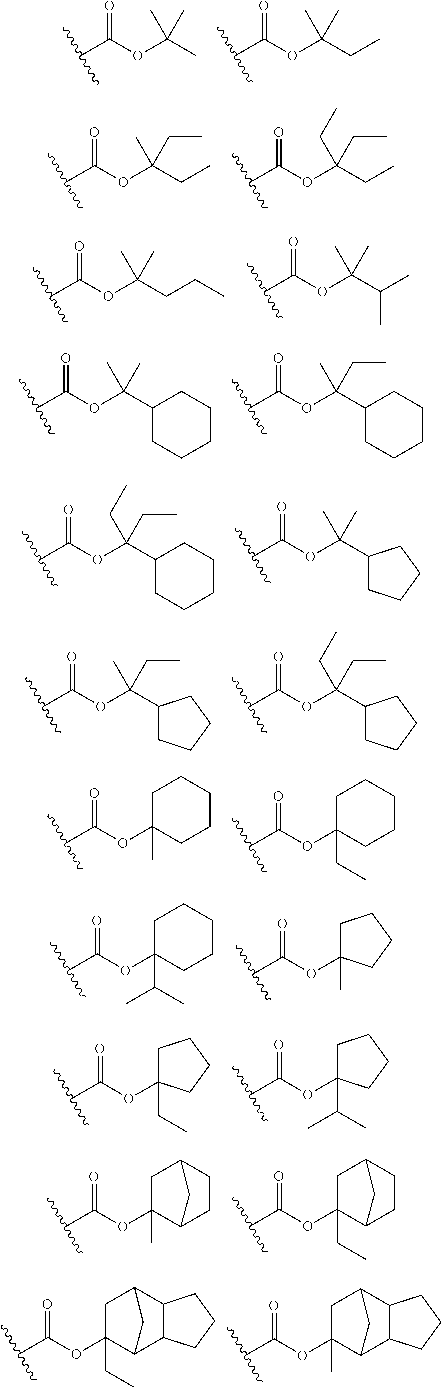

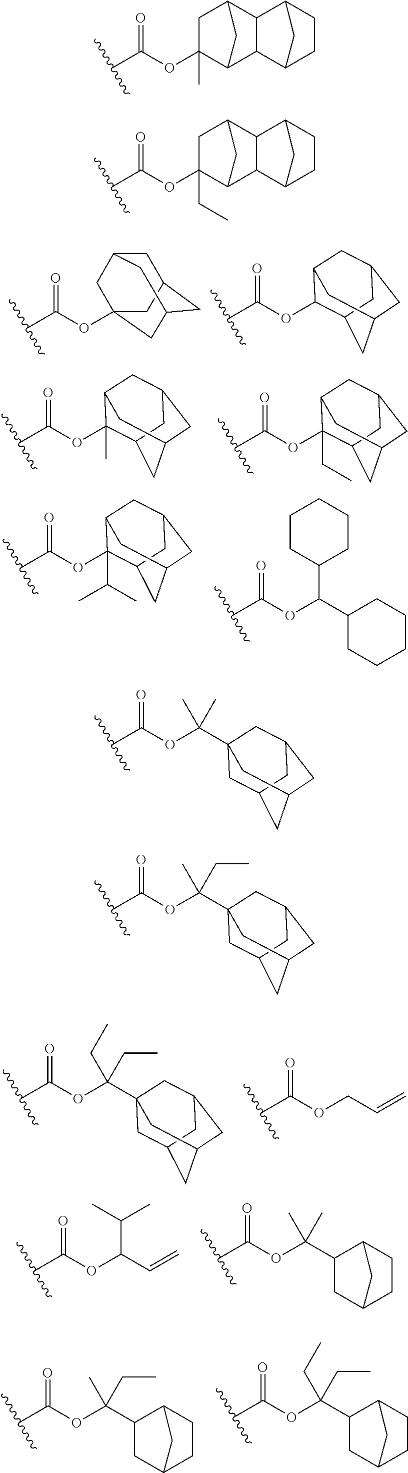

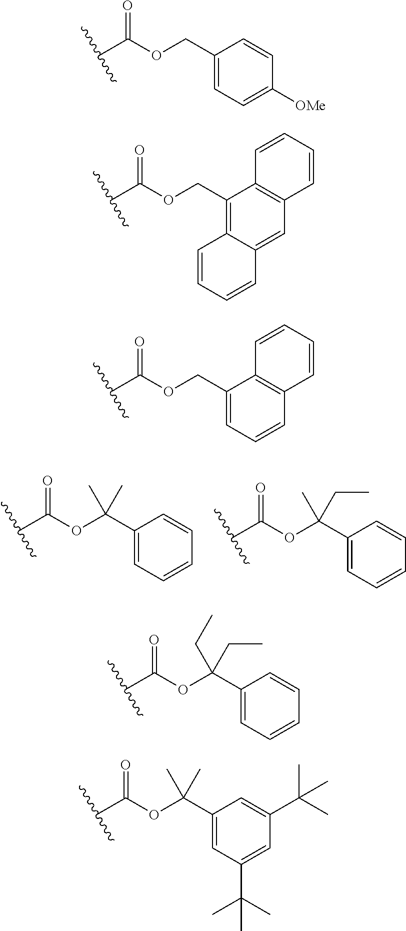

It is also possible to configure the compound (D) by arbitrarily combining the basic compound which will be described below and the structure which is represented by General Formula (d-1).

The compound (D) particularly preferably has the structure which is represented by General Formula (A) below.

Here, the compound (D) may be equivalent to the basic compound described above as long as the compound (D) is a low molecular compound which has a group which is desorbed due to an action of an acid.

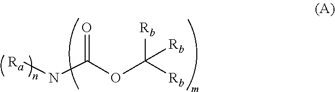

In General Formula (A), Ra indicates a hydrogen atom, an alkyl group, a cycloalkyl group, an aryl group, or an aralkyl group. In addition, when n=2, the two Ra may be the same or different and two Ra may be bonded with each other to form a heterocyclic hydrocarbon group (preferably with 20 or less carbon atoms) or a derivative thereof with a nitrogen atom bonded with Ra.

Rb each independently indicates a hydrogen atom, an alkyl group, a cycloalkyl group, an aryl group, an aralkyl group, or an alkoxyalkyl group. However, in —C(Rb)(Rb)(Rb), when one or more Rb are hydrogen atoms, at least one of the remaining Rb is a cyclopropyl group, a 1-alkoxyalkyl group, or an aryl group.

At least two Rb may be bonded with each other to form an alicyclic hydrocarbon group, an aromatic hydrocarbon group, a heterocyclic hydrocarbon group, or a derivative thereof

n represents an integer of 0 to 2, m represents an integer of 1 to 3, and n+m=3.

In General Formula (A), the alkyl group, the cycloalkyl group, the aryl group, and the aralkyl group indicated by Ra and Rb may be substituted with a functional group such as a hydroxyl group, a cyano group, an amino group, a pyrrolidino group, a piperidino group, a morpholino group, and an oxo group, an alkoxy group, or a halogen atom. The same applies to the examples of the alkoxyalkyl group indicated by Rb.

The alkyl group, the cycloalkyl group, the aryl group, and the aralkyl group of Ra and/or Rb (the alkyl group, the cycloalkyl group, the aryl group, and the aralkyl group may be substituted with the functional groups, the alkoxy group, and the halogen atom described above) include
a group which is derived from straight-chain or branched alkanes such as methane, ethane, propane, butane, pentane, hexane, heptane, octane, nonane, decane, undecane, and dodecane, a group in which the group which is derived from the alkane is substituted with, for example, one or more of one or more types of cycloalkyl group such as a cyclobutyl group, a cyclopentyl group, and a cyclohexyl group,
a group which is derived from a cycloalkane such as cyclobutane, cyclopentane, cyclohexane, cycloheptane, cyclooctane, norbornane, adamantane, and noradamantane, a group in which the group which is derived from the cycloalkane is substituted with, for example, one or more of one or more types of straight-chain or branched alkyl groups such as a methyl group, an ethyl group, an n-propyl group, an i-propyl group, an n-butyl group, a 2-methylpropyl group, a 1-methylpropyl group, and a t-butyl group,
a group which is derived from an aromatic compound such as benzene, naphthalene, and anthracene, a group in which the group which is derived from the aromatic compound is substituted with, for example, one or more of one or more types of straight-chain or branched alkyl groups such as a methyl group, an ethyl group, an n-propyl group, an i-propyl group, an n-butyl group, a 2-methylpropyl group, a 1-methylpropyl group, and a t-butyl group,
a group which is derived from a heterocyclic compound such as pyrrolidine, piperidine, morpholine, tetrahydrofuran, tetrahydropyran, indole, indoline, quinoline, perhydroquinoline, indazole, and benzimidazole, a group in which the group which is derived from the heterocyclic compound is substituted with one or more of one or more types of groups which are derived from a straight-chain or branched alkyl group or an aromatic compound, a group in which a group which is derived from a straight-chain or branched alkane and a group which is derived from a cycloalkane are substituted with one or more of one or more types of groups which are derived from an aromatic compound such as a phenyl group, a naphthyl group, and an anthracenyl group, and the like, or a group in which the substituent groups described above are substituted with functional groups such as a hydroxyl group, a cyano group, an amino group, a pyrrolidino group, a piperidino group, a morpholino group, and an oxo group, or the like.

In addition, examples of a divalent heterocyclic hydrocarbon group (preferably with 1 to 20 carbon atoms) which is formed by Ra bonding with each other or a derivative thereof include a group which is derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[0.4.0] dec-5-ene, indole, indoline, 1,2,3,4-tetrahydroquinoxaline, perhydroquinoline, and 1,5,9-triazacyclododecane; a group in which the groups which are derived from the heterocyclic compound are substituted with one or more of one or more types of groups which are derived from straight-chain or branched alkanes, groups which are derived from cycloalkanes, groups which are derived from an aromatic compound, groups which are derived from a heterocyclic compound, and functional groups such as a hydroxyl group, a cyano group, an amino group, a pyrrolidino group, a piperidino group, a morpholino group, and an oxo group, and the like.

Specific examples of a particularly preferable compound (D) in the present invention will be shown; however, the present invention is not limited thereto.

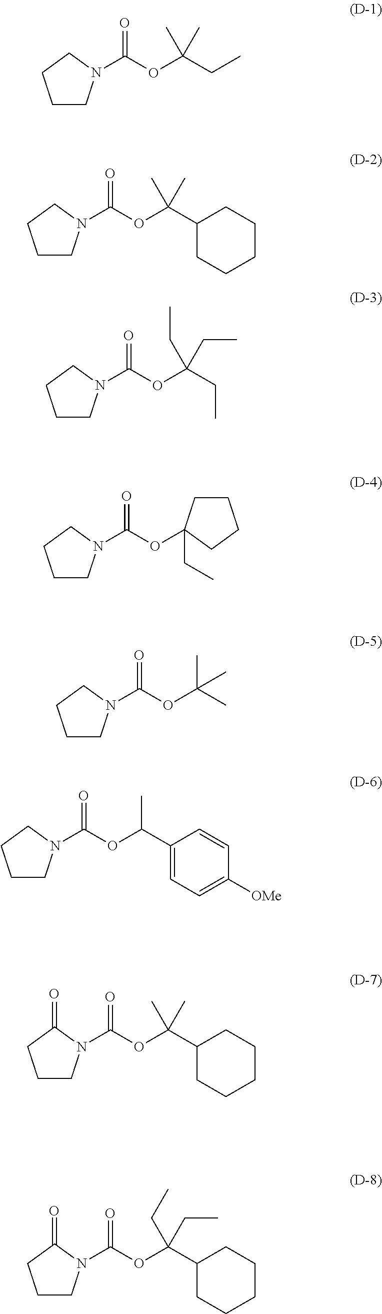

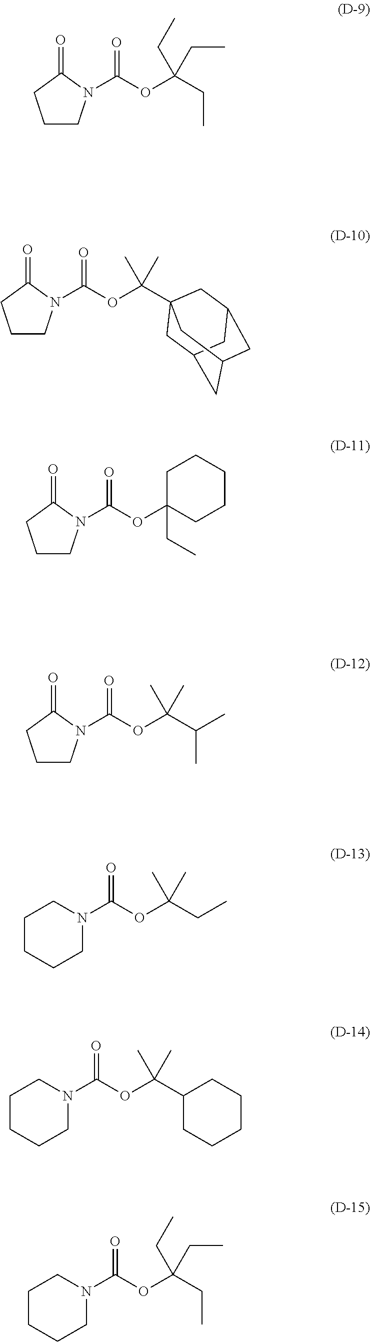

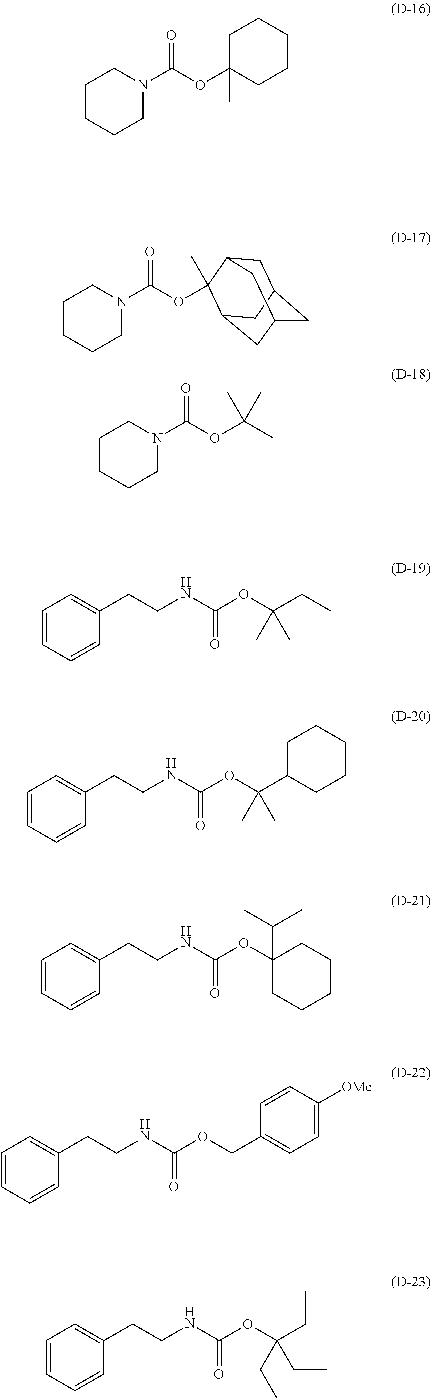

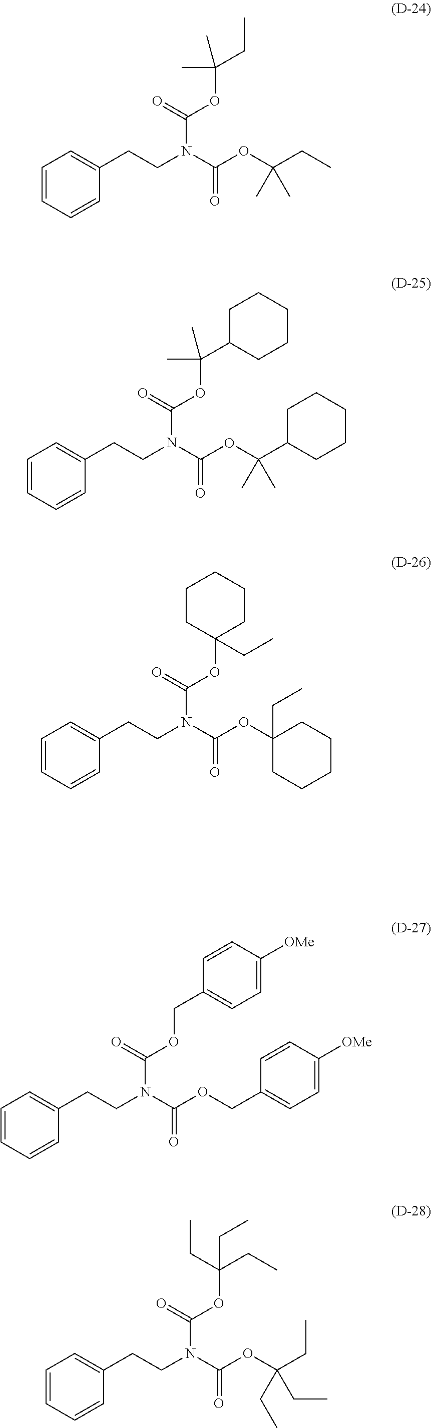 [SMILES: CCC(C)(C)OC(=O)N(CCc1ccccc1)C(=O)OC(C)(C)CC ; CC(C)(OC(=O)N(CCc1ccccc1)C(=O)OC(C)(C)C1CCCCC1)C1CCCCC1 ; CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC]

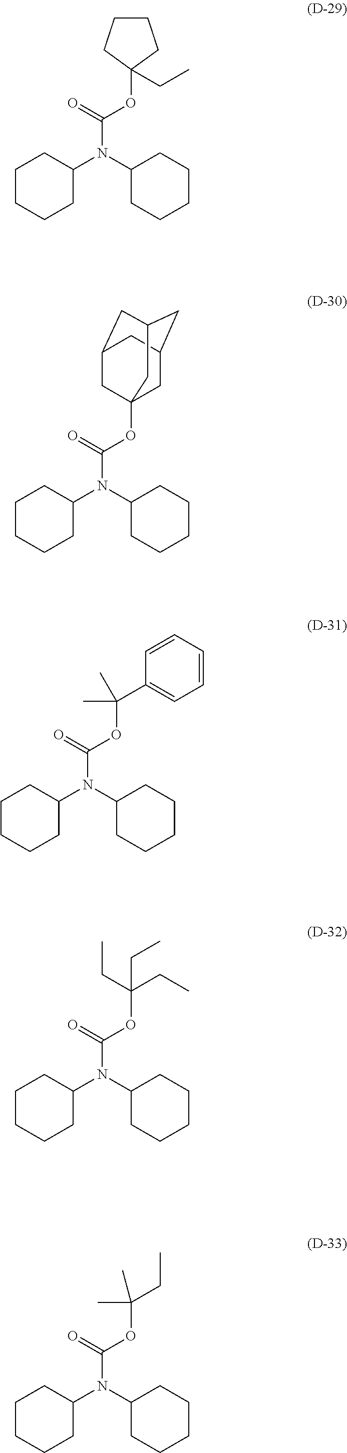 [SMILES: CCC1(OC(=O)N(C2CCCCC2)C2CCCCC2)CCCC1 ; O=C(OC12CC3CC(CC(C3)C1)C2)N(C1CCCCC1)C1CCCCC1 ; CC(C)(OC(=O)N(C1CCCCC1)C1CCCCC1)c1ccccc1 ; CCC(CC)(CC)OC(=O)N(C1CCCCC1)C1CCCCC1 ; CCC(C)(C)OC(=O)N(C1CCCCC1)C1CCCCC1]

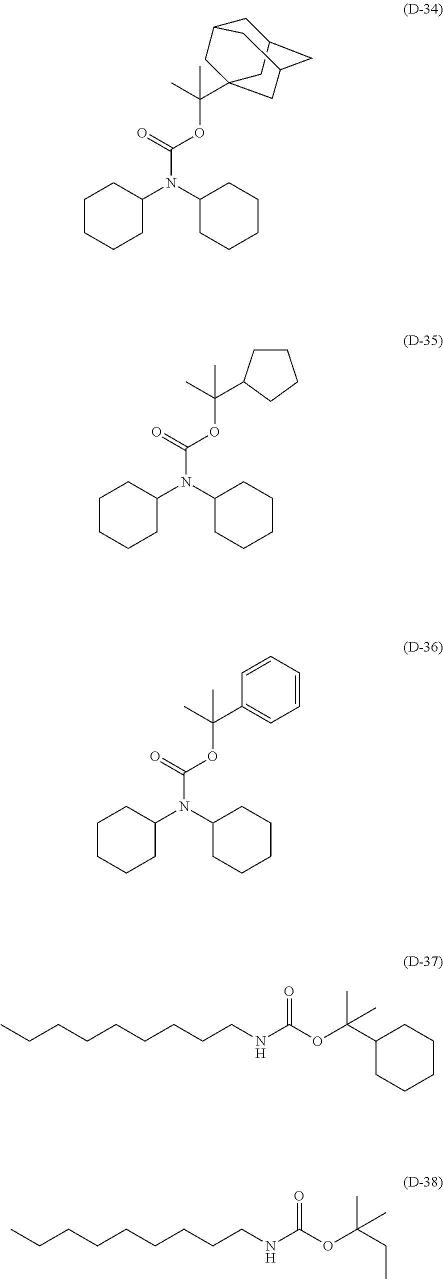 [SMILES: CC(C)(OC(=O)N(C1CCCCC1)C1CCCCC1)C12CC3CC(CC(C3)C1)C2 ; CC(C)(OC(=O)N(C1CCCCC1)C1CCCCC1)C1CCCC1 ; CC(C)(OC(=O)N(C1CCCCC1)C1CCCCC1)c1ccccc1 ; CCCCCCCCCNC(=O)OC(C)(C)C1CCCCC1 ; CCCCCCCCCNC(=O)OC(C)(C)CC]

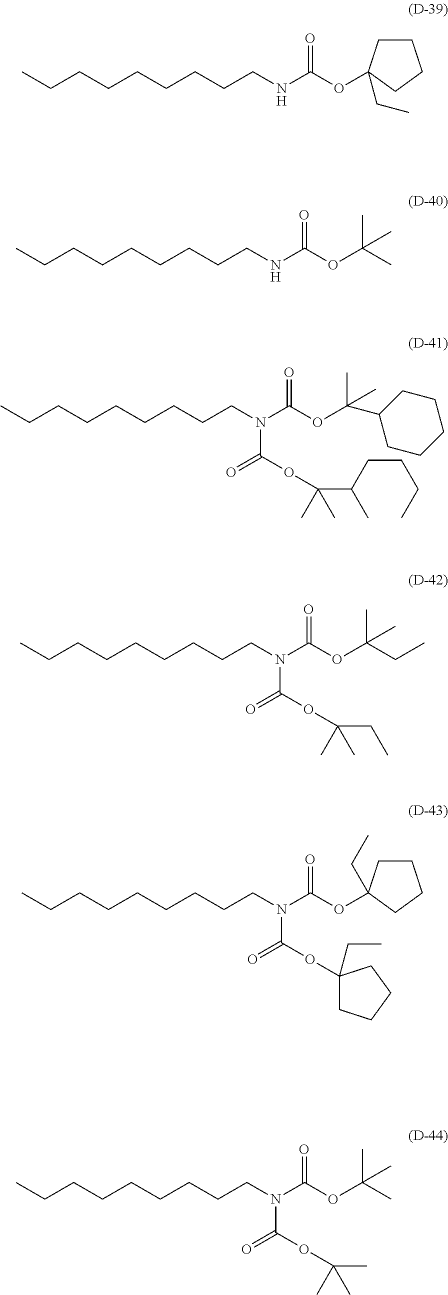

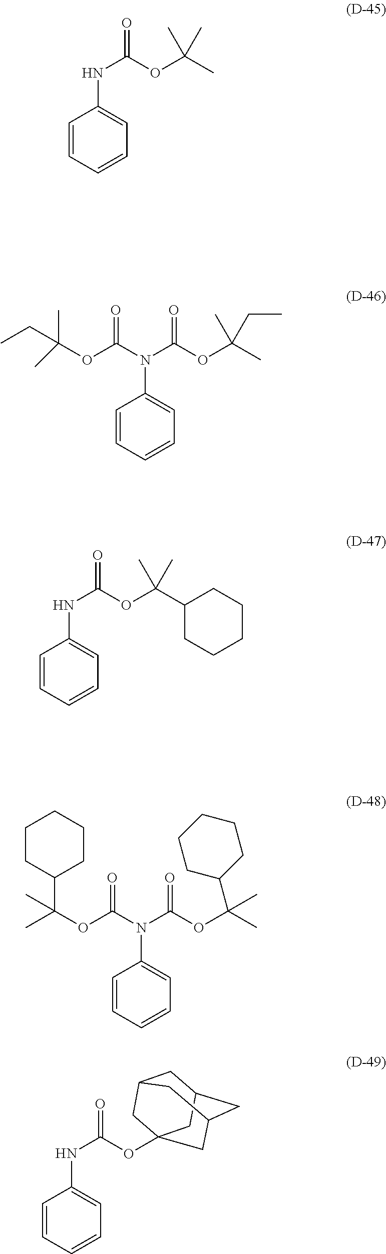

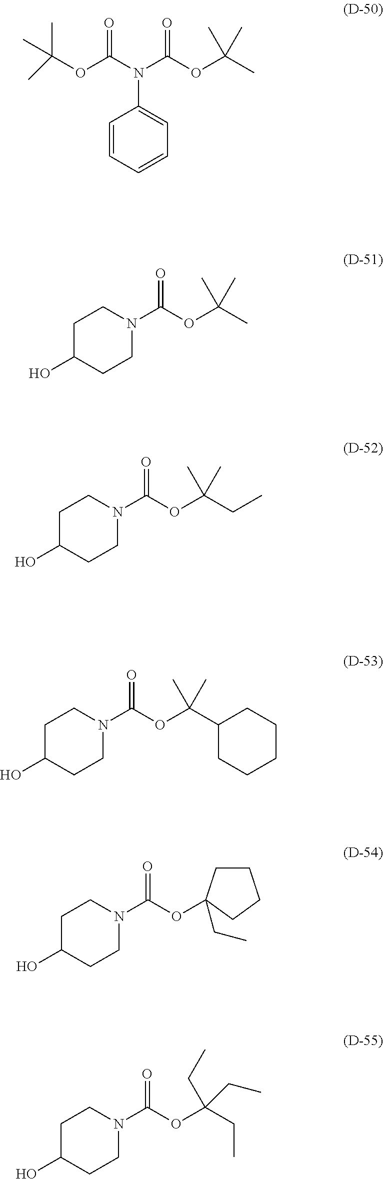 [SMILES: CC(C)(C)OC(=O)N(C(=O)OC(C)(C)C)c1ccccc1 ; CC(C)(C)OC(=O)N1CCC(O)CC1 ; CCC(C)(C)OC(=O)N1CCC(O)CC1 ; CC(C)(OC(=O)N1CCC(O)CC1)C1CCCCC1 ; CCC1(OC(=O)N2CCC(O)CC2)CCCC1 ; CCC(CC)(CC)OC(=O)N1CCC(O)CC1]

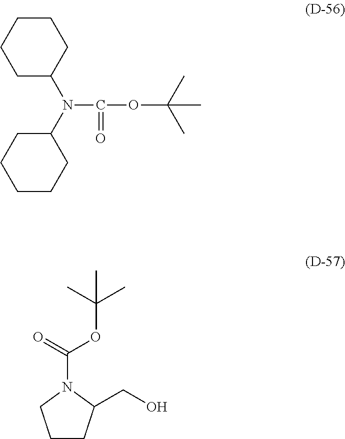 [SMILES: CC(C)(C)OC(=O)N(C1CCCCC1)C1CCCCC1 ; CC(C)(C)OC(=O)N1CCCC1CO]

It is possible to synthesize the compound which is represented by General Formula (A) based on JP2007-298569A, JP2009-199021A, or the like.

In the present invention, it is possible to use the low molecular compound (D) which has a nitrogen atom and a group which is desorbed due to an action of an acid as one type individually or in a mixture of two or more types.

The composition of the present invention may or may not contain the low molecular compound (D) which has a nitrogen atom and a group which is desorbed due to an action of an acid; however, when contained, the content of the compound (D) is normally 0.001 mass % to 20 mass % based on the total solid content of the composition in combination with the basic compound which will be described below, preferably 0.001 mass % to 10 mass %, and more preferably 0.01 mass % to 5 mass %.

The usage ratio of the acid generator and the compound (D) in the composition is preferably acid generator/[compound (D)+basic compound described below] (molar ratio)=2.5 to 300. That is, the molar ratio is preferably 2.5 or more from the point of view of the sensitivity and resolution and preferably 300 or less from the point of view of suppressing decreases in the resolution due to the resist pattern becoming thick due to the passing of time until the heating step after exposure. The acid generator/[compound (D)+basic compound described below] (molar ratio) is more preferably 5.0 to 200 and even more preferably 7.0 to 150.

[5] Solvent

Examples of solvents which are able to be used when preparing the resist composition by dissolving each of the components described above include organic solvents of alkylene glycol monoalkyl ether carboxylate, alkylene glycol monoalkyl ether, alkyl lactate ester, alkyl alkoxypropionate, cyclic lactone (preferably with 4 to 10 carbon atoms), a monoketone compound which may contain a ring (preferably with 4 to 10 carbon atoms), alkylene carbonate, alkoxy alkyl acetate, alkyl pyruvate, and the like.

Examples of alkylene glycol monoalkyl ether carboxylate preferably include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Examples of alkylene glycol monoalkyl ether preferably include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Examples of alkyl lactate ester preferably include methyl lactate, ethyl lactate, propyl lactate, and butyl lactate.

Examples of alkyl alkoxypropionate preferably include 3-ethyl ethoxy propionate, 3-methyl methoxy propionate, 3-methyl ethoxy propionate, and 3-ethyl methoxy propionate.

Examples of cyclic lactone preferably include β-propiolactone, β-butyrolactone, γ-butyrolactone, α-methyl-γ-butyrolactone, β-methyl-γ-butyrolactone, γ-valerolactone, γ-caprolactone, γ-octanoiclactone, and α-hydroxy-γ-butyrolactone.

Examples of a monoketone compound which may contain a ring preferably include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Examples of alkylene carbonate preferably include propylene carbonate, vinylene carbonate, ethylene carbonate, and butylene carbonate.

Examples of alkoxy alkyl acetate preferably include acetate-2-methoxyethyl, acetate-2-ethoxyethyl, acetate-2-(2-ethoxyethoxy)ethyl, acetate-3-methoxy-3-methylbutyl, and acetate-1-methoxy-2-propyl.

Examples of alkyl pyruvate preferably include methyl pyruvate, ethyl pyruvate, and propyl pyruvate.

Examples of solvents which are preferably used include solvents with a boiling point of 130° C. or more under room temperature and normal pressure. In detail, examples include cyclopentanone, γ-butyrolactone, cyclohexanone, ethyl lactate, ethylene glycol monoethyl ether acetate, propylene glycol monomethyl ether acetate, 3-ethyl ethoxy propionate, ethyl pyruvate, acetate-2-ethoxyethyl, acetate-2-(2-ethoxyethoxy)ethyl, and propylene carbonate.

In the present invention, the solvents described above may be used individually or in a combination of two or more types.

In the present invention, as an organic solvent, a mixed solvent mixing a solvent which contains a hydroxyl group in a structure and a solvent which does not contain a hydroxyl group may be used.

It is possible to appropriately select the previously exemplified compounds as the solvent which contains a hydroxyl group and the solvent which does not contain a hydroxyl group; however, the solvent which contains a hydroxyl group is preferably alkylene glycol monoalkyl ether, alkyl lactate, or the like and more preferably propylene glycol monomethyl ether and ethyl lactate. In addition, the solvent which does not have a hydroxyl group is preferably alkylene glycol monoalkyl ether acetate, alkylalkoxy propionate, a monoketone compound which may contain a ring, cyclic lactone, alkyl acetate, and the like and, among these, propylene glycol monomethyl ether acetate, ethylethoxy propionate, 2-heptanone, γ-butyrolactone, cyclohexanone, and butyl acetate are particularly preferable and propylene glycol monomethyl ether acetate, ethylethoxy propionate, and 2-heptanone are the most preferable.

The mixing ratio (mass) of a solvent which contains a hydroxyl group and a solvent which does not contain a hydroxyl group is 1/99 to 99/1, preferably 10/90 to 90/10, and more preferably 20/80 to 60/40. A mixed solvent which contains 50 mass % or more of a solvent which does not contain a hydroxyl group is particularly preferable in terms of the coating uniformity.

The solvent is preferably a mixed solvent of two or more types which contain propylene glycol monomethyl ether acetate.

[6] Basic Compound

The resist composition of the present invention preferably contains a basic compound in order to reduce changes in performance over time from the exposure until the heating.

Examples of the basic compound preferably include a compound which has a structure which is illustrated by Formulas (A) to (E) below.

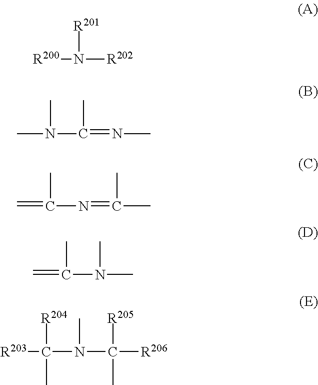

In General Formulas (A) and (E),

R²⁰⁰, R²⁰¹ and R²⁰² may be the same or may be different and represent a hydrogen atom, an alkyl group (preferably with 1 to 20 carbon atoms), a cycloalkyl group (preferably with 3 to 20 carbon atoms), or an aryl group (with 6 to 20 carbon atoms) and R²⁰¹ and R²⁰² here may bond with each other to form a ring. R²⁰³, R²⁰⁴, R²⁰⁵, and R²⁰⁶ may be the same or may be different and represent an alkyl group with 1 to 20 carbon atoms.

With regard to the alkyl groups described above, the alkyl group which has a substituent group is preferably an aminoalkyl group with 1 to 20 carbon atoms, a hydroxyalkyl group with 1 to 20 carbon atoms, or a cyanoalkyl group with 1 to 20 carbon atoms.

The alkyl groups in General Formulas (A) and (E) are more preferably unsubstituted.

Examples of preferable compounds include guanidine, aminopyrrolidine, pyrazole, pyrazoline, piperazine, aminomorpholine, aminoalkylmorpholine, piperidine, and the like and examples of more preferable compounds include compounds which have an imidazole structure, a diazabicyclo structure, an onium hydroxide structure, an onium carboxylate structure, a trialkylamine structure, an aniline structure, or a pyridine structure, an alkylamine derivative which has a hydroxyl group and/or an ether bond, an aniline derivative which has a hydroxyl group and/or an ether bond, and the like.

Examples of a compound which has an imidazole structure include imidazole, 2,4,5-triphenylimidazole, benzimidazole, 2-phenylbenzimidazole, and the like. Examples of a compound which has a diazabicyclo structure include 1,4-diazabicyclo[2,2,2]octane, 1,5-diazabicyclo[4,3,0]nona-5-ene, 1,8-diazabicyclo[5,4,0]undeca-7-ene, and the like. Examples of a compound which has an onium hydroxide structure include tetrabutyl ammonium hydroxide, triaryl sulfonium hydroxide, phenacyl sulfonium hydroxide, sulfonium hydroxide which has a 2-oxoalkyl group, specifically, triphenyl sulfonium hydroxide, tris(t-butylphenyl) sulfonium hydroxide, bis(t-butylphenyl) iodonium hydroxide, phenacyl thiophenium hydroxide, 2-oxopropyl thiophenium hydroxide, and the like. A compound which has an onium carboxylate structure is a compound in which an anion section of a compound which has an onium hydroxide structure is carboxylate and examples thereof include acetate, adamantane-1-carboxylate, perfluoroalkyl carboxylate, and the like. Examples of a compound which has a trialkylamine structure include tri(n-butyl)amine, tri(n-octyl)amine, and the like. Examples of an aniline compound include 2,6-diisopropylaniline, N,N-dimethylaniline, N,N-dibutylaniline, N,N-dihexylaniline, and the like. Examples of an alkylamine derivative which has a hydroxyl group and/or an ether bond include ethanolamine, diethanolamine, triethanolamine, N-phenyldiethanolamine, tris(methoxyethoxyethyl)amine, and the like. Examples of an aniline derivative which has a hydroxyl group and/or an ether bond include N,N-bis(hydroxyethyl)aniline and the like.

Examples of a preferable basic compound further include an amine compound which has a phenoxy group, an ammonium salt compound which has a phenoxy group, an amine compound which has a sulfonic acid ester group, and an ammonium salt compound which has a sulfonic acid ester group.

In the amine compound which has a phenoxy group, the ammonium salt compound which has a phenoxy group, the amine compound which has a sulfonic acid ester group, and the ammonium salt compound which has a sulfonic acid ester group described above, at least one alkyl group is preferably bonded with a nitrogen atom. In addition, the alkyl chains described above preferably have oxygen atoms, and oxyalkylene groups are preferably formed therein. The number of oxyalkylene groups in the molecule is 1 or more, preferably 3 to 9, and more preferably 4 to 6. Among the oxyalkylene groups, a structure of —CH₂CH₂O—, —CH(CH₃)CH₂O—, or —CH₂CH₂CH₂O— is preferable.

Specific examples of the amine compound which has a phenoxy group, the ammonium salt compound which has a phenoxy group, the amine compound which has a sulfonic acid ester group, and the ammonium salt compound which has a sulfonic acid ester group described above include compounds (C1-1) to (C3-3) exemplified in paragraph “0066” in US2007/0224539A; however, the present invention is not limited thereto.

The basic compound is used individually or two or more types are used together.

The usage amount of the basic compounds is normally 0.001 mass % to 10 mass % based on the solid content of the resist composition and preferably 0.01 mass % to 5 mass %.

The usage ratio of the acid generator and the basic compound in the composition is preferably acid generator/basic compound (molar ratio)=2.5 to 300. That is, the molar ratio is preferably 2.5 or more from the point of view of the sensitivity and resolution and preferably 300 or less from the point of view of suppressing decreases in the resolution due to the resist pattern becoming thick due to the passing of time until the heating step after exposure. The acid generator/basic compound (molar ratio) is more preferably 5.0 to 200 and even more preferably 7.0 to 150.

[7] Surfactant

The active light-sensitive or radiation-sensitive resin composition may further contain a surfactant. When contained, it is preferable to contain any fluorine-based and/or silicon-based surfactant (a fluorine-based surfactant, a silicon-based surfactant, and a surfactant which has both a fluorine atom and a silicon atom) or two or more types thereof

By the composition of the present invention containing the surfactant described above, it is possible to impart a resist pattern with less adhesion and fewer developing defects with a favorable sensitivity and resolution while using an exposure light source of 250 nm or less, particularly 220 nm or less.

Examples of the fluorine-based and/or silicon-based surfactants include the surfactants described in paragraph “0276” in US2008/0248425A and are, for example, Eftop EF301 and EF303 (manufactured by Shin-Akita Kasei Co., Ltd.), Fluorad FC430, 431, and 4430 (manufactured by Sumitomo 3M Inc.), Megafac F171, F173, F176, F189, F113, F110, F177, F120, and R08 (manufactured by DIC Inc.), Surflon S-382, SC101, 102, 103, 104, 105, and 106 (manufactured by Asahi Glass Co., Ltd.), Troyzol S-366 (manufactured by Troy Chemical Industries, Inc.), GF-300 and GF-150 (manufactured by Toagosei Co., Ltd.), Surflon S-393 (manufactured by Seimi Chemical Co., Ltd.), Eftop EF121, EF122A, EF122B, RF122C, EF125M, EF135M, EF351, EF352, EF801, EF802, and EF601 (manufactured by Jemco Inc.), PF636, PF656, PF6320, and PF6520 (manufactured by OMNOVA Corp.), FTX-204G, 208G, 218G, 230G, 204D, 208D, 212D, 218D, and 222D (manufactured by Neos Co., Ltd.), and the like. In addition, it is also possible to use polysiloxane polymer KP-341 (manufactured by Shin-Etsu Chemical Co., Ltd.) as a silicon-based surfactant.

In addition, as a surfactant, other than the surfactants known in the art as described above, it is possible to use a surfactant which uses a polymer which has a fluoro aliphatic group which is derived from a fluoro aliphatic compound which is produced by a telomerization method (also referred to as a telomer method) or an oligomerization method (also referred to an oligomer method). It is possible to synthesize the fluoro aliphatic compound using the method described in JP2002-90991A.

A polymer which has a fluoro aliphatic group is preferably a copolymer of a monomer which has a fluoro aliphatic group and (poly(oxyalkylene)) acrylate and/or (poly(oxyalkylene)) methacrylate and may be irregularly distributed or may be block-copolymerized. In addition, examples of a poly(oxyalkylene) group include a poly(oxyethylene) group, a poly(oxypropylene) group, a poly(oxybutylene) group, and the like and additionally, the poly(oxyalkylene) group may be a unit which has an alkylene with different chain length in the same chain length such as a poly(block linking body of oxyethylene, oxypropylene, and oxyethylene) or a poly(block linking body of oxyethylene and oxypropylene). Furthermore, the copolymer of a monomer which has a fluoro aliphatic group and (poly(oxyalkylene)) acrylate (or methacrylate) is not only a binary copolymer, but may be a tertiary or higher copolymer where a monomer which has two or more different types of fluoro aliphatic groups, two or more different types of (poly(oxyalkylene)) acrylate (or methacrylate), or the like are copolymerized at the same time.

Examples of commercially available surfactants include Megafac F-178, F-470, F-473, F-475, F-476, and F-472 (manufactured by DIC Inc.), a copolymer of acrylate (or methacrylate) which has a C₆F₁₃ group and (poly(oxyalkylene)) acrylate (or methacrylate), a copolymer of acrylate (or methacrylate) which has a C₃F₇ group, (poly(oxyethylene)) acrylate (or methacrylate), and (poly(oxypropylene)) acrylate (or methacrylate), and the like.

In addition, in the present invention, it is also possible to use other surfactants than the fluorine-based and/or the silicon-based surfactants described in paragraph “0280” in US2008/0248425A.

The surfactants may be used individually or may be used in various combinations.

The usage amount of the surfactants is preferably 0 mass % to 2 mass % with respect to the total solid content of the active light-sensitive or radiation-sensitive resin composition (the total amount excluding solvents), more preferably 0.0001 mass % to 2 mass %, and particularly preferably 0.0005 mass % to 1 mass %.

[8] Carboxylic Acid Onium Salt

The resist composition in the present invention may contain carboxylic acid onium salt. The carboxylic acid onium salt is preferably iodonium salt and sulfonium salt. An anion section is preferably a straight-chain, branched, cyclic, or polycyclic cyclic alkylcarboxylic acid anion with 1 to 30 carbon atoms. A carboxylic acid anion in which some or all of the alkyl groups are substituted with fluorine is more preferable. An oxygen atom may be included in an alkyl chain. Due to this, transparency with respect to light of 220 nm or less is secured, the sensitivity and resolving power are improved, and the density dependency and exposure margin are improved.

Examples of a carboxylic acid anion which is substituted with fluorine include anions and the like of fluoroacetic acid, difluoroacetic acid, trifluoroacetic acid, pentafluoro propionate, heptafluoro butyric acid, nonafluoro pentanoic acid, perfluoro dodecanoic acid, perfluoro tridecanoic acid, perfluoro cyclohexane carboxylic acid, and 2,2-bistrifluoro methyl propionate.

The content of the carboxylic acid onium salt in the composition is generally 0.1 mass % to 20 mass % with respect to the total solid content of the composition, preferably 0.5 mass % to 10 mass %, and more preferably 1 mass % to 7 mass %.

[9] Dissolution Inhibiting Compound with a Molecular Weight of 3000 or Less of which, Due to being Decomposed by an Action of an Acid, the Solubility Increases in an Alkali Developer

A dissolution inhibiting compound (also referred to below as a “dissolution inhibiting compound”) with a molecular weight of 3000 or less of which, due to being decomposed by an action of an acid, the solubility increases in an alkali developer is preferably an alicyclic or aliphatic compound which contains an acid-decomposable group such as a cholic acid derivative which includes an acid-decomposable group described in Proceeding of SPIE, 2724, 355 (1996) so as to not decrease the transparency of 220 nm or less. Examples of the acid-decomposable group and the alicyclic structure include the same examples as described in (B) components of a resin.

Here, in a case of exposing the resist composition of the present invention to a KrF excimer laser or irradiating the resist composition with electron beams, the dissolution inhibiting compound preferably contains a structure in which a phenolic hydroxyl group of a phenol compound is substituted with an acid-decomposable group. The phenol compound preferably contains 1 to 9 phenol skeletons and more preferably contains 2 to 6.

The added amount of the dissolution inhibiting compound is preferably 3 mass % to 50 mass % with respect to the solid content of the resist composition and more preferably 5 mass % to 40 mass %.

Specific examples of the dissolution inhibiting compound will be shown below; however, the present invention is not limited thereto.

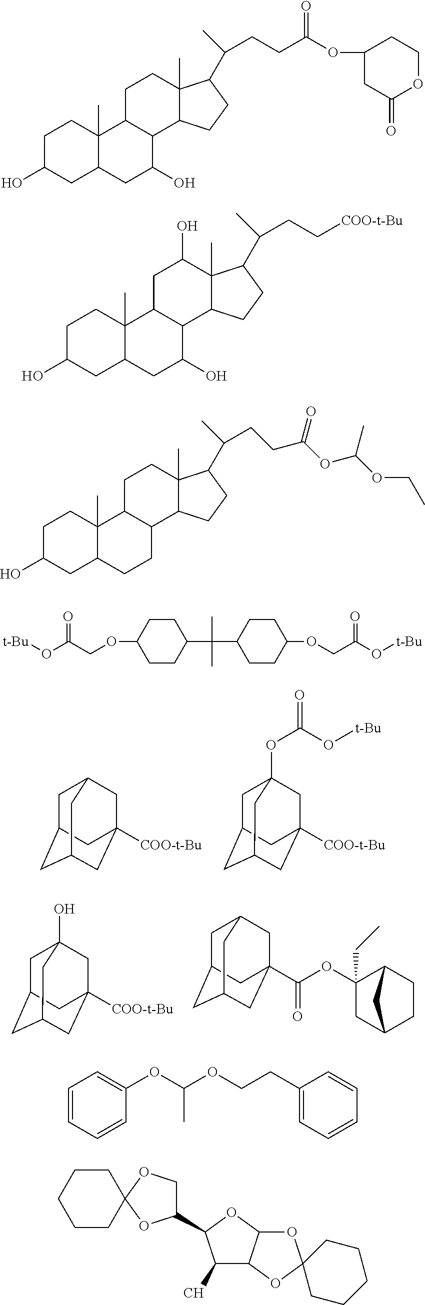

[10] Other Additive Agents

It is possible to further contain a compound (for example, a phenol compound with a molecular weight of 1000 or less, an alicyclic or aliphatic compound which has a carboxyl group) or the like which promotes the solubility with respect to a dye, a plasticizer, a photosensitizer, a light absorption agent, and a developer as necessary in the resist composition of the present invention.

It is possible to easily synthesize the phenol compound with a molecular weight of 1000 or less by a person skilled in the art with reference to the methods described in, for example, JP1992-122938A (JP-H4-122938A), JP1990-28531A (JP-H2-28531A), U.S. Pat. No. 4,916,210A, EP219294A, and the like.

Specific examples of an alicyclic or aliphatic compound which has a carboxyl group include a carboxylic acid derivative which has a steroid structure such as cholic acid, deoxycholic acid, and lithocholic acid, an adamantane carboxylic acid derivative, adamantane dicarboxylic acid, cyclohexane carboxylic acid, cyclohexane dicarboxylic acid, and the like; however, the present invention is not limited thereto.

[11] Pattern-Forming Method

From the viewpoint of improving the resolution, the composition of the present invention is preferably used with a film thickness of 30 nm to 250 nm and more preferably used with a film thickness of 30 nm to 200 nm. It is possible to set the film thickness by setting the solid content concentration in the resist composition to an appropriate range to have a suitable viscosity and to improve the coating property and film-forming property.

The total solid content concentration in the resist composition is generally 1 mass % to 10 mass %, more preferably 1 mass % to 8.0 mass %, and even more preferably 1.0 mass % to 6.0 mass %.

After dissolving the components described above in a predetermined organic solvent, preferably in the mixed solvent described above, and carrying out filtration with a filter, the resist composition of the present invention is used to coat a predetermined support body as below. The filter which is used for the filter filtration is preferably made of polytetrafluoroethylene, polyethylene, or nylon with a pore size of 0.1 microns or less, more preferably 0.05 microns or less, and even more preferably 0.03 microns or less.

For example, the resist film is formed by coating and drying the resist composition on a substrate which is used for manufacturing precision integrated circuit elements (for example, by silicon/silicon dioxide coating) using an appropriate coating tool such as spinner or coater.

The resist film is irradiated with active light or radiation through a predetermined mask, baking (heating) is preferably performed, and developing and rinsing are carried out. Due to this, it is possible to obtain a more favorable pattern.

Examples of the active light or radiation include infrared light, visible light, ultraviolet light, far ultraviolet light, extreme ultraviolet light, X-rays, electron beams, and the like; however, the active light or radiation is preferably far ultraviolet light with a wavelength of 250 nm or less, more preferably 220 nm or less, and particularly preferably 1 nm to 200 nm, specifically a KrF excimer laser (248 nm), an ArF excimer laser (193 nm), an F₂ excimer laser (157 nm), X-rays, electron beams, and the like and an ArF excimer laser, an F₂ excimer laser, EUV (13 nm), and electron beams are preferable.

An antireflection film may be coated on the substrate beforehand before forming the resist film.

As the antireflection film, it is possible to use either an inorganic film type such as titanium, titanium dioxide, titanium nitride, chromium oxide, carbon, and amorphous silicon, or an organic film type formed of a light absorbing agent and polymer material. In addition, as the organic antireflection film, it is also possible to use commercially available antireflection films such as DUV30 series or DUV-40 series manufactured by Brewer Science Inc. and AR-2, AR-3, and AR-5 manufactured by Shipley Japan, Ltd., and the like.

The developer which is used in the step of developing the resist film which is formed with the active light-sensitive or radiation-sensitive resin composition of the present invention is not particularly limited; however, it is possible to use, for example, an alkali developer or a developer (also referred to below as an organic-based developer) which contains an organic solvent.

Quaternary ammonium salt which is represented by tetramethyl ammonium hydroxide is generally used as an alkali developer; however, apart from this, it is also possible to use an alkali aqueous solution of inorganic alkali, primary amine, secondary amine, tertiary amine, alcohol amine, cyclic amine, and the like. Furthermore, use is also possible by adding an appropriate amount of alcohols and a surfactant to the alkali developer described above. The alkali concentration of the alkali developer is generally 0.1 mass % to 20 mass %. The pH of the alkali developer is normally 10.0 to 15.0.

Furthermore, use is also possible by adding an appropriate amount of alcohols and a surfactant to the alkali aqueous solution described above.

As an organic-based developer, it is possible to use a polar solvent such as a ketone-based solvent, an ester-based solvent, an alcohol-based solvent, an amide-based solvent, and an ether-based solvent or a hydrocarbon-based solvent.

Examples of the ketone-based solvents include 1-octanone, 2-octanone, 1-nonanone, 2-nonanone, acetone, 2-heptanone (methylamyl ketone), 4-heptanone, 1-hexanone, 2-hexanone, diisobutyl ketone, cyclohexanone, methylcyclohexanone, phenylacetone, methylethyl ketone, methylisobutyl ketone, acetylacetone, acetonylacetone, ionone, diacetonyl alcohol, acetylcarbinol, acetophenone, methylnaphthyl ketone, isophorone, propylene carbonate, and the like.

Examples of the ester-based solvents include methyl acetate, butyl acetate, ethyl acetate, isopropyl acetate, pentyl acetate, isopentyl acetate, amyl acetate, propylene glycol monomethyl ether acetate, ethylene glycol monoethy ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate, propyl lactate, and the like.

Examples of the alcohol-based solvents include alcohols such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol, and n-decanol, glycol-based solvents such as ethylene glycol, diethylene glycol, and triethylene glycol, glycol ether-based solvents such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol, and the like.

Examples of the ether-based solvents include dioxane, tetrahydrofuran, and the like other than the glycol ether-based solvents described above.

As the amide-based solvents, it is possible to use N-methyl-2-pyrrolidone, N,N-dimethyl acetamide, N,N-dimethyl formamide, hexamethylphosphoric triamide, 1,3-dimethyl-2-imidazolidinone, and the like.

Examples of the hydrocarbon-based solvents include aromatic hydrocarbon-based solvents such as toluene and xylene and aliphatic hydrocarbon-based solvents such as pentane, hexane, octane, and decane.

A plurality of the solvents described above may be mixed or the solvents may be used mixed with solvents other than the above or water. The content of the water which is included in the organic-type developer is preferably less than 10 mass % and, more preferably, water is substantially not contained.

That is, the usage amount of the organic solvent with respect to the organic-based developer is preferably 90 mass % to 100 mass % with respect to the total amount of the developer and more preferably 95 mass % to 100 mass %.

In particular, the organic-based developer is preferably a developer which contains at least one type of an organic solvent selected from a group consisting of a ketone-based solvent, an ester-based solvent, an alcohol-based solvent, an amide-based solvent, and an ether-based solvent. It is possible to add an appropriate amount of a surfactant to the organic-based developer as necessary.

The surfactant is not particularly limited; however, it is possible to use, for example, ionic or non-ionic fluorine-based and/or silicon-based surfactants and the like. Examples of the fluorine and/or silicon-based surfactant include the surfactants described in JP1987-36663A (JP-S62-36663A), JP1986-226746A (JP-S61-226746A), JP1986-226745A (JP-S61-226745A), JP1987-170950A (JP-S62-170950A), JP1988-34540A (JP-S63-34540A), JP1995-230165A (JP-H7-230165A), JP1996-62834A (JP-H8-62834A), JP1997-54432A (JP-H9-54432A), JP1997-5988A (JP-H9-5988A), U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A and non-ionic surfactants are preferable. The non-ionic surfactant is not particularly limited; however, it is more preferable to use a fluorine-based surfactant or a silicon-based surfactant. The usage amount of the surfactant is normally 0.001 mass % to 5 mass % with respect to the total amount of the developer, preferably 0.005 mass % to 2 mass %, and more preferably 0.01 mass % to 0.5 mass %.

In addition, it is possible to add an appropriate amount of the basic compound described above to the organic-based developer as necessary.

As a rinsing liquid, pure water is used and use is also possible with an appropriate amount of a surfactant added thereto.

In addition, it is possible to perform a process which removes developer or rinsing liquid which is attached to the pattern using a supercritical fluid after the developing process or the rinsing process.

In addition, the present invention also relates to a method for manufacturing an electronic device which includes the pattern-forming method of the present invention described above and to an electronic device which is manufactured by this manufacturing method.

The electronic device of the present invention is favorably mounted on electrical and electronic devices (household electrical appliances, OA and media-related devices, optical apparatuses and instruments, telecommunication devices, and the like).

### EXAMPLES

Examples will be shown below; however, the present invention is not limited thereto.

(Synthesizing Resin B-1)

14.2 g of cyclohexanone was added to a three-neck flask in a nitrogen gas stream and heated to 85° C. In this manner, a solvent 1 was obtained. Next, a monomer solution was prepared by dissolving the monomer 1 (8.89 g) below, the monomer 2 (3.55 g) below, and the monomer 3 (8.20 g) below in cyclohexanone (56.9 g). A solution where 8.0 mol %, with respect to the total amount of the monomer, of a polymerization initiator V-601 (manufactured by Wako Pure Chemical Industries, Ltd.) was added and dissolved in this monomer solution was dripped over 6 hours with respect to the solvent 1 described above and, after finishing the dripping, a reaction was further carried out at 85° C. for 2 hours. After leaving the reaction liquid to cool, 16.5 g of the resin (B−1) was obtained by dripping the reaction liquid in a mixed solvent of 506 g of heptane/217 g of ethyl acetate and filtering and drying the extracted powder. The weight average molecular weight (Mw) of the obtained resin (B−1) was 8500 and the dispersity (Mw/Mn) was 1.56.

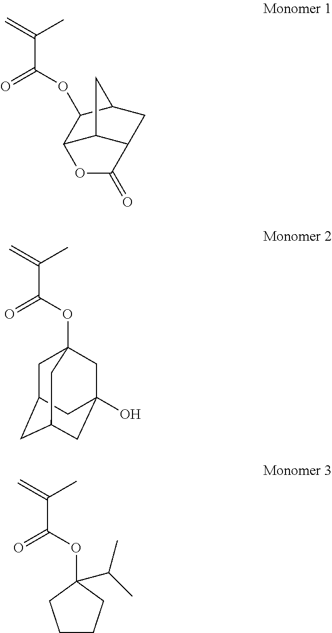

In the same manner as the resin (B−1), the resins (B-2), (B-3), and (B-X) which were used in Examples were synthesized.

(Synthesizing Photoacid Generator A-1)

A photoacid generator (A−1) was synthesized according to the synthesizing method described in WO2011/104127A. The photoacid generators (A-2) to (A-6), (A-X), and (A-Y) were also synthesized in the same manner.

<Resist Preparation>

An active light-sensitive or radiation-sensitive resin composition (also referred to below as a resist composition) was prepared by dissolving the components shown in Table 2 below in a solvent, preparing a solution with a solid content concentration of 4 mass % for each component, and filtering the results using a polyethylene filter with a pore size of 0.05 μm. The active light-sensitive or radiation-sensitive resin composition was evaluated by the method below and the results thereof are shown in Table 2.

<Resist Evaluation>

(ArF Liquid Immersion Exposure)

An antireflection film with a film thickness of 98 nm was formed by coating ARC29SR (produced by Nissan Chemical Industries, Ltd.) for forming an organic antireflection film on a 12 inch silicon wafer, and performing baking at 205° C. for 60 seconds. The active light-sensitive or radiation-sensitive resin composition which was prepared above was coated thereon, baking was performed at 95° C. for 60 seconds, and a resist film with film thickness of 120 nm was formed. With respect to this, using an ArF excimer laser liquid immersion scanner (XT1700i manufactured by ASML, NA1.20, C-Quad, outer sigma 0.981, inner sigma 0.895, and XY inclination), exposure was carried out through a 6% half tone mask with a 1:1 line and space pattern with a line width of 48 nm. Ultra-pure water was used as the immersion liquid. After that, after heating at 90° C. for 60 seconds, developing was carried out by paddling in a tetramethyl ammonium hydroxide water solution (2.38 mass %) for 30 seconds and a pattern was formed by spin drying after being rinsed by paddling in pure water.

(LWR Evaluation)

The line pattern (ArF liquid immersion exposure: a line width of 48 nm) with a line/space=1/1 which was obtained above was observed using a scanning microscope (S9380 manufactured by Hitachi Ltd.). In a range at the 2 μm from the edge in a longitudinal direction of the line pattern, the line width was measured at 50 points, the standard deviation was obtained regarding the measurement variations, and 3σ was calculated. A small value indicates a more favorable performance.

(Depth of Focus Latitude (DOF) Evaluation)

An exposure amount and focus depth for reproducing a resist pattern with a 1:1 line and space pattern with a line width of 48 nm were set to a suitable exposure amount and a suitable focus depth and a focus depth width which allowed a line width of ±10% of the line width described above (that is 48 nm±10%) was measured when changing (defocusing) the focus depth from the suitable focus depth while the exposure amount was left as the suitable exposure amount. When the value was large, the focus shift allowance was large, which is desirable.

TABLE 2

| | Photoacid | | Basic | | Solvent | | Evaluation | Evaluation |
|---|---|---|---|---|---|---|---|---|
| | generator | Resin | substance | Hydrophobic | (mass | Surfactant | item 1 | item 2 DOF |
| | (g) | (10 g) | (g) | resin HR (35 mg) | ratio) | (10 mg) | LWR (nm) | (μm) |
| Example 1 | A-1 | B-1 | C-1 | B-4 | A1 | W-1 | 5.5 | 0.11 |
| | (0.6) | | (0.35) | | (100) | | | |
| Example 2 | A-2 | B-2 | C-2 | B-18 | A1/A2/A3 | W-2 | 5.1 | 0.12 |
| | (1.2) | | (0.15) | | (85/10/5) | | | |
| Example 3 | A-3 | B-3 | C-1 | B-16 | A1/B1 | W-3 | 5.7 | 0.09 |
| | (0.8) | | (0.39) | | (60/40) | | | |
| Example 4 | A-4 | B-2 | C-2 | B-3 | A1/B2 | W-1 | 6.0 | 0.09 |
| | (0.8) | | (0.16) | | (90/10) | | | |
| Example 5 | A-5 | B-1 | C-1 | B-13 | A1/A2 | None | 5.2 | 0.12 |
| | (1.1) | | (0.39) | | (70/30) | | | |
| Example 6 | A-6/A-X | B-3 | C-2 | B-3 | A1/A2 | W-1 | 5.4 | 0.11 |
| | (0.5/0.1) | | (0.18) | | (70/30) | | | |
| Example 7 | A-2/A-5 | B-3 | C-2 | B-21 | A1 | W-3 | 5.2 | 0.12 |
| | (0.9/0.3) | | (0.14) | | (100) | | | |
| Comparative | A-X | B-1 | C-1 | B-4 | A1 | W-1 | 6.5 | 0.06 |
| Example 1 | (0.6) | | (0.35) | | (100) | | | |
| Comparative | A-Y | B-1 | C-1 | B-4 | A1 | W-1 | 6.7 | 0.05 |
| Example 2 | (0.6) | | (0.35) | | (100) | | | |
| Comparative | A-1 | B-X | C-1 | B-4 | A1 | W-1 | 7.1 | 0.05 |
| Example 3 | (0.6) | | (0.35) | | (100) | | | |

The reference numbers in the table represent the following.

[Photoacid Generator]

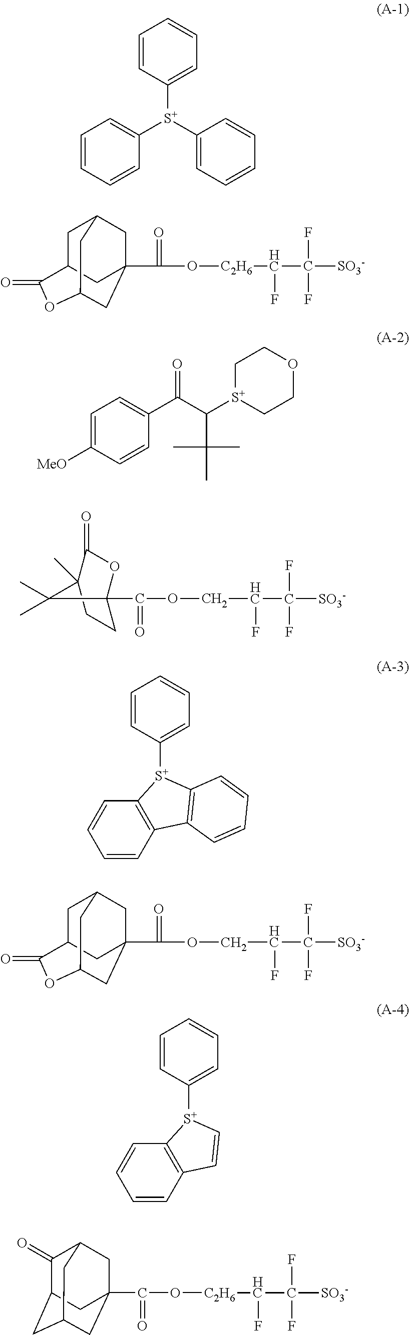

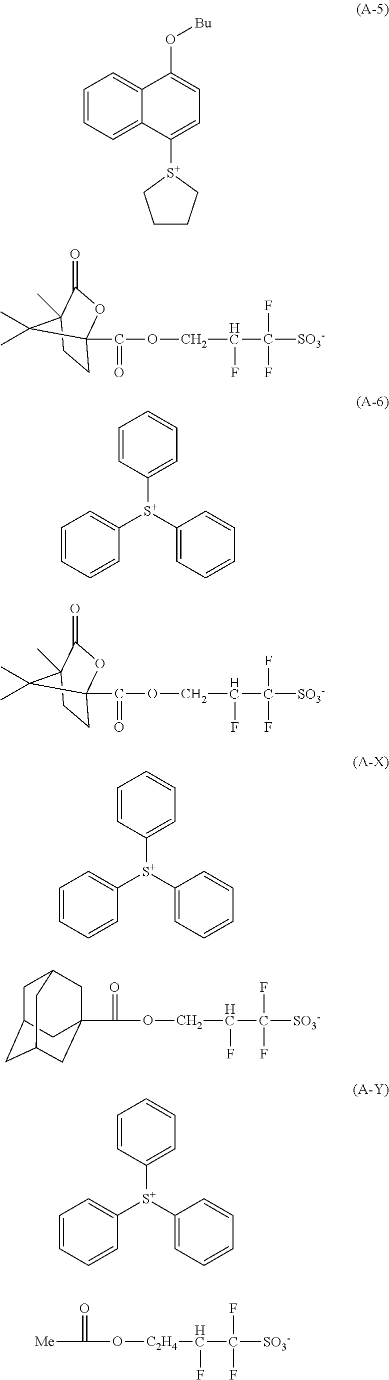

[Resin]

With regard to each of the resins below, the composition ratio of repeating units is the molar ratio.

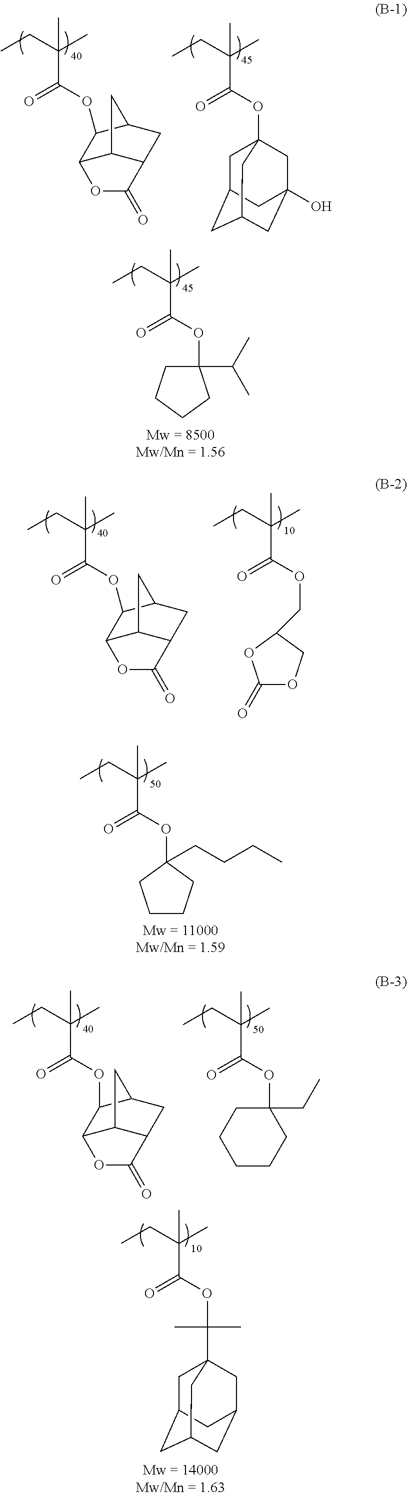

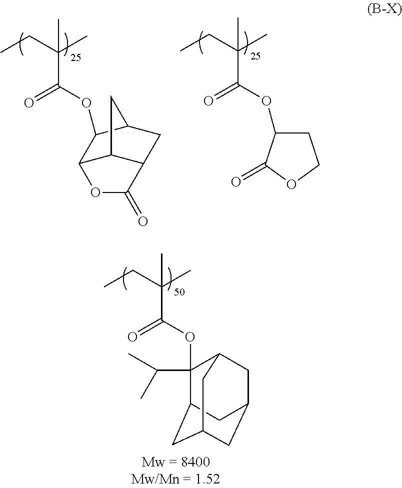

[Basic Compound]

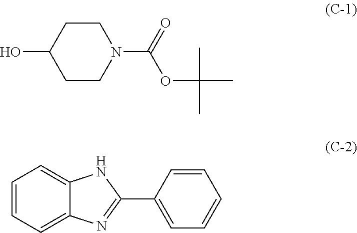

[Hydrophobic Resin]

The hydrophobic resin was appropriately selected from (B−1) to (B-55) given above as the specific examples and used.

[Solvent]

A1: Propylene glycol monomethyl ether acetate (PGMEA)

A2: Cyclohexanone

A3: γ-butyrolactone

B1: Propylene glycol monomethyl ether (PGME)

B2: Ethyl lactate

[Surfactant]

W-1: Megafac F176 (produced by DIC Inc.) (fluorine-based)

W2: Troyzol S-366 (produced by Troy Chemical Industries, Inc.) (fluorine-based)

W-3: PF-656 (produced by OMNOVA Solutions Inc.) (fluorine-based)

From Table 2 above, it is understood that each of the compositions which were used in the Examples are excellent in terms of exposure latitude and pattern roughness such as LWR.

Apart from changing the developer to butyl acetate, LWR and DOF were evaluated in the same manner as for the resist evaluation described above. The result thereof are shown in Table 3. The structures of the resin (B-4) and the hydrophobic resin (B-X) which were used in the table will be shown below.

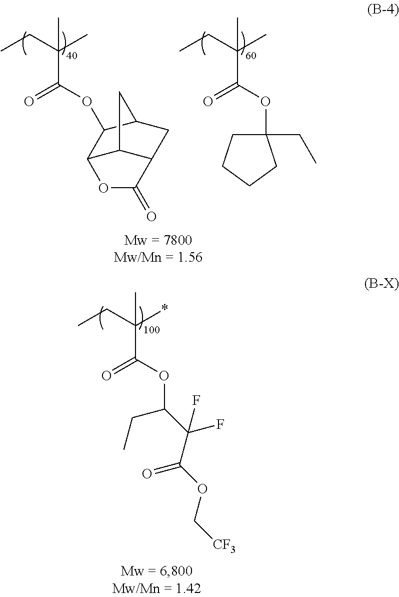

TABLE 3

| | Photoacid | | Basic | | Solvent | | Evaluation | Evaluation |
|---|---|---|---|---|---|---|---|---|
| | generator | Resin | substance | Hydrophobic | (mass | Surfactant | item 1 | item 2 DOF |
| | (g) | (10 g) | (g) | resin HR (35 mg) | ratio) | (10 mg) | LWR (nm) | (μm) |
| Example 1 | A-1/A-X | B-3 | C-1 | B-4 | A1 | W-1 | 5.2 | 0.11 |
| | (0.6/0.1) | | (0.35) | | (100) | | | |
| Example 2 | A-5 | B-2 | C-2 | B-18 | A1/A2 | W-1 | 5.1 | 0.11 |
| | (1.1) | | (0.15) | | (70/30) | | | |
| Example 3 | A-2/A-6 | B-4 | C-2 | B-X | A1/B1 | W-3 | 4.9 | 0.12 |
| | (0.9/0.3) | | (0.15) | | (60/40) | | | |
| Comparative | A-X | B-3 | C-1 | B-3 | A1 | W-1 | 6.3 | 0.07 |
| Example 1 | (0.5) | | (0.35) | | (100) | | | |
| Comparative | A-1 | B-X | C-1 | B-4 | A1 | W-1 | 7.1 | 0.05 |
| Example 2 | (0.6) | | (0.35) | | (100) | | | |

From Table 3 above, it is understood that each of the compositions which were used in Examples are excellent in terms of exposure latitude and pattern roughness such as LWR even in a case of using an organic-based developer.

What is claimed is:

1. An active light-sensitive or radiation-sensitive resin composition comprising:
(A) at least one type of a compound which is represented by General Formula (I) below and which generates an acid by irradiation with active light or radiation; and
(B) at least one type of a resin which includes a repeating unit which is represented by General Formula (1) below and of which, due to being decomposed by an action of an acid, a solubility increases with respect to an alkali developer, 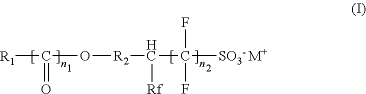
wherein, in General Formula (I),
R₁ represents an alicyclic hydrocarbon group in which at least one of methylene groups configuring a ring skeleton is substituted with a divalent linking group having a hetero atom;
R₂ represents a divalent linking group;
Rf represents a fluorine atom or an alkyl group which is substituted with at least one fluorine atom;
n₁ and n₂ each independently represent 0 or 1; and
M⁺ represents a monovalent cation, and 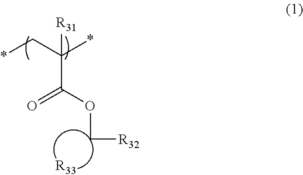
in General Formula (1),
R₃₁ represents a hydrogen atom, a fluorine atom, an alkyl group, or a fluorinated alkyl group;
R₃₂ represents an alkyl group or a cycloalkyl group;
R₃₃ represents an atom group which is necessary for forming a monocyclic alicyclic hydrocarbon structure with a carbon atom with which R₃₂ is bonded, and
in the alicyclic hydrocarbon structure, a part of carbon atoms configuring a ring may be substituted with a hetero atom or a group having a hetero atom.

2. The active light-sensitive or radiation-sensitive resin composition according to claim 1,
wherein, in General Formula (I),
R₁ is a lactone group.

3. The active light-sensitive or radiation-sensitive resin composition according to claim 1,
wherein, in General Formula (I), n₂ is 1 and Rf is a fluorine atom.

4. The active light-sensitive or radiation-sensitive resin composition according to claim 1,
wherein, in General Formula (I), n₁ is 1 and R₂ is a methylene group.

5. The active light-sensitive or radiation-sensitive resin composition according to claim 1,
wherein, in General Formula (I), R₁ is a lactone group, R₂ is a methylene group, Rf is a fluorine atom, and, n₁ and n₂ is 1.

6. The active light-sensitive or radiation-sensitive resin composition according to claim 1,
wherein, in General Formula (I),
R₁ is a lactone group having a polycyclic structure.

7. The active light-sensitive or radiation-sensitive resin composition according to claim 1,
wherein, in General Formula (I),
R₁ is a lactone group represented by the structural formula below.

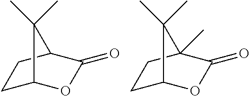

8. The active light-sensitive or radiation-sensitive resin composition according to claim 1,
wherein, in General Formula (I),
M⁺ is a sulfonium cation represented by General Formula (II) or (III) below, and 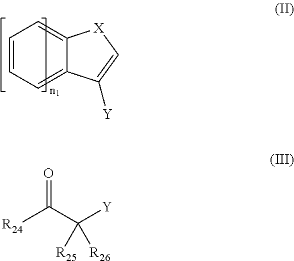
in General Formulas (II) and (III),
Y represents a structure represented by any of General Formulas (V-1) to (V-3) below; 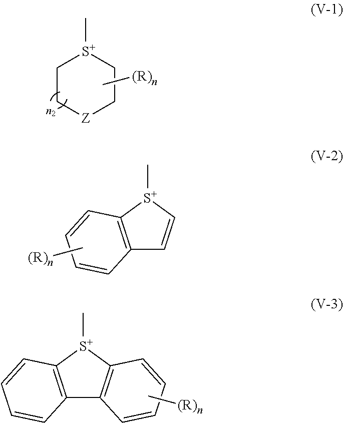
n₁ and n₂ are each independently 0 or 1;
X and Z represent any of —CH₂—, —CR₂₁═CR₂₂—, —NR₂₃—, —S—, and —O—;
R₂₁, R₂₂, and R₂₃ each independently represent a hydrogen atom, a substituted or unsubstituted alkyl group, a cycloalkyl group, or an alkoxy group;
R₂₄ represents a substituted or unsubstituted aryl group;
R₂₅ and R₂₆ each independently represent a hydrogen atom, a substituted or unsubstituted alkyl group or a cycloalkyl group, and R₂₅ and R₂₆ may form a ring by linking with each other; and
(R)ₙ represents a substituent group.

9. The active light-sensitive or radiation-sensitive resin composition according to claim 1,
wherein at least one type of a photoacid generator other than the compound (A) is included.

10. The active light-sensitive or radiation-sensitive resin composition according to claim 1, further comprising:
a hydrophobic resin.

11. An active light-sensitive or radiation-sensitive film which includes the composition according to claim 1.

12. A pattern-forming method comprising:
forming a film which includes the composition according to claim 1;
irradiating the film with active light or radiation; and
developing the film irradiated with active light or radiation.

13. The pattern-forming method according to claim 12,
wherein the irradiating with active light or radiation is performed by ArF liquid immersion exposure.

14. A method for manufacturing an electronic device, which includes the pattern-forming method according to claim 12.

15. An electronic device which is manufactured by the method for manufacturing an electronic device according to claim 14.
